(19) United States
(12) Patent Application Publication
(10) Pub. No.: US 2026/0206469 A1
(43) Pub. Date: Jul. 16, 2026

(54) ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Takanori MATSUZAKI, Atsugi, Kanagawa (JP); Yoshiaki OIKAWA, Atsugi, Kanagawa (JP); Kensuke YOSHIZUMI, Atsugi, Kanagawa (JP); Natsuko TAKASE, Isehara, Kanagawa (JP); Atsushi MIYAGUCHI, Hadano, Kanagawa (JP)

(21) Appl. No.: 19/135,163

(22) PCT Filed: Dec. 21, 2023
(86) PCT No.: PCT/IB2023/063068

§ 371 Date: Jun. 3, 2025

(30) Foreign Application Priority Data
Dec. 28, 2022 (JP) 2022-211876

(51) Int. Cl. H10K 59/80; H10D 86/40; H10D 86/60; H10K 50/19

(52) U.S. Cl. CPC H10K 59/879; H10D 86/423; H10D 86/60; H10K 50/19

(57) ABSTRACT

An object of the present invention is to provide an electronic device with an appropriate screen size and low power consumption. The electronic device includes a lens and a display apparatus (10A). The display apparatus (10A) includes a display portion and a transistor (52). The display portion includes a light-emitting device (61). The transistor (52) is positioned below the light-emitting device (61). The diagonal size of the display portion is greater than or equal to 1.0 inch and less than or equal to 2.5 inches. The transistor (52) includes an oxide semiconductor in a channel formation region. The transistor (52) controls the driving of the light-emitting device (61).

### TECHNICAL FIELD

One embodiment of the present invention relates to a semiconductor device. One embodiment of the present invention relates to a display apparatus. One embodiment of the present invention relates to an electronic device including a display apparatus.

Note that one embodiment of the present invention is not limited to the above technical field. Examples of the technical field of one embodiment of the present invention disclosed in this specification and the like include a display apparatus, a light-emitting apparatus, a power storage device, a memory device, an electronic device, a lighting device, an input device, an input/output device, a driving method thereof, and a manufacturing method thereof.

### BACKGROUND ART

In recent years, electronic devices including semiconductor devices have been widely used. Examples of the electronic device include a head-mounted display (HMD) suitable for an XR (Extended Reality or Cross Reality) application such as virtual reality (VR) or augmented reality (AR). HMDs are capable of displaying a video showing 360-degree view of the user's surroundings in accordance with the motion of the user's head or the user's gaze or operation; thus, the user can have a high sense of immersion and a high realistic sensation.

An HMD has a structure in which an optical member or the like magnifies an image displayed on a display apparatus, so that the user sees the magnified image. In this case, there is a possibility that the size of a housing increases because of the presence of the optical member or that the user sees pixels easily and senses graininess strongly; hence, the display apparatus is required to have high definition and a smaller size. For example, Patent Document 1 discloses an HMD that includes minute pixels using transistors capable of high-speed driving (see Patent Document 1).

Another example of the electronic device including a semiconductor device is a wearable device that performs mobile communication or the like. For example, an arm-worn electronic device may include a variety of sensors, a CPU for controlling the sensors, a memory for storing data, and the like in addition to a display (e.g., see Patent Document 2).

### REFERENCE

### Patent Document

[Patent Document 1] Japanese Published Patent Application No. 2000-2856
[Patent Document 2] PCT International Publication No. 2016/036472

### SUMMARY OF THE INVENTION

### Problems to be Solved by the Invention

A semiconductor device that can be used for an electronic device such as a device for VR, a device for AR, or a wearable device, in particular, a display panel using the semiconductor device needs to have a screen as large as possible while achieving a reduction in the manufacturing cost.

In order to improve display quality, a display panel with high luminance and high definition is required. Meanwhile, a high-luminance and high-definition display panel has a risk of causing color mixture between adjacent pixels. In addition, the high-definition display panel has a problem of an increase in power consumption because the display panel needs to transmit and receive an enormous amount of image data or needs to perform arithmetic processing necessary for drawing processing.

In view of the above object, an object of one embodiment of the present invention is to provide a novel semiconductor device, a novel display apparatus, or a novel electronic device. Another object of one embodiment of the present invention is to provide a semiconductor device, a display apparatus, or an electronic device whose screen size is optimized. Another object of one embodiment of the present invention is to provide a semiconductor device, a display apparatus, or an electronic device which inhibits color mixture between pixels while achieving higher definition. Another object of one embodiment of the present invention is to provide a semiconductor device, a display apparatus, or an electronic device with low power consumption. Another object of one embodiment of the present invention is to provide a semiconductor device, a display apparatus, or an electronic device with reduced weight. Another object of one embodiment of the present invention is to provide a semiconductor device, a display apparatus, or an electronic device with superior drawing processing capacity.

Note that the description of these objects does not preclude the existence of other objects. One embodiment of the present invention does not necessarily achieve all these objects. Note that objects other than these can be derived from the description of the specification, the drawings, the claims, and the like.

### Means for Solving the Problems

One embodiment of the present invention is an electronic device including a lens and a display apparatus. The lens is provided at a position where light from the display apparatus passes. The display apparatus includes a display portion and a transistor. The display portion includes a light-emitting device. The transistor is placed below the light-emitting device. The display portion has a diagonal size greater than or equal to 1.0 inch and less than or equal to 2.5 inches. The transistor includes an oxide semiconductor in a channel formation region. The transistor controls driving of the light-emitting device.

Another embodiment of the present invention is an electronic device including a lens and a display apparatus. The lens is provided at a position where light from the display apparatus passes. The display apparatus includes a display portion and a transistor. The display portion includes a light-emitting device. The transistor is placed below the light-emitting device. The display portion has a diagonal size greater than or equal to 1.0 inch and less than or equal to 2.5 inches. The transistor includes an oxide semiconductor in a channel formation region. The light-emitting device is an organic EL element, and the transistor controls driving of the organic EL element.

Another embodiment of the present invention is an electronic device including a lens and a display apparatus. The lens is provided at a position where light from the display apparatus passes. The display apparatus includes a display portion, a first transistor, and a second transistor. The display portion includes a light-emitting device. The first transistor is placed below the light-emitting device. The second transistor is placed below the first transistor. The display portion has a diagonal size greater than or equal to 1.0 inch and less than or equal to 2.5 inches, the light-emitting device is an organic EL element, and the first transistor constitutes a part of a pixel circuit. The second transistor constitutes a part of a driver circuit or a functional circuit.

In the above, it is preferable that the first transistor and the second transistor each include an oxide semiconductor. Alternatively, in the above, it is preferable that the first transistor include an oxide semiconductor and that the second transistor include silicon.

### Effect of the Invention

According to one embodiment of the present invention, a novel semiconductor device can be provided. According to another embodiment of the present invention, a semiconductor device whose screen size is optimized can be provided. According to another embodiment of the present invention, a semiconductor device that inhibits color mixture between pixels while achieving higher definition can be provided. According to another embodiment of the present invention, a semiconductor device with low power consumption can be provided. According to another embodiment of the present invention, a semiconductor device with reduced weight can be provided. According to another embodiment of the present invention, a semiconductor device with superior drawing processing capacity can be provided.

Note that the description of these effects does not preclude the existence of other effects. One embodiment of the present invention does not need to have all these effects. Note that effects other than these can be derived from the description of the specification, the drawings, the claims, and the like.

### BRIEF DESCRIPTION OF THE DRAWINGS

FIG. 1A to FIG. 1F are diagrams each illustrating a size of a display portion and a light-exposure region.

FIG. 2A and FIG. 2B are diagrams each illustrating an example of the number of chips taken out of a Si wafer.

FIG. 3A and FIG. 3B are diagrams each illustrating an example of the number of chips taken out of a Si wafer.

FIG. 4A and FIG. 4B are diagrams each illustrating an example of the number of chips taken out of a Si wafer.

FIG. 5A and FIG. 5B are diagrams illustrating a structure example of a semiconductor device.

FIG. 6A and FIG. 6B are diagrams illustrating a structure example of an electronic device.

FIG. 7A and FIG. 7B are diagrams illustrating a structure example of an electronic device.

FIG. 8A to FIG. 8D are diagrams illustrating structure examples of electronic devices.

FIG. 9A and FIG. 9B are diagrams illustrating a structure example of a display apparatus.

FIG. 10 is a diagram illustrating a structure example of a display apparatus.

FIG. 11A to FIG. 11C are each a perspective view of a display module.

FIG. 12 is a diagram showing an operation method example of an electronic device.

FIG. 13A and FIG. 13B are schematic diagrams illustrating a structure example of an electronic device.

FIG. 14A and FIG. 14B are schematic diagrams each illustrating a structure example of an electronic device.

FIG. 15A and FIG. 15B are schematic diagrams illustrating a structure example of an electronic device.

FIG. 16A and FIG. 16B are diagrams illustrating a structure example of a display apparatus.

FIG. 17A to FIG. 17D are diagrams each illustrating a structure example of a pixel circuit.

FIG. 18A to FIG. 18D are diagrams each illustrating a structure example of a pixel circuit.

FIG. 19 is a timing chart showing a driving method of a display apparatus.

FIG. 20A is a block diagram illustrating a structure example of a pixel. FIG. 20B is a diagram illustrating a structure example of a pixel circuit.

FIG. 21A and FIG. 21B are diagrams illustrating a structure example of a display apparatus.

FIG. 22A to FIG. 22D are diagrams illustrating a structure example of a display apparatus.

FIG. 23A to FIG. 23C are diagrams illustrating a structure example of a display apparatus.

FIG. 24 is a block diagram illustrating a structure example of the display apparatus.

FIG. 25A to FIG. 25C are diagrams illustrating structure examples of display apparatuses and a display system.

FIG. 26A to FIG. 26D are diagrams illustrating examples of display apparatuses and images of display systems.

FIG. 27 is a diagram showing an example of an operation method of a display system.

FIG. 28 is a schematic cross-sectional view illustrating a structure example of a display apparatus.

FIG. 29 is a schematic cross-sectional view illustrating a structure example of a display apparatus.

FIG. 30 is a schematic cross-sectional view illustrating a structure example of a display apparatus.

FIG. 31A to FIG. 31C are schematic diagrams illustrating a structure example of a semiconductor device.

FIG. 32A and FIG. 32B are schematic cross-sectional views illustrating a structure example of a semiconductor device.

FIG. 33A is a schematic top view illustrating a structure example of a semiconductor device. FIG. 33B to FIG. 33D are schematic cross-sectional views illustrating a structure example of a semiconductor device.

FIG. 34A to FIG. 34D are schematic cross-sectional views illustrating an example of a method for manufacturing a device.

FIG. 35A to FIG. 35F are schematic cross-sectional views each illustrating a structure example of a light-emitting device.

FIG. 36A to FIG. 36C are schematic cross-sectional views each illustrating a structure example of a light-emitting device.

### MODE FOR CARRYING OUT THE INVENTION

Embodiments will be described below with reference to the drawings. However, the embodiments can be implemented with various modes, and it will be readily appreciated by those skilled in the art that modes and details can be changed in various ways without departing from the spirit and scope of the present invention. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be used interchangeably depending on the case or the circumstances. For example, the term “conductive layer” can be replaced with the term “conductive film”. For another example, the term “insulating film” can be replaced with the term “insulating layer”.

A transistor is a kind of semiconductor element and can achieve a function of amplifying a current or a voltage, switching operation for controlling conduction or non-conduction, and the like. An IGFET (Insulated Gate Field Effect Transistor) and a thin film transistor (TFT) are in the category of a transistor in this specification.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

In this specification and the like, the expression “electrically connected” includes the case where components are connected to each other through an “object having any electric action”. There is no particular limitation on an “object having any electric function” as long as electric signals can be transmitted and received between components that are connected through the object. Examples of the “object having any electric function” are a switching element such as a transistor, a resistor, a coil, a capacitor, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, an off state in an n-channel transistor refers to a state where a voltage V_{gs} between its gate and source is lower than a threshold voltage Vₜₕ (in a p-channel transistor, higher than Vₜₕ).

In this specification and the like, “normally-on characteristics” mean a state where a channel exists and a current flows through a transistor even when no voltage is applied to a gate. Furthermore, “normally-off characteristics” mean a state where a current does not flow through a transistor when no potential or a ground potential is applied to a gate.

In this specification and the like, a top-view shape of a component means the outline of the component in a plan view (also referred to as a top view). A plan view means that the component is observed from a normal direction of a surface where the component is formed or from a normal direction of a surface of a support (e.g., a substrate) where the component is formed.

In this specification and the like, the expression “having substantially the same top-view shapes” means that at least outlines of stacked layers partly overlap with each other. For example, the case of processing an upper layer and a lower layer with use of the same mask pattern or mask patterns that are partly the same is included. However, in some cases, the outlines do not completely overlap with each other and the upper layer is positioned on the inner side of the lower layer or the upper layer is positioned on the outer side of the lower layer; such a case may also be represented by the expression “top surface shapes are substantially the same”. In the case where the top-view shapes are the same or substantially the same, it can be said that the end portions are aligned or substantially aligned with each other or the side end portions are aligned or substantially aligned with each other.

Note that in this specification and the like, the tapered shape refers to a shape such that at least part of a side surface of a component is inclined to a substrate surface or a formation surface. For example, the tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat, and may have a substantially planar shape with a small curvature or a substantially planar shape with slight unevenness.

In this specification and the like, an oxynitride refers to a material that includes more oxygen than nitrogen in its composition. A nitride oxide refers to a material that includes more nitrogen than oxygen in its composition.

The content of hydrogen, oxygen, nitrogen, or any other element can be analyzed by secondary ion mass spectrometry (SIMS) or X-ray photoelectron spectroscopy (XPS). XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than or equal to 0.5 atomic %, or lower than or equal to 1 atomic %). To compare the contents of elements, analysis with a combination of SIMS and XPS is preferably used.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure.

In this specification and the like, a structure in which at least light-emitting layers of light-emitting devices (also referred to as light-emitting elements) having different emission wavelengths are separately formed is sometimes referred to as an SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, a light-emitting device includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

In this embodiment, a semiconductor device of one embodiment of the present invention will be described.

The semiconductor device of one embodiment of the present invention can be used for any of display panels of electronic devices. Thus, the semiconductor device of one embodiment of the present invention can also be referred to as a display apparatus. In particular, the semiconductor device of one embodiment of the present invention can be suitably used for a display panel of a device for AR, a display panel of a device for VR, or a display panel of a wearable device (typically, a watch-type device). Note that the semiconductor device of one embodiment of the present invention includes a display portion, and the pixel density (resolution) of the display portion can be higher than or equal to 1000 ppi and lower than or equal to 10000 ppi. The pixel density can be higher than or equal to 2000 ppi and lower than or equal to 6000 ppi, or higher than or equal to 3000 ppi and lower than or equal to 5000 ppi, for example.

Note that there is no particular limitation on the screen ratio (aspect ratio) of the display portion. For example, the display portion is compatible with a variety of screen ratios such as 1:1 (a square), 4:3, 16:9, and 16:10. Note that there is no particular limitation on the outer shape of the display portion, and a variety of shapes such as a square, a rectangle, and a circle can be employed.

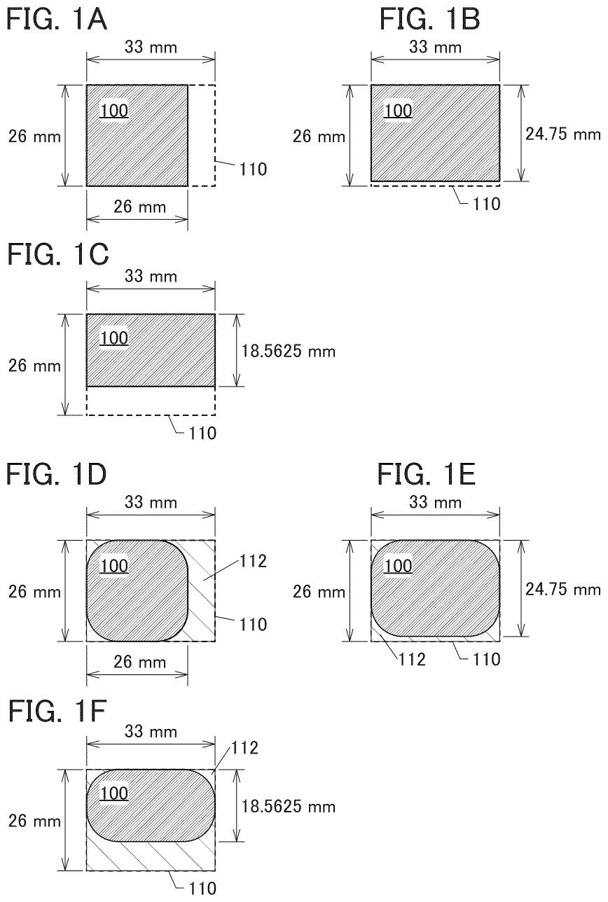

Here, the relation between the size of the semiconductor device and a light-exposure region of a light-exposure apparatus is described with reference to FIG. 1A to FIG. 1F. Note that in the following description, a semiconductor device 100 and a light-exposure region 110 of the light-exposure apparatus are used. In the description of FIG. 1, the semiconductor device 100 is sometimes rephrased as a chip. Alternatively, the semiconductor device 100 is described as a display portion of a display panel in some cases.

### Size of Semiconductor Device and Light-Exposure Region

In the case where the maximum value of the light-exposure region 110 of the light-exposure apparatus is [26 mm×33 mm] as illustrated in FIG. 1A to FIG. 1C, the maximum size of the semiconductor device 100 that can be obtained with one light exposure is [26 mm×26 mm] for an aspect ratio of 1:1, [33 mm×24.75 mm] for an aspect ratio of 4:3, and [33 mm×18.5625 mm] for an aspect ratio of 16:9.

Note that as the maximum value of the light-exposure region 110 of the light-exposure apparatus, [26 mm×33 mm] is presently mainstream; therefore, the description below is considered based on [26 mm×33 mm]. When the maximum value of the light-exposure region 110 is [26 mm×33 mm], the size of the semiconductor device 100 that can be obtained with one light exposure (1 shot) is [26 mm×33 mm].

As illustrated in FIG. 1A to FIG. 1C, the size of the semiconductor device 100 is considered with reference to the light-exposure region 110 of the light-exposure apparatus, whereby the semiconductor device can be fabricated at an optimal manufacturing cost. For example, a stepper and a scanner can be given as the light-exposure apparatus. The wavelength of a light source that can be used for the light-exposure apparatus can be 13 nm (EUV (Extreme Ultra Violet)), 157 nm (F₂), 193 nm (ArF), 248 nm (KrF), 308 nm (XeCl), 365 nm (an i-line), 436 nm (a g-line), or the like. With the light source having a short wavelength, a high-definition semiconductor device or a miniaturized semiconductor device can be obtained.

In the case where the semiconductor device of one embodiment of the present invention is used for a display panel for XR (AR, VR, or the like), the preferred size of a display portion of the display panel is larger than or equal to the human eyeball size (approx. 23 to 24 mm), in which case the whole of eye or the whole of field of view can be covered with the display portion. For example, when the display portion has a diagonal size greater than or equal to 1.0 inch and less than or equal to 2.5 inches, preferably greater than or equal to 1.4 inches and less than or equal to 2.5 inches, further preferably greater than or equal to 1.5 inches and less than or equal to 2.5 inches, the semiconductor device can be placed so that the user's field of view is entirely covered with the display portion. Thus, the use of the semiconductor device of one embodiment of the present invention for a display apparatus or a display system can provide a higher level of one or more of sense of immersion, realistic sensation, and sense of depth.

Since the above-described numerical value corresponds to the maximum size of the display portion, the actual outer dimension of the semiconductor device is larger than or equal to the size of the display portion in some cases. The aspect ratio of the semiconductor device (outer dimension) may be the same as or different from the aspect ratio of the display portion.

Note that the size of the display region is not limited to the above size. For example, in the case where the semiconductor device of one embodiment of the present invention is used for a wearable (e.g., watch-type) device or an electronic device such as a smartphone or a TV, the display region size can exceed 2.5 inches, e.g., can be greater than or equal to 3 inches and less than or equal to 100 inches.

Next, variations of the semiconductor device 100 illustrated in FIG. 1A to FIG. 1C are illustrated in FIG. 1D to FIG. 1F.

FIG. 1D to FIG. 1F each illustrate a shape of the semiconductor device 100 with the corner portions to which fillets are attached (the shape obtained by processing of rounding the corner portion). Although not illustrated, the semiconductor device 100 may have a shape where the corner portions are chamfered (the shape with the corner portions removed). When the semiconductor device 100 have a shape with the corner portions filleted or chamfered, a highly designed display portion can be obtained. When the semiconductor device 100 is used for a device for AR or a device for VR, a lens is sometimes provided in the vicinity of the semiconductor device 100 for screen enlargement or reduction. The lens is provided at a position where light from the semiconductor device 100 passes. A lens generally used has a circular shape in many cases, which is less likely to use the corner portions of the semiconductor device 100 efficiently. Thus, even when the display portion of the semiconductor device 100 is shaped to have rounded corners or chamfered corners, the display quality of an image seen by the user is less likely to be degraded.

In FIG. 1D to FIG. 1F, a region 112 is illustrated as a region where the semiconductor device 100 and the light-exposure region 110 do not overlap with each other. In the region 112, an alignment marker or the like used in light exposure is provided, for example. Providing the alignment marker or the like in the region 112 can increase the manufacturing yield of the semiconductor device, and the number of chips taken out of a silicon wafer (hereinafter also referred to as a Si wafer) can be increased. That is, a semiconductor device whose manufacturing const is low can be provided. As well as the alignment marker, a variety of markers necessary in the manufacturing process, such as a length measuring marker and an evaporation marker, may be provided in the region 112.

### Number of Chips Taken Out

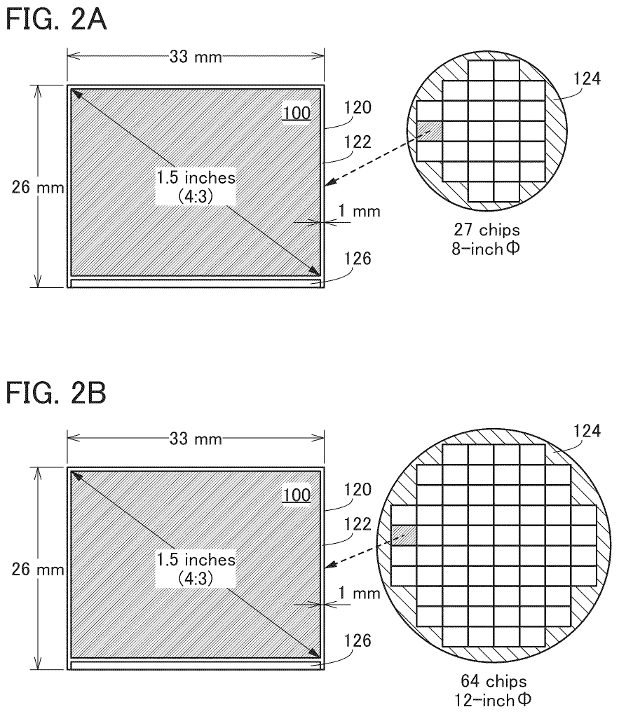

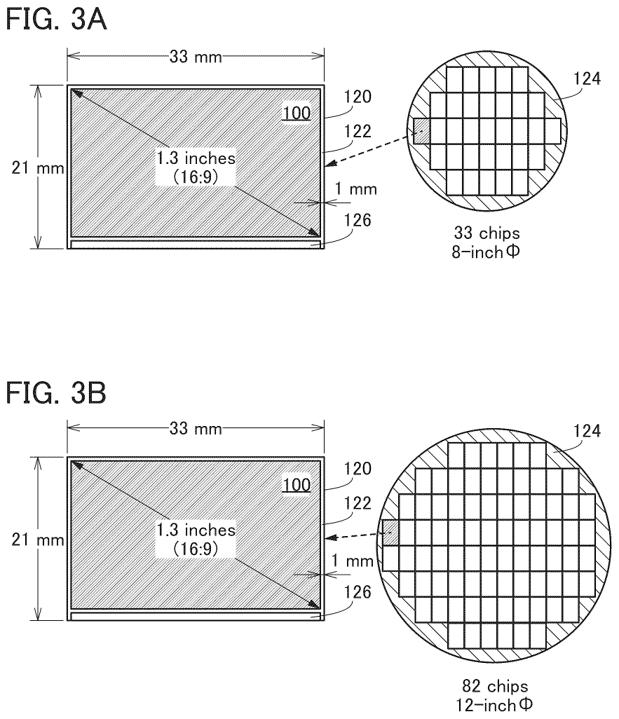

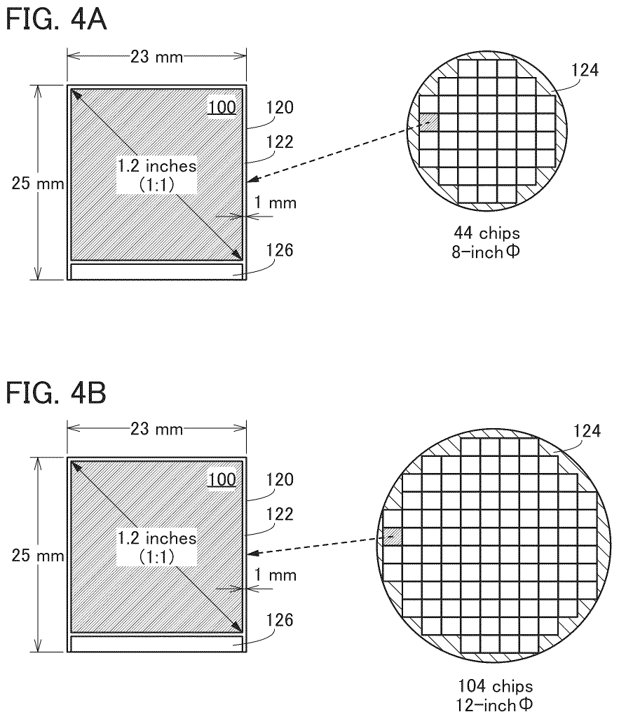

Next, an example of the number of chips taken out of a Si wafer is described. FIG. 2A, FIG. 3A, and FIG. 4A each show the number of chips taken out of one Si wafer assuming that the Si wafer has a diameter Φ of 8 inches, and FIG. 2B, FIG. 3B, and FIG. 4B each show the number of chips taken out of one Si wafer assuming that the Si wafer has a diameter Φ of 12 inches.

In FIG. 2A to FIG. 4B, the description is made using a light-exposure region 120 of the light-exposure apparatus, the semiconductor device 100 that is a semiconductor device provided inside the light-exposure region 120, a sealing region 122 that is a region provided between the semiconductor device 100 and the light-exposure region 120, a terminal region 126 that is a region provided on one side of the light-exposure region 120, and a non-chip region 124 that is not used after taking the chips out of the Si wafer. Note that in this embodiment, the semiconductor device 100 corresponds to the display portion, and the light-exposure region 120 corresponds to the outline of the chip. In addition, a marker region or the like may be provided in the sealing region 122.

Although FIG. 2A to FIG. 4B each exemplify a structure in which a terminal region that can be connected to an external device is provided as the terminal region 126, one embodiment of the present invention is not limited to the structure. For example, a structure that allows a display portion to be connected to an external device with a through electrode or the like extending from the back surface of the chip without providing the terminal region 126 may be employed. With such a structure, the display region can be expanded. Meanwhile, the structure provided with the terminal region 126 as illustrated in FIG. 2A to FIG. 4B is effective in reducing the manufacturing cost because it is not necessary to additionally form a terminal connected to an external terminal.

FIG. 2A and FIG. 2B each illustrate an example in which the sealing region 122 with a width of 1 mm is provided inside the light-exposure region 120 with a size of 33 mm×26 mm. Note that here, the sealing region 122 indicates a region from an edge portion of the semiconductor device 100 to a dividing position of a substrate or a position of a terminal, and does not necessarily indicates a region to which the sealant is applied. In this case, the diagonal size of the semiconductor device 100 is approximately 1.5 inches, and the aspect ratio thereof is 4:3 (hereinafter, such a size is referred to as 1.5 inches (4:3)).

As illustrated in FIG. 2A, 27 chips each of which is 1.5 inches (4:3) can be taken out of the 8-inchΦ Si wafer, and as illustrated in FIG. 2B, 64 chips each of which is 1.5 inches (4:3) can be taken out of a 12-inchΦ Si wafer. In this point, assuming that the area of the 8-inchΦ Si wafer is 100%, the non-chip region 124 illustrated in FIG. 2A accounts for 26%. Furthermore, assuming that the 12-inchΦ Si wafer is 100%, the non-chip region 124 illustrated in FIG. 2B accounts for 22%.

As illustrated in FIG. 2A and FIG. 2B, the number of chips taken out can be increased and the percentage of the non-chip region 124 can be decreased with use of the 12-inchΦ Si wafer as compared with the case of using of the 8-inchΦ Si wafer. The 12-inchΦ Si wafer enables the number of chips taken out to be 2.37 times as large as the number of chips taken out of the 8-inchΦ Si wafer.

FIG. 3A and FIG. 3B each illustrate an example in which the sealing region 122 with a width of 1 mm is provided inside the light-exposure region 120 with a size of 33 mm×21 mm. Here, the structure of the sealing region 122 is similar to those illustrated in FIG. 2A and FIG. 2B. In this case, the diagonal size of the semiconductor device 100 is approximately 1.3 inches, and the aspect ratio thereof is 16:9 (hereinafter, such a size is referred to as 1.3 inches (16:9)).

As illustrated in FIG. 3A, 33 chips each of which is 1.3 inches (16:9) can be taken out of the 8-inchΦ Si wafer, and as illustrated in FIG. 3B, 82 chips each of which is 1.3 inches (16:9) can be taken out of the 12-inchΦ Si wafer. In this point, assuming that the area of the 8-inchΦ Si wafer is 100%, the non-chip region 124 illustrated in FIG. 3A accounts for 27%. Furthermore, assuming that the 12-inchΦ Si wafer is 100%, the non-chip region 124 illustrated in FIG. 3B accounts for 20%.

As illustrated in FIG. 3A and FIG. 3B, the number of chips taken out can be increased and the percentage of the non-chip region 124 can be decreased with use of the 12-inchΦ Si wafer as compared with the case of using the 8-inchΦ Si wafer. The 12-inchΦ Si wafer enables the number of chips taken out to be 2.48 times as large as the number of chips taken out of the 8-inchΦ Si wafer.

FIG. 4A and FIG. 4B each illustrate an example in which the sealing region 122 with a width of 1 mm is provided inside the light-exposure region 120 with a size of 23 mm×25 mm. Here, the structure of the sealing region 122 is similar to those illustrated in FIG. 2A and FIG. 2B. In this case, the diagonal size of the semiconductor device 100 is approximately 1.2 inches, and the aspect ratio thereof is 1:1 (hereinafter, such a region is referred to as 1.2 inches (1:1)).

As illustrated in FIG. 4A, 44 chips each of which is 1.2 inches (1:1) can be taken out of the 8-inchΦ Si wafer, and as illustrated in FIG. 4B, 104 chips each of which is 1.2 inches (1:1) can be taken out of the 12-inchΦ Si wafer. In this point, assuming that the area of the 8-inchΦ Si wafer is 100%, the non-chip region 124 illustrated in FIG. 4A accounts for 19%. Furthermore, assuming that the 12-inchΦ Si wafer is 100%, the non-chip region 124 illustrated in FIG. 4B accounts for 15%.

As illustrated in FIG. 4A and FIG. 4B, the number of chips taken out can be increased and the percentage of the non-chip region 124 can be decreased with use of the 12-inchΦ Si wafer as compared with the case of using the 8-inchΦ Si wafer. The 12-inchΦ Si wafer enables the number of chips taken out to be 2.36 times as large as the number of chips taken out of the 8-inchΦ Si wafer.

Here, Table 1 shows the numbers of chips taken out of the 8-inchΦ Si wafer and the 12-inchΦ Si wafer. Table 1 is a summary of the structures illustrated in FIG. 2A to FIG. 4B.

TABLE 1

| | 4:3 | 16:9 | 1:1 |
|---|---|---|---|
| | (1.5 inches) | (1.3 inches) | (1.2 inches) |
| Number of chips taken | 27 | 33 | 44 |
| out of 8-inchΦ wafer | | | |
| Number of chips taken | 64 | 82 | 104 |
| out of 12-inchΦ wafer | | | |

As shown in Table 1, the number of chips taken out of the Si wafer can be increased as the chip size is reduced. In contrast, for increasing the screen size of the display apparatus, a preferred structure is 4:3, that is, 1.5 inches.

### Structure Example of Semiconductor Device

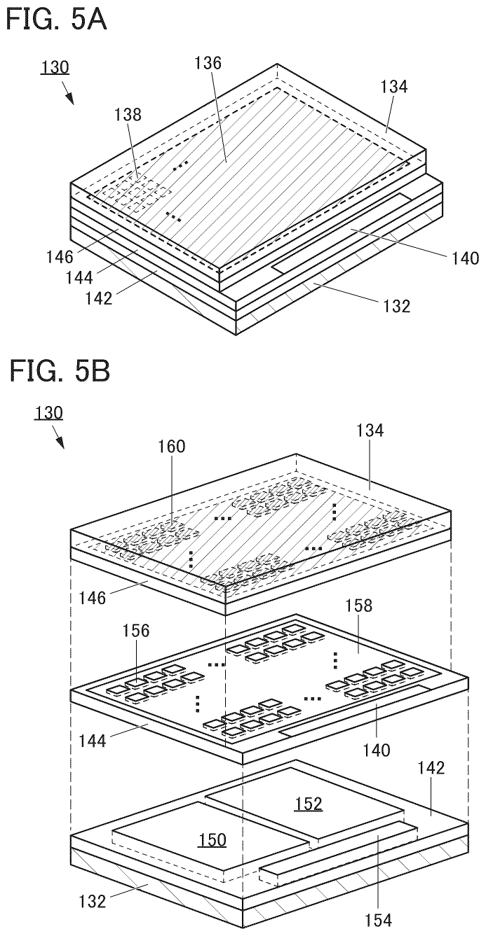

Next, a structure example of a semiconductor device of one embodiment of the present invention is described with reference to FIG. 5A and FIG. 5B. FIG. 5A and FIG. 5B are perspective views illustrating the semiconductor device of one embodiment of the present invention.

A semiconductor device 130 includes a substrate 132 and a substrate 134. The semiconductor device 130 includes a display portion 136 provided between the substrate 132 and the substrate 134. The display portion 136 includes a plurality of pixels 138. The pixel 138 includes a pixel circuit 156 and a light-emitting device 160. The display portion 136 is a region where an image is displayed in the semiconductor device 130.

By arranging the pixels 138 in a matrix of 1920×1080 pixels, the display portion 136 can achieve display with a resolution of a so-called full hi-vision (also referred to as “2K resolution”, “2K1K”, “2K”, or the like). For example, by arranging the pixels 138 in a matrix of 3840×2160 pixels, the display portion 136 can achieve display with a resolution of a so-called ultra hi-vision (also referred to as “4K resolution”, “4K2K”, “4K”, or the like). For example, by arranging the pixels 138 in a matrix of 7680×4320 pixels, the display portion 136 can achieve display with a resolution of a so-called super hi-vision (also referred to as “8K resolution”, “8K4K”, “8K”, or the like). By increasing the number of pixels 138, the display portion 136 that can perform display with 16K or 32K resolution can also be obtained.

Note that there is no particular limitation on the screen ratio (aspect ratio) of the display portion 136. For example, the display portion 136 is compatible with a variety of screen ratios such as 1:1 (a square), 4:3, 16:9, and 16:10.

Various kinds of signals and power supply potentials are input to the semiconductor device 130 from the outside via a terminal portion 140, so that image display can be performed using a display element provided in the display portion 136. Any of a variety of elements can be used as the display element. Typically, a light-emitting device having a function of emitting light, such as an organic EL element or an LED element, can be used. Note that a liquid crystal element, a MEMS (Micro Electro Mechanical Systems) element, or the like may be used instead of the light-emitting device.

A plurality of layers are provided between the substrate 132 and the substrate 134, and each of the layers is provided with a transistor for a circuit operation or a light-emitting device emitting light. A pixel circuit having a function of controlling an operation of the light-emitting device, a driver circuit having a function of controlling the pixel circuit, a functional circuit having a function of controlling the driver circuit, and the like are provided in the plurality of layers. Note that FIG. 5A illustrates a structure in which a layer 142, a layer 144, and a layer 146 are provided between the substrate 132 and the substrate 134.

FIG. 5B is a perspective view schematically illustrating the layers structures provided between the substrate 132 and the substrate 134.

The layer 142 is provided over the substrate 132. The layer 142 includes a driver circuit 150, a functional circuit 152, and an input/output circuit 154. A transistor containing silicon in its channel formation region (also referred to as a “Si transistor” or a “SiFET”) or a transistor containing an oxide semiconductor in its channel formation region (also referred to as an “OS transistor” or an “OSFET”) can be used for the layer 142. With use of the Si transistor for the layer 142, a semiconductor device with enhanced driving capability can be provided. Meanwhile, with use of the OS transistor for the layer 142, a semiconductor device with reduced power consumption can be provided. The OS transistor has a characteristic of an extremely low off-state current. Thus, with use of the OS transistor particularly as a transistor provided in the pixel circuit, analog data written to the pixel circuit can be retained for a long period.

Note that in this embodiment, a structure using a silicon substrate is described as an example of the substrate 132. A silicon substrate is preferable because it has higher thermal conductivity than a glass substrate. By providing the driver circuit 150, the functional circuit 152, and the input/output circuit 154 in the same layer, wirings electrically connecting the driver circuit 150, the functional circuit 152, and the input/output circuit 154 can be short. As a result, charge and discharge time of a control signal used when the functional circuit 152 controls the driver circuit 150 becomes short, leading to a reduction in power consumption. In addition, charge and discharge time during which a signal is supplied from the input/output circuit 154 to the functional circuit 152 and the driver circuit 150 becomes short, leading to a reduction in power consumption.

A transistor containing polycrystalline silicon in its channel formation region (also referred to as a “Poly-Si transistor”) may be provided in the layer 142. As the polycrystalline silicon, low-temperature polysilicon (LTPS) may be used. Note that a transistor containing LTPS in its channel formation region is also referred to as an “LTPS transistor”.

Any of a variety of circuits such as a shift register, a level shifter, an inverter, a latch, an analog switch, and a logic circuit can be used as the driver circuit 150. The driver circuit 150 includes a gate driver circuit, a source driver circuit, or the like, for example. In addition, an arithmetic circuit, a memory circuit, a power supply circuit, and the like may be included. Since the gate driver circuit, the source driver circuit, and other circuits can be placed to overlap with the display portion 136, the width of a non-display region (also referred to as a bezel) provided along the outer periphery of the display portion 136 of the semiconductor device 130 can be extremely narrow compared with the case where the above-described circuits and the display portion 136 are arranged side by side, whereby the semiconductor device 130 can be reduced in size.

The functional circuit 152 has a function of an application processor for controlling the circuits in the semiconductor device 130 and generating signals used for controlling the circuits, for example. In addition, the functional circuit 152 may include a CPU and a circuit for correcting image data, such as an accelerator (e.g., a GPU). The functional circuit 152 may include an LVDS (Low Voltage Differential Signaling) circuit, an MIPI (Mobile Industry Processor Interface) circuit, and a D/A (Digital to Analog) converter circuit, for example, having a function of an interface for receiving image data or the like from the outside of the semiconductor device 130. The functional circuit 152 may include a circuit for compressing and decompressing image data and a power supply circuit, for example.

The layer 144 is provided over the layer 142. The layer 144 includes a pixel circuit group 158 including a plurality of the pixel circuits 156. An OS transistor may be provided in the layer 144. Each of the pixel circuits 156 may include an OS transistor. Note that the layer 144 can be stacked over the layer 142.

A Si transistor may be provided in the layer 144. For example, the pixel circuits 156 may each include a transistor containing single crystal silicon or polycrystalline silicon in its channel formation region. As the polycrystalline silicon, LTPS may be used. For example, the layer 144 can be formed over another substrate and bonded to the layer 142.

As another example, the pixel circuits 156 may each include a plurality of kinds of transistors using different semiconductor materials. In the case where the pixel circuits 156 each include a plurality of kinds of transistors using different semiconductor materials, the transistors may be provided in different layers depending on the kinds of transistors. For example, in the case where the pixel circuits 156 each include a Si transistor and an OS transistor, the Si transistor and the OS transistor may be provided to overlap with each other. Providing the transistors to overlap with each other reduces the area occupied by the pixel circuits 156. Thus, the definition of the semiconductor device 130 can be improved. Note that a structure in which an LTPS transistor and an OS transistor are combined is referred to as LTPO in some cases.

The layer 146 is provided over the layer 144. Over the layer 146, the substrate 134 is provided. The substrate 134 is preferably a light-transmitting substrate or a layer formed of a light-transmitting material. The layer 146 includes the plurality of light-emitting devices 160. The layer 146 can be stacked over the layer 144. As the light-emitting device 160, an organic electroluminescent element (also referred to as an organic EL element) or the like can be used, for example. However, the light-emitting device 160 is not limited thereto, and an inorganic EL element formed of an inorganic material may be used, for example. Note that an “organic EL element” and an “inorganic EL element” are collectively referred to as “EL element” in some cases. The light-emitting device 160 may contain an inorganic compound such as quantum dots. For example, when used for a light-emitting layer, the quantum dots can function as a light-emitting material.

As illustrated in FIG. 5B, the semiconductor device 130 of one embodiment of the present invention can have a structure in which the light-emitting devices 160, the pixel circuits 156, the driver circuit 150, and the functional circuit 152 are stacked; thus, the aperture ratio (effective display area ratio) of the pixels can be extremely high. For example, the pixel aperture ratio can be higher than or equal to 40% and lower than 100%, preferably higher than or equal to 50% and lower than or equal to 95%, further preferably higher than or equal to 60% and lower than or equal to 95%. Furthermore, the pixel circuits 156 can be arranged extremely densely, and thus the pixels can be arranged with an extremely high definition. For example, the pixels can be arranged in the display portion 136 of the semiconductor device 130 (a region where the pixel circuits 156 and the light-emitting devices 160 are stacked) with definition higher than or equal to 1000 ppi, higher than or equal to 2000 ppi, preferably higher than or equal to 3000 ppi, further preferably higher than or equal to 5000 ppi, still further preferably higher than or equal to 6000 ppi, and lower than or equal to 10000 ppi, lower than or equal to 20000 ppi, or lower than or equal to 30000 ppi. In particular, definition higher than or equal to 1000 ppi and lower than or equal to 10000 ppi is preferable.

Such a semiconductor device 130 has extremely high definition, and thus can be suitably used for a device for VR such as a head-mounted display or a glasses-type device for AR. For example, even in the case of a structure in which the display portion of the semiconductor device 130 is viewed through an optical component such as a lens, pixels of the extremely-high-definition display portion included in the semiconductor device 130 are not seen when the display portion is enlarged by the lens, so that display providing a high sense of immersion can be performed.

At least part of this embodiment can be implemented in combination with the other embodiments described in this specification as appropriate.

### Embodiment 2

In this embodiment, an electronic device, a display apparatus, and the like according to one embodiment of the present invention will be described. One embodiment of the present invention can be suitably used also as a wearable electronic device for VR or AR applications, for example.

### Structure Example of Electronic Device

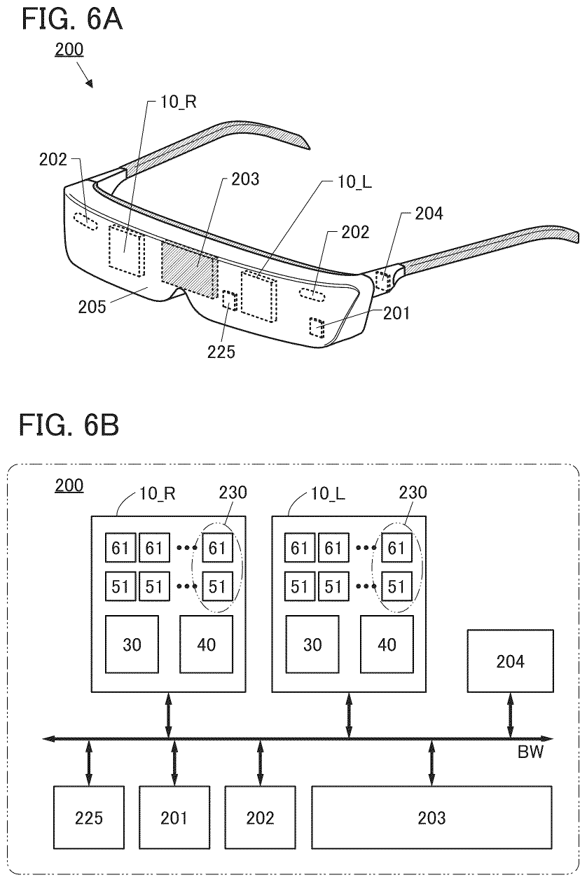

FIG. 6A is a perspective view of a glasses-type electronic device 200 as an example of a wearable electronic device. The electronic device 200 illustrated in FIG. 6A includes, in a housing 205, a pair of display apparatuses 10 (a display apparatus 10_L and a display apparatus 10_R), a motion detection portion 201, gaze detection portions 202, an arithmetic portion 203, and a communication portion 204.

FIG. 6B is a block diagram of the electronic device 200 in FIG. 6A. As in FIG. 6A, the electronic device 200 includes the display apparatus 10_L, the display apparatus 10_R, the motion detection portion 201, the gaze detection portion 202, the arithmetic portion 203, and the communication portion 204, and a variety of signals are transmitted and received between these components through a bus wiring BW. Each of the display apparatus 10_L and the display apparatus 10_R includes a plurality of pixels 230, a driver circuit 30, and a functional circuit 40. One pixel 230 includes one light-emitting element 61 and one pixel circuit 51. Thus, each of the display apparatus 10_L and the display apparatus 10_R includes a plurality of light-emitting elements 61 and a plurality of pixel circuits 51.

The motion detection portion 201 has a function of detecting the motion of the housing 205, i.e., the motion of the head of the user who wears the electronic device 200. The motion detection portion 201 can include a motion sensor using a MEMS technology, for example. As the motion sensor, a three-axis motion sensor, a six-axis motion sensor, or the like can be used. Information on the motion of the housing 205 detected by the motion detection portion 201 may be referred to as first information, motion data, or the like.

The gaze detection portion 202 has a function of obtaining information regarding the user's gaze. Specifically, the gaze detection portion 202 has a function of detecting the user's gaze. The user's gaze, for example, may be obtained by a gaze measurement (eye tracking) method such as a pupil center corneal reflection method or a bright/dark pupil effect method. Alternatively, the user's gaze may be obtained by a gaze measurement method using a laser, an ultrasonic wave, or the like. Alternatively, the user's gaze may be detected using an imaging element typified by an image sensor. Examples of the image sensor include a CMOS (Complementary Metal Oxide Semiconductor) image sensor and a CCD (Charge Coupled Device) image sensor.

The arithmetic portion 203 has a function of calculating the user's gaze point by using a gaze detection result in the gaze detection portion 202. That is, an object the user is gazing in the image being displayed on the display apparatus 10_L and the display apparatus 10_R can be found. In addition, whether or not the user is gazing at a part other than the screen can be detected. Note that information regarding the user's gaze obtained by the gaze detection portion 202 (the gaze detection result) is referred to as second information, gaze information, or the like in some cases.

The arithmetic portion 203 has a function of performing drawing processing (arithmetic process of image data) in accordance with the motion of the housing 205. The arithmetic portion 203 performs the drawing processing in accordance with the motion of the housing 205 with use of the first information and image data that is input from the outside through the communication portion 204. As the image data, for example, a 360-degree omnidirectional image data can be used. The 360-degree omnidirectional image data is image data captured by a celestial sphere camera (an omnidirectional camera or a 360° camera), image data generated by computer graphics, or the like, for example. The arithmetic portion 203 has a function of converting the 360-degree omnidirectional image data on the basis of the first information into image data that can be displayed on the display apparatus 10_L and the display apparatus 10_R.

The arithmetic portion 203 has a function of determining the size and shape of a plurality of regions that are set for each of the display portions of the display apparatus 10_L and the display apparatus 10_R with use of the second information. Specifically, the arithmetic portion 203 calculates a gaze point on the display portion on the basis of the second information and sets a first region S1 to a third region S3 and the like described later on the display portion with use of the gaze point as a reference.

A microprocessor such as a central processing unit (CPU), a DSP (Digital Signal Processor), or a GPU (Graphics Processing Unit) can be used alone or in combination as the arithmetic portion 203. A structure may be employed in which such a microprocessor is obtained with a PLD (Programmable Logic Device) such as an FPGA (Field Programmable Gate Array) or an FPAA (Field Programmable Analog Array).

The arithmetic portion 203 interprets and executes instructions from various programs with use of a processor to perform various kinds of data processing and program control. The programs that can be executed by the processor may be stored in a memory region included in the processor or a memory portion which is additionally provided. As the memory portion, a memory device using a nonvolatile memory element, such as a flash memory, an MRAM (Magnetoresistive Random Access Memory), a PRAM (Phase change RAM), an ReRAM (Resistive RAM), or an FeRAM (Ferroelectric RAM); a memory device using a volatile memory element, such as a DRAM (Dynamic RAM) and an SRAM (Static RAM); or the like may be used, for example.

The communication portion 204 has a function of communicating with an external device by wire or wirelessly to obtain a variety of data, including image data. The communication portion 204 is provided with a high frequency circuit (RF circuit), for example, to transmit and receive an RF signal. The high frequency circuit is a circuit for performing mutual conversion between an electromagnetic signal and an electrical signal in a frequency band that is set by national laws to perform wireless communication with another communication apparatus using the electromagnetic signal. In the case of performing wireless communication, it is possible to use, as a communication protocol or a communication technology, a communication standard such as LTE (Long Term Evolution), GSM (Global System for Mobile Communication: registered trademark), EDGE (Enhanced Data Rates for GSM Evolution), CDMA 2000 (Code Division Multiple Access 2000), or WCDMA (Wideband Code Division Multiple Access: registered trademark), or a communication standard developed by IEEE such as Wi-Fi (registered trademark), Bluetooth (registered trademark), or ZigBee (registered trademark). The third-generation mobile communication system (3G), the fourth-generation mobile communication system (4G), or the fifth-generation mobile communication system (5G) defined by the International Telecommunication Union (ITU) or the like can be used.

The communication portion 204 may include an external port such as a LAN (Local Area Network) connection terminal, a digital broadcast-receiving terminal, or an AC adaptor connection terminal.

Each of the display apparatus 10_L and the display apparatus 10_R includes the plurality of light-emitting elements 61, the plurality of pixel circuits 51, the driver circuit 30, and the functional circuit 40. The pixel circuit 51 has a function of controlling light emission of the light-emitting element 61. The driver circuit 30 has a function of controlling the pixel circuit 51.

Information on the plurality of regions in the display portion of the display apparatus 10 determined by the arithmetic portion 203 can be used for driving such that the resolution differs from region to region. The functional circuit 40 has a function of controlling the driver circuit 30 so that the display resolution is high in a region close to a gaze point and controlling the driver circuit 30 so that the display resolution is low in a region distant from the gaze point.

For example, when rewriting of image data is performed for every other pixel or every other plurality of pixels, display with low resolution can be performed. By reducing the number of pixels where image data is rewritten, power consumption of the display apparatus can be reduced.

As in one embodiment of the present invention, the arithmetic portion 203 may be provided in addition to the functional circuit 40. Providing the arithmetic portion 203 makes it possible for the arithmetic portion 203 to perform heavy-load arithmetic processing such as drawing processing in accordance with the motion of the housing 205 and determining a plurality of regions described later (the first region S1 to the third region S3) in accordance with a gaze point. Meanwhile, the functional circuit 40 performs the processing of controlling the driver circuit 30, so that reductions in circuit size and power consumption can be achieved. A wearable electronic device in particular is required to detect the motion of the user's head, gaze, or the like in a short period, and thus high speed arithmetic processing is required, leading to high power consumption for an arithmetic operation. By contrast, in one embodiment of the present invention, the function of outputting a control signal for the driver circuit 30 is separated from the arithmetic portion 203 and can be performed by the functional circuit 40. This prevents concentration of load on one arithmetic portion and can reduce the load on the arithmetic portion. Thus, low power consumption as a whole can be achieved.

The electronic device 200 may be provided with a sensor 225. The sensor 225 has a function of obtaining information on one or more of the senses of sight, hearing, touch, taste, and smell of the user. Specifically, the sensor 225 has a function of sensing or measuring one or more of the following information: force, displacement, position, speed, acceleration, angular velocity, rotational frequency, distance, light, magnetism, temperature, sound, time, electric field, current, voltage, electric power, radiation, humidity, gradient, oscillation, smell, and infrared rays. The electronic device 200 may be provided with one or more sensors 225.

With use of the sensor 225, ambient temperature, humidity, illumination, odor, and the like may be measured. Furthermore, with use of the sensor 225, information for personal authentication using a fingerprint, a palm print, an iris, a retina, a shape of a blood vessel (including a shape of a vein and a shape of an artery), a face, or the like may be obtained, for example. Moreover, with use of the sensor 225, the number of blinks, eyelid behavior, pupil size, body temperature, pulse, oxygen saturation in blood, or the like of the user may be measured, so that the user's fatigue level, health condition, and the like can be detected. The electronic device 200 may sense the user's fatigue level, health condition, and the like and display an alert or the like on the display apparatus 10.

The operation of the electronic device 200 may be controlled by detecting the user's gaze and eyelid movement. Since the user does not need to touch and operate the electronic device 200, an input operation or the like can be achieved with holding nothing in both hands (in a state where both hands are free).

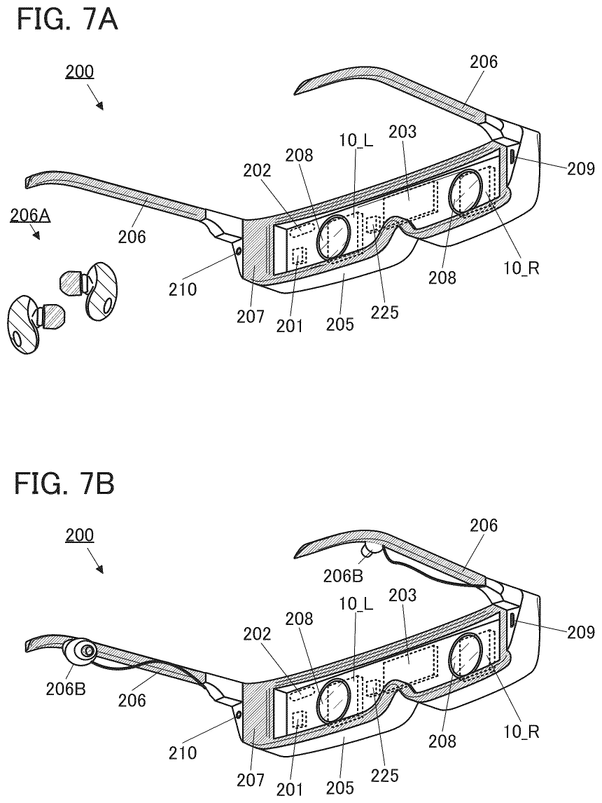

FIG. 7A is a perspective view illustrating the electronic device 200. In FIG. 7A, the housing 205 of the electronic device 200 includes, for example, a wearing portion 206, a cushion 207, a pair of lenses 208, and the like, in addition to the pair of the display apparatus 10_L and the display apparatus 10_R and the arithmetic portion 203. The lens 208 is provided at a position where light from the display apparatus 10_L or the display apparatus 10_R passes. In other words, the pair of the display apparatus 10_L and the display apparatus 10_R are positioned inside the housing 205 so as to be seen through the lenses 208.

In addition, an input terminal 209 and an output terminal 210 are provided in the housing 205 illustrated in FIG. 7A. To the input terminal 209, a cable for supplying an image signal (image data) from a video output device or the like, power for charging a battery (not illustrated) provided in the housing 205, or the like can be connected. The output terminal 210 can function as, for example, an audio output terminal to which earphones, headphones, or the like can be connected.

In addition, the housing 205 preferably includes a mechanism by which the left and right positions of the lenses 208 and the display apparatus 10_L and the display apparatus 10_R can be adjusted to the optimal positions in accordance with the positions of the user's eyes. Moreover, the housing 205 preferably includes a mechanism for adjusting focus by changing the distance between the lenses 208 and the display apparatus 10_L and the display apparatus 10_R.

The cushion 207 is a portion to be in contact with the user's face (forehead, cheek, or the like). When the cushion 207 is in close contact with the user's face, external light incidence (light leakage) can be prevented, which increases the sense of immersion. A soft material is preferably used for the cushion 207 so that the cushion 207 is in close contact with the user's face when the user wears the electronic device 200. Using such a material is preferable because it provides a soft texture and the user does not feel cold when wearing the electronic device in a cold season, for example. The member to be in contact with the user's skin, such as the cushion 207 or the wearing portion 206, is preferably detachable, in which case cleaning or replacement can be easily performed.

The electronic device of one embodiment of the present invention may further include earphones 206A. The earphones 206A include a communication portion (not illustrated) and have a wireless communication function. The earphones 206A can output audio data with the wireless communication function. The earphones 206A may include a vibration mechanism to function as bone-conduction earphones.

The earphones 206A can be connected to the wearing portion 206 directly or by wire like earphones 206B illustrated in FIG. 7B. The earphones 206B and the wearing portion 206 may each have a magnet. This is preferable because the earphones 206B can be fixed to the wearing portion 206 with magnetic force and thus can be easily housed.

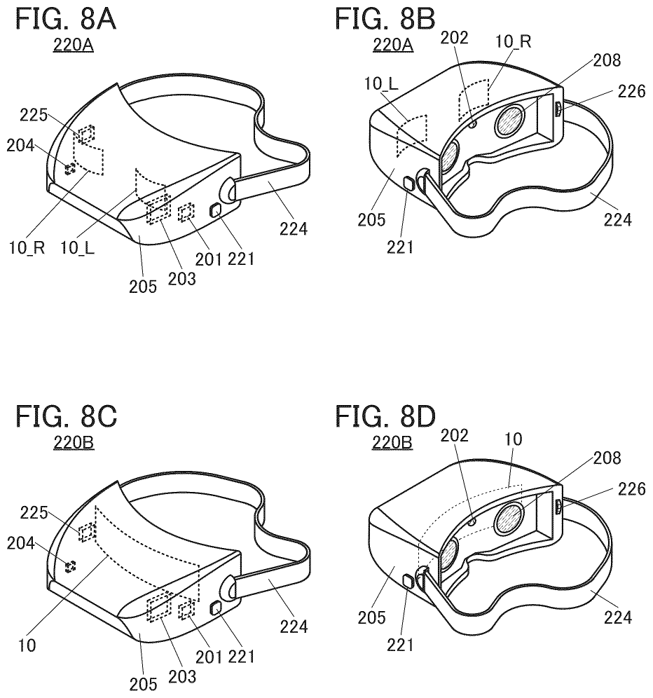

FIG. 8A and FIG. 8B are perspective views of a goggles-type electronic device 220A. FIG. 8A and FIG. 8B each illustrate an example in which a pair of display apparatuses 10 (including the display apparatus 10_R and the display apparatus 10_L) that are curved are provided. The electronic device 220A further includes the motion detection portion 201, the gaze detection portion 202, the arithmetic portion 203, the communication portion 204, the housing 205, the lens 208, the sensor 225, and the like. The electronic device 220A further includes an operation button 221, a wearing tool 224, a dial 226, and the like.

Since the two display apparatuses 10 are included, the user's eyes can see their respective display apparatuses. This allows a high-resolution video to be displayed even when three-dimensional display using parallax is performed. In addition, the display apparatus 10 is curved around an arc with the user's eye as an approximate center. This allows a uniform distance between the user's eye and the display surface of the display apparatus 10; thus, the user can see a more natural image. Even when having what is called viewing angle dependence where the luminance or chromaticity of light changes depending on a viewing angle, the display apparatus 10 can have a structure in which the user's eye is positioned in the normal direction of the display surface of the display apparatus 10; accordingly, the influence of the viewing angle dependence particularly in the horizontal direction can be practically ignored, enabling display of a more realistic video.

The operation button 221 has a function of a power button or the like. A button other than the operation button 221 may be included.

As illustrated in FIG. 8B, a lens 208 is provided between the display apparatus 10 and the user's eyes. FIG. 8B illustrates an example where the dial 226 for changing the positions of the lenses for visibility adjustment is provided. In addition, in the case where the electronic device 220A has an autofocus function, the dial 226 for visibility adjustment is not necessarily provided.

FIG. 8C and FIG. 8D illustrate an electronic device 220B including one display apparatus 10. Such a structure can reduce the number of components.

The display apparatus 10 can display an image for the right eye and an image for the left eye side by side on a right region and a left region, respectively. Thus, a three-dimensional image using binocular disparity can be displayed.

One image that can be seen by both eyes may be displayed on the entire display apparatus 10. A panorama image can thus be displayed from end to end of the field of view, which can provide a stronger sense of reality.

The display apparatus 10 may display two different images side by side using parallax, or may display two same images side by side without using parallax. Alternatively, a structure may be employed in which one image is displayed on the display apparatus and the same image (i.e., the same display region) can be seen with both eyes through the lens 208.

The display apparatus of one embodiment of the present invention can be used for the display apparatus 10. Since the display apparatus of one embodiment of the present invention has an extremely high definition, even when an image is magnified using the lens 208, the pixels are not perceived by the user, and thus a more realistic image can be displayed.

### Structure Example of Display Apparatus

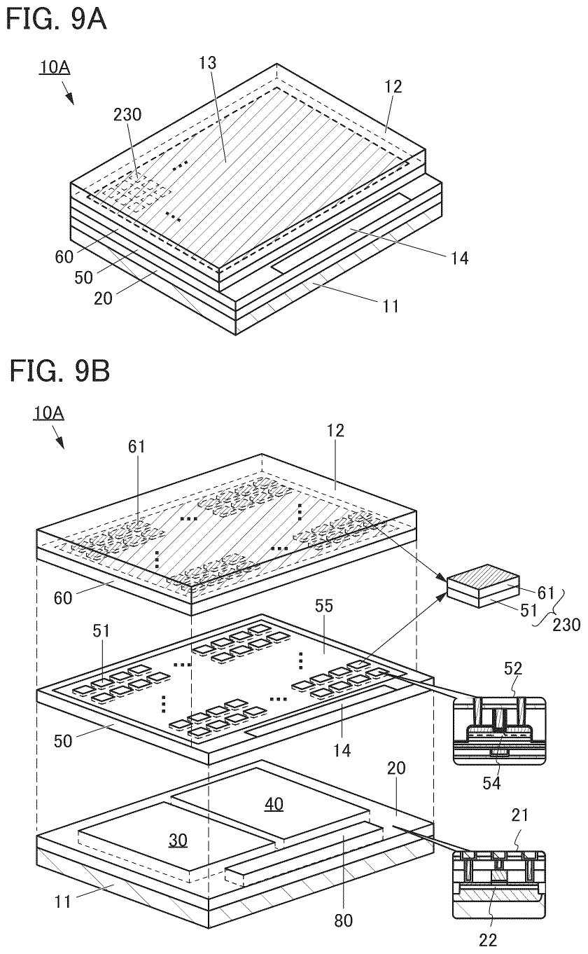

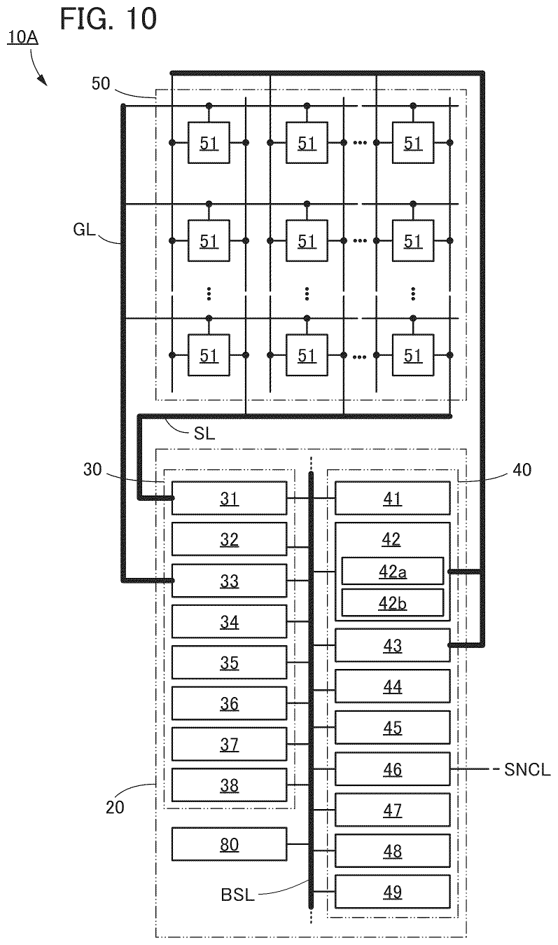

A structure of a display apparatus 10A that can be used for the display apparatus 10_L and the display apparatus 10_R illustrated in FIG. 6A and FIG. 6B is described with reference to FIG. 9A, FIG. 9B, and FIG. 10.

FIG. 9A is a perspective view of the display apparatus 10A that can be used as the display apparatus 10_L and the display apparatus 10_R illustrated in FIG. 6A and FIG. 6B.

Note that portions similar to those in Embodiment 1, <Structure example of semiconductor device>, and FIG. 5A and FIG. 5B are not described in some cases.

The display apparatus 10A includes a substrate 11 and a substrate 12. The display apparatus 10A includes a display portion 13 provided between the substrate 11 and the substrate 12. The display portion 13 includes the plurality of pixels 230. The pixels 230 each include the pixel circuit 51 and the light-emitting element 61. The display portion 13 is a region where an image is displayed in the display apparatus 10A.

The above description can be referred to for the preferred ranges of the resolution, definition, aperture ratio, aspect ratio, and the like of the display apparatus 10A.

In this specification and the like, the term “element” can be replaced with the term “device” in some cases. For example, a display element, a light-emitting element, and a liquid crystal element can be rephrased as a display device, a light-emitting device, and a liquid crystal device, respectively, for example.

A pixel circuit having a function of controlling an operation of the display element, a driver circuit having a function of controlling the pixel circuit, a functional circuit having a function of controlling the driver circuit, and the like are provided between the substrate 11 and the substrate 12.

FIG. 9B is a perspective view schematically illustrating the structures of the layers provided between the substrate 11 and the substrate 12.

A layer 20 is provided over the substrate 11. The layer 20 includes the driver circuit 30, the functional circuit 40, and an input/output circuit 80. The layer 20 includes transistors 21 each containing silicon in a channel formation region 22. A layer 50 is provided over the layer 20. The layer 50 includes a pixel circuit group 55 including the plurality of pixel circuits 51.

The transistor 21 can be a transistor containing single crystal silicon in its channel formation region (also referred to as a “c-Si transistor”), for example. This is preferable because the on-state current of the transistor can be increased and the circuits included in the layer 20 can be driven at high speed. The Si transistor can be formed by microfabrication to have a channel length greater than or equal to 3 nm and less than or equal to 10 nm, for example; thus, a CPU, an accelerator such as a GPU, an application processor, or the like can be integral with the display portion in the display apparatus 10A.

A transistor containing polycrystalline silicon such as low-temperature polysilicon may be used for the layer 20. An OS transistor may be provided in the layer 20 as necessary.

In the case where a thin film transistor with a thin film as a semiconductor in which a channel is formed, such as a Poly-Si transistor, an LTPS transistor, or an OS transistor, is provided in the layer 20, an insulating substrate that is more inexpensive than the semiconductor substrate can be used as the substrate. When the thin film transistor is provided over a flexible substrate, a bendable display apparatus can provided.

The above description can be referred to for the preferred modes of the driver circuit 30, the functional circuit 40, the pixel circuit group 55 including the plurality of pixel circuits 51, and the like.

It is preferable to use, as the transistor 52 that is an OS transistor, a transistor including an oxide containing at least one of indium, an element M (the element M is aluminum, gallium, yttrium, or tin), and zinc in a channel formation region 54. Such an OS transistor has a characteristic of an extremely low off-state current. Thus, it is particularly preferable to use the OS transistor as a transistor provided in the pixel circuit, in which case analog data written to the pixel circuit can be retained for a long period.

A layer 60 is provided over the layer 50. The above description can be referred to for the preferred modes of the substrate 12, the plurality of light-emitting elements 61, and the like included in the layer 60.

The display apparatus 10A described above has an extremely high definition, and thus can be suitably used for a device for VR such as a head-mounted display or a glasses-type device for AR. For example, even in the case of a structure in which the display portion of the display apparatus 10A is seen through an optical member such as a lens, pixels of the extremely-high-definition display portion included in the display apparatus 10A are not seen when the display portion is magnified by the lens, so that display providing a high sense of immersion can be performed.

Note that in the case where the display apparatus 10A is used as a wearable display apparatus for VR or AR, the display portion 13 can have a diagonal size greater than or equal to 0.1 inches and less than or equal to 5.0 inches, preferably greater than or equal to 0.5 inches and less than or equal to 2.0 inches, further preferably greater than or equal to 1 inch and less than or equal to 1.7 inches. For example, the display portion 13 may have a diagonal size of 1.5 inches or approximately 1.5 inches. When the display portion 13 has a diagonal size less than or equal to 2.0 inches, the number of times of light exposure treatment using a light exposure apparatus (typically, a scanner apparatus) can be one; thus, the productivity of a manufacturing process can be improved.

The display apparatus 10A according to one embodiment of the present invention can be used for an electronic device other than a wearable electronic device. In that case, the display portion 13 can have a diagonal size greater than 2.0 inches. The structure of transistors used in the pixel circuits 51 may be selected as appropriate depending on the diagonal size of the display portion 13. In the case where single crystal Si transistors are used in the pixel circuits 51, for example, the diagonal size of the display portion 13 is preferably greater than or equal to 0.1 inches and less than or equal to 3 inches. In the case where LTPS transistors are used in the pixel circuits 51, the diagonal size of the display portion 13 is preferably greater than or equal to 0.1 inches and less than or equal to 30 inches, further preferably greater than or equal to 1 inch and less than or equal to 30 inches. In the case where LTPO transistors are used in the pixel circuits 51, the diagonal size of the display portion 13 is preferably greater than or equal to 0.1 inches and less than or equal to 50 inches, further preferably greater than or equal to 1 inch and less than or equal to 50 inches. In the case where OS transistors are used in the pixel circuits 51, the diagonal size of the display portion 13 is preferably greater than or equal to 0.1 inches and less than or equal to 200 inches, further preferably greater than or equal to 50 inches and less than or equal to 100 inches.

An increase in size of a display apparatus using single crystal Si transistors is extremely difficult because an increase in size of a single crystal Si substrate is difficult. Furthermore, in the case where LTPS transistors are used in a display apparatus, LTPS transistors are unlikely to respond to an increase in size (typically to a screen diagonal size greater than 30 inches) because a laser crystallization apparatus is used in the manufacturing process. By contrast, since the manufacturing process does not necessarily require a laser crystallization apparatus or the like or can be performed at a relatively low process temperature (typically, lower than or equal to 450° C.), OS transistors can be used for a display apparatus with a relatively large area (typically, a diagonal size greater than or equal to 50 inches and less than or equal to 100 inches). In addition, LTPO is applicable to a diagonal size of a display portion which is midway between the case of using LTPS transistors and the case of using OS transistors (typically, a diagonal size greater than or equal to 1 inch and less than or equal to 50 inches).

Specific structure examples of the driver circuit 30 and the functional circuit 40 will be described with reference to FIG. 10. FIG. 10 is a block diagram illustrating a plurality of wirings connecting the pixel circuits 51, the driver circuit 30, and the functional circuit 40 in the display apparatus 10A, a bus wiring in the display apparatus 10A, and the like.

In the display apparatus 10A shown in FIG. 10, the plurality of pixel circuits 51 are arranged in a matrix in the layer 50.

Furthermore, the driver circuit 30, the functional circuit 40, and the input/output circuit 80 are provided in the layer 20 in the display apparatus 10A shown in FIG. 10. The driver circuit 30 includes, for example, a source driver circuit 31, a digital-analog converter (DAC) circuit 32, a gate driver circuit 33, a level shifter 34, an amplifier circuit 35, an inspection circuit 36, a video generation circuit 37, and a video distribution circuit 38. The functional circuit 40 includes, for example, a memory device 41, a GPU (AI accelerator) 42, an EL correction circuit 43, a timing generation circuit 44, a CPU 45, a sensor controller 46, a power supply circuit 47, a temperature sensor 48, and a luminance correction circuit 49. The functional circuit 40 has a function of an application processor.

The input/output circuit 80 is compatible with a transmission method such as LVDS (Low Voltage Differential Signaling), and the input/output circuit 80 has a function of dividing control signals, image data, and the like input via the terminal portion 14 for the driver circuit 30 and the functional circuit 40. Furthermore, the input/output circuit 80 has a function of outputting information of the display apparatus 10A to the outside via the terminal portion 14.

In the display apparatus 10A in FIG. 10, an example of a structure in which the circuits included in the driver circuit 30, the circuits included in the functional circuit 40, and the input/output circuit 80 are each electrically connected to a bus wiring BSL is illustrated.

The source driver circuit 31 has a function of transmitting image data to the pixel circuits 51 included in the pixels 230, for example. Thus, the source driver circuit 31 is electrically connected to the pixel circuits 51 through a wiring SL. Note that a plurality of source driver circuits 31 may be provided.

The digital-analog converter circuit 32 has a function of converting image data that has been digitally processed by a GPU, a correction circuit, or the like described later, into analog data, for example. The image data converted into analog data is amplified by the amplifier circuit 35 such as an operational amplifier and is transmitted to the pixel circuits 51 via the source driver circuit 31. Note that the image data may be transmitted to the source driver circuit 31, the digital-analog converter circuit 32, and the pixel circuits 51 in this order. The digital-analog converter circuit 32 and the amplifier circuit 35 may be included in the source driver circuit 31.

The gate driver circuit 33 has a function of selecting a pixel circuit to which image data is to be transmitted among the pixel circuits 51, for example. Thus, the gate driver circuit 33 is electrically connected to the pixel circuits 51 through a wiring GL. Note that a plurality of gate driver circuits 33 may be provided such that the number of the gate driver circuits 33 corresponds to the number of the source driver circuits 31.

The level shifter 34 has a function of converting signals to be input to the source driver circuit 31, the digital-analog converter circuit 32, the gate driver circuit 33, and the like into appropriate levels, for example.

The memory device 41 has a function of storing image data to be displayed by the pixel circuits 51, for example. Note that the memory device 41 can be configured to store the image data as digital data or analog data.

In the case where the memory device 41 stores image data, the memory device 41 is preferably a nonvolatile memory. In that case, a NAND memory or the like can be used as the memory device 41, for example.

In the case where the memory device 41 stores temporary data generated in the GPU 42, the EL correction circuit 43, the CPU 45, or the like, the memory device 41 is preferably a volatile memory. In that case, an SRAM, a DRAM, or the like can be used as the memory device 41, for example.

The GPU 42 has a function of performing processing for outputting, to the pixel circuits 51, image data read from the memory device 41, for example. Specifically, the GPU 42 is configured to perform pipeline processing in parallel and thus can perform high-speed processing of image data to be output to the pixel circuits 51. The GPU 42 can also have a function of a decoder for decoding an encoded image.

The functional circuit 40 may include a plurality of circuits that can improve the display quality of the display apparatus 10A. As such circuits, for example, correction (toning and dimming) circuits that detect color irregularity of a displayed image and correct the color irregularity to obtain an optimal image may be provided. In the case where a light-emitting device utilizing organic EL is used as the display element, for example, an EL correction circuit that corrects image data in accordance with characteristics of the light-emitting device may be provided in the functional circuit 40. The functional circuit 40 includes the EL correction circuit 43 as an example.

The above-described image correction may be performed using artificial intelligence. For example, a current flowing in a pixel circuit (or a voltage applied to the pixel circuit) may be monitored and obtained, a displayed image may be obtained with an image sensor or the like, the current (or voltage) and the image may be used as input data in an arithmetic operation of the artificial intelligence (e.g., an artificial neural network), and the output result may be used to judge whether the image should be corrected.

Such an arithmetic operation of artificial intelligence can be applied to not only image correction but also upconversion for increasing the definition of image data. As an example, FIG. 10 illustrates the GPU 42 that includes blocks for performing arithmetic operations for various kinds of correction (e.g., color irregularity correction 42a and upconversion 42b).

The upconversion processing of image data can be performed with an algorithm selected from a Nearest neighbor method, a Bilinear method, a Bicubic method, a RAISR (Rapid and Accurate Image Super-Resolution) method, an ANR (Anchored Neighborhood Regression) method, an A+ method, an SRCNN (Super-Resolution Convolutional Neural Network) method, and the like.

The algorithm used for the upconversion processing may be different for each region determined in accordance with a gaze point. For example, upconversion processing for a region including the gaze point and the vicinity of the gaze point is performed using an algorithm with a low processing speed but high accuracy, and upconversion processing for a region other than the region is performed using an algorithm with low accuracy but a high processing speed. In that case, the time required for upconversion processing can be shortened. In addition, power consumption required for upconversion processing can be reduced.

Without limitation to upconversion processing, downconversion processing for decreasing the definition of image data may be performed. In the case where the definition of image data is higher than the definition of the display portion 13, part of the image data is not displayed on the display portion 13, in some cases. In that case, downconversion processing enables the entire image data to be displayed on the display portion 13.

The timing generation circuit 44 has a function of controlling driving frequency (e.g., frame frequency, frame rate, or refresh rate) for displaying an image, for example. In the case where a still image is displayed on the display apparatus 10A, for example, the driving frequency is lowered by the timing generation circuit 44, so that power consumption of the display apparatus 10A can be reduced. The driving with a lowered driving frequency for reducing power consumption of a display apparatus may be referred to as idling stop (IDS) driving.

The CPU 45 has a function of performing general-purpose processing such as execution of an operating system, control of data, and execution of various kinds of arithmetic operations and programs, for example. The CPU 45 has a role in, for example, giving an instruction for a writing operation or a reading operation of image data in the memory device 41, an operation for correcting image data, an operation of a later-described sensor, or the like. Furthermore, the CPU 45 may have a function of transmitting a control signal to at least one of the circuits included in the functional circuit 40, for example.

The sensor controller 46 has a function of controlling a sensor, for example. FIG. 10 illustrates a wiring SNCL as a wiring for electrical connection to the sensor.

The sensor can be, for example, a touch sensor that can be provided in the display portion 13. Alternatively, the sensor can be an illuminance sensor, for example.

The power supply circuit 47 has a function of generating voltages to be supplied to the pixel circuits 51, the driver circuit 30, and the functional circuit 40, for example. Note that the power supply circuit 47 may have a function of selecting a circuit to which a voltage is to be supplied. The power supply circuit 47 can stop supply of a voltage to the CPU 45, the GPU 42, and the like during a period in which a still image is displayed so that the power consumption of the whole display apparatus 10A is reduced, for example.

As described above, the display apparatus of one embodiment of the present invention can have a structure in which display elements, pixel circuits, a driver circuit, and the functional circuit 40 are stacked. The driver circuit and the functional circuit, which are peripheral circuits, can be provided so as to overlap with the pixel circuits and thus the width of the bezel can be made extremely small, so that the display apparatus can be downsized. The display apparatus of one embodiment of the present invention has a structure in which circuits are stacked and thus wirings connecting the circuits can be shortened, resulting in a reduction in weight of the display apparatus. The display apparatus of one embodiment of the present invention can include a display portion with an increased definition of pixels; thus, the display apparatus can have high display quality.

### Structure Example of Display Module

Next, a structure example of a display module including the display apparatus 10A is described.

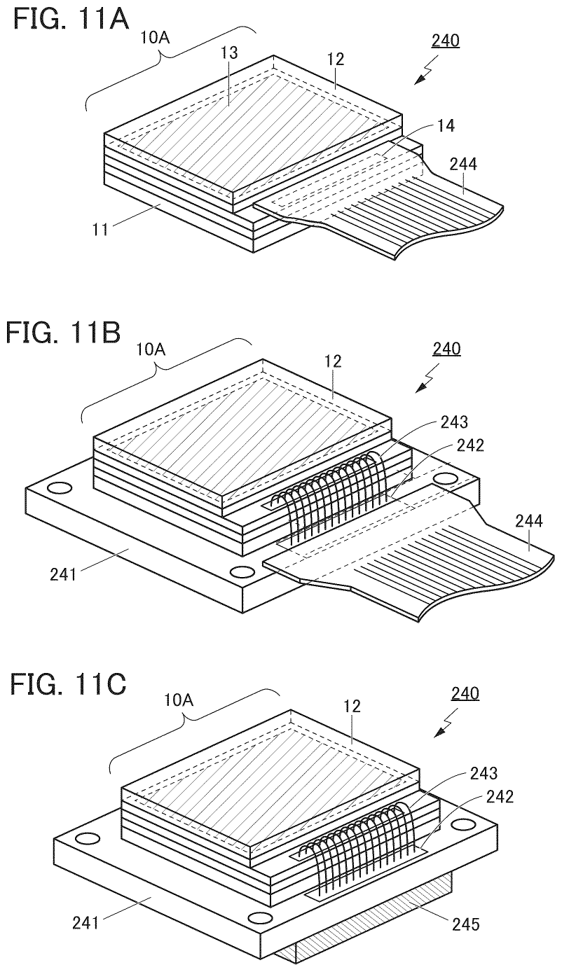

FIG. 11A to FIG. 11C are each a perspective view of a display module 240. The display module 240 has a structure in which an FPC (Flexible printed circuit) 244 is provided on the terminal portion 14 of the display apparatus 10A. The FPC 244 has a structure in which a film formed of an insulator is provided with a wiring. The FPC 244 is flexible. The FPC 244 functions as a wiring for supplying a video signal, a control signal, a power supply potential, and the like to the display apparatus 10A from the outside. An IC may be mounted on the FPC 244.

The display module 240 illustrated in FIG. 11B has a structure in which the display apparatus 10A is provided over a printed wiring board 241. The printed wiring board 241 includes wirings inside a substrate formed of an insulator and/or on the surface of the substrate.

In the display module 240 illustrated in FIG. 11B, the terminal portion 14 of the display apparatus 10A is electrically connected to a terminal portion 242 of the printed wiring board 241 through a wire 243. The wire 243 can be formed in wire bonding. Ball bonding or wedge bonding can be used as the wire bonding.

After the wire 243 is formed, the wire 243 may be covered with a resin material or the like. Note that the display apparatus 10A and the printed wiring board 241 may be electrically connected to each other by a method other than the wire bonding. For example, the display apparatus 10A and the printed wiring board 241 may be electrically connected to each other using an anisotropic conductive adhesive or a bump.

In the display module 240 illustrated in FIG. 11B, the terminal portion 242 of the printed wiring board 241 is electrically connected to the FPC 244. In the case where the electrode pitch in the terminal portion 14 of the display apparatus 10A is different from the electrode pitch in the FPC 244, for example, the terminal portion 14 may be electrically connected to the FPC 244 via the printed wiring board 241. Specifically, the interval (pitch) between a plurality of electrodes in the terminal portion 14 can be converted into the interval between a plurality of electrodes in the terminal portion 242 using wirings formed on the printed wiring board 241. Accordingly, even when the electrode pitch in the terminal portion 14 is different from the electrode pitch in the FPC 244, electrical connection between the electrodes can be achieved.

The printed wiring board 241 can be provided with a variety of elements such as a resistor, a capacitor, and a semiconductor element.

As in the display module 240 illustrated in FIG. 11C, the terminal portion 242 may be electrically connected to a connection portion 245 provided on a bottom surface (a surface where the display apparatus 10A is not provided) of the printed wiring board 241. With use of a socket-type connection portion as the connection portion 245, for example, the display module 240 can be easily attached to and detached from another device.

### Operation Example of Electronic Device

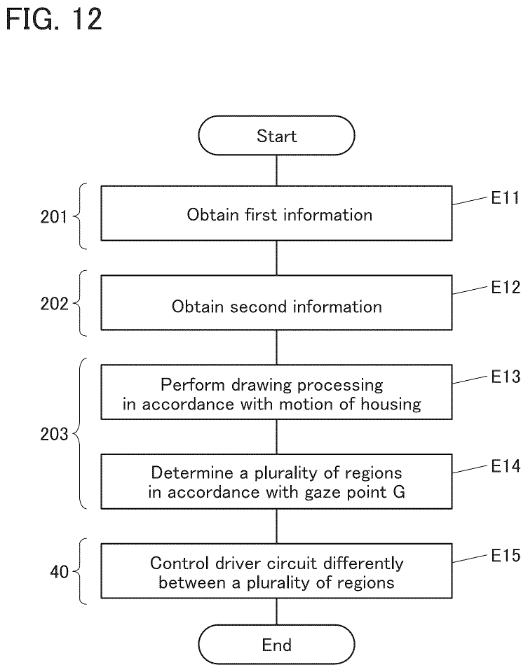

An operation example of the electronic device 200 is described with reference to drawings. FIG. 12 is a flow chart showing the operation example of the electronic device 200.

The motion detection portion 201 obtains the first information (the information on the motion of the housing 205) (Step E11).

The gaze detection portion 202 obtains the second information (the information on the user's gaze) (Step E12).

The arithmetic portion 203 performs drawing processing of 360-degree omnidirectional image data on the basis of the first information (Step E13).

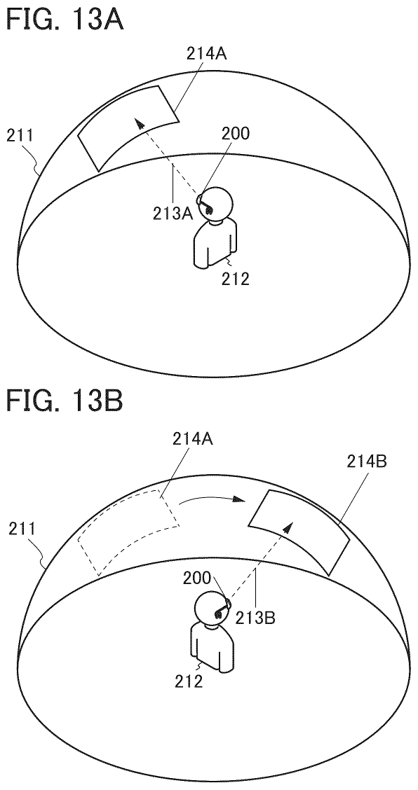

Step E13 is described by giving a specific example. A schematic view in FIG. 13A illustrates a user 212 positioned at the center of a space expressed by a 360-degree omnidirectional image data 211. The user 212 can see an image 214A that is displayed on the display apparatus 10A of the electronic device 200 and that is in a direction 213A.

A schematic view in FIG. 13B illustrates the state where the user 212 that has been in the state of the schematic view in FIG. 13A moves his/her head to see an image 214B that is in a direction 213B. The image 214A changes into the image 214B in accordance with the motion of the housing of the electronic device 200, so that the user 212 can perceive the space expressed by the 360-degree omnidirectional image data 211.

As illustrated in FIG. 13A and FIG. 13B, the housing of the electronic device 200 moves in accordance with the motion of the head of the user 212. When the image obtained from the 360-degree omnidirectional image data 211 is an image processed with higher drawing processing capacity in accordance with the motion of the electronic device 200, the user 212 can recognize a virtual space matching a real-world space.

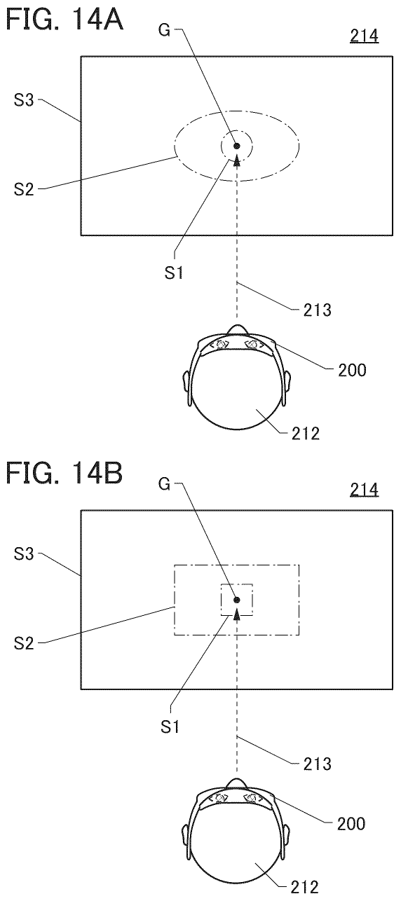

The arithmetic portion 203 determines a plurality of regions of the display portion in the display apparatus in accordance with a gaze point G based on the second information (Step E14). As illustrated in FIG. 14A, the first region S1 including the gaze point G is determined, the second region S2 adjacent to the first region S1 is determined, for example. Furthermore, the outside of the second region is the third region S3.

Step E14 is described by giving a specific example.

In general, the human visual field is roughly classified into the following five fields, although varying between individuals. The discriminating visual field refers to the region (a region including a gaze point) within approximately 5° from the center of vision, where visual performance such as eyesight and color identification is the most excellent. The effective visual field refers to a region that is horizontally within approximately 30° and vertically within approximately 20° from the center of vision (a gaze point) and adjacent to the outside of the discrimination visual field, where instant identification of particular information is possible only with an eye movement. The stable visual field refers to a region that is horizontally within approximately 90° and vertically within approximately 70° from the center of vision and adjacent to the outside of the effective visual field, where identification of particular information is possible without any difficulty with a head movement. The inducting visual field refers to a region that is horizontally within approximately 100° and vertically within approximately 85° from the center of vision and adjacent to the outside of the stable visual field, where the existence of a particular target can be sensed but the identification ability is low. The supplementary visual field refers to a region that is horizontally within approximately 100° to 200° and vertically within approximately 85° to 130° from the center of vision and adjacent to the outside of the inducting visual field, where the identification ability for a particular target is significantly low to an extent that the existence of a stimulus can be sensed.

From the above, it is found that the image quality in the discrimination visual field and the effective visual field is important in an image 214. The image quality in the discrimination visual field is particularly important.

FIG. 14A is a schematic view illustrating the state where the user 212 sees the image 214 displayed on the display portion of the display apparatus 10A of the electronic device 200 from the front (image display surface). The image 214 illustrated in FIG. 14A also corresponds to the display portion. The gaze point G in the direction of a gaze 213 of the user 212 is illustrated on the image 214. In this specification and the like, a region including the discrimination visual field and a region including the effective visual field on the image 214 are referred to as the “first region S1” and the “second region S2”, respectively. Furthermore, a region including the stable visual field, the inducting visual field, or the supplementary visual field is referred to as the “third region S3”.

Although the boundary (outline) between the first region S1 and the second region S2 is illustrated by a curved line in FIG. 14A, one embodiment of the present invention is not limited thereto. As illustrated in FIG. 14B, the boundary (outline) between the first region S1 and the second region S2 may be rectangular or polygonal. Alternatively, the boundary may have a shape in which a straight line and a curved line are combined. The display portion of the display apparatus 10A may be divided into two regions; one of the regions including the discrimination visual field and the effective visual field may be referred to as the first region S1, and the other region may be referred to as the second region S2. In this case, the third region S3 is not formed.

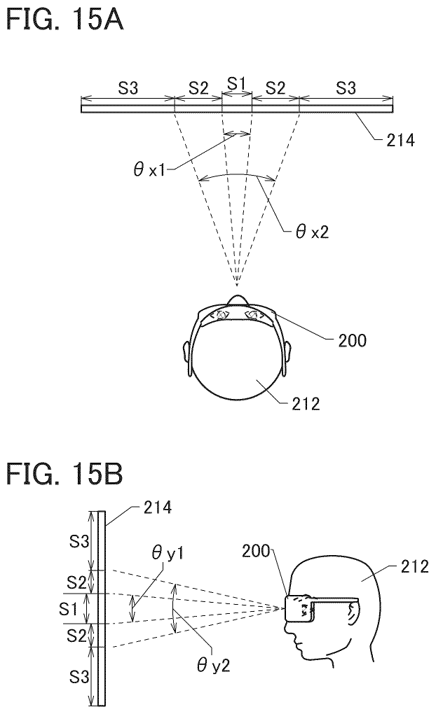

FIG. 15A is a top view of the image 214 displayed on the display portion of the display apparatus 10A of the electronic device 200, and FIG. 15B is a side view of the image 214 displayed on the display portion of the display apparatus 10A of the electronic device 200. In this specification and the like, the angle of the first region S1 in the horizontal direction is shown by “angle θx1”, and the angle of the second region S2 in the horizontal direction is shown by “angle θx2” (see FIG. 15A). In this specification and the like, the angle of the first region S1 in the vertical direction is shown by “angle θy1”, and the angle of the second region S2 in the vertical direction is shown by “angle θy2” (see FIG. 15B).

For example, by setting the angle θx1 to 10° and the angle θy1 to 10°, the area of the first region S1 can be widened. In that case, part of the effective visual field is included in the first region S1. Furthermore, by setting the angle θx2 to 45° and the angle θy2 to 35°, the area of the second region S2 can be widened. In that case, part of the stable visual field is included in the second region S2.

The position of the gaze point G varies to some extent by a swing of the gaze 213. Thus, the angle θx1 and the angle θy1 are each preferably greater than or equal to 5° and less than 20°. When the area of the first region S1 is set larger than the discrimination visual field, the operation of the display apparatus 10A is stabilized and the image visibility is improved.

When the gaze 213 of the user 212 moves, the gaze point G also moves. Accordingly, the first region S1 and the second region S2 also move. For example, in the case where the fluctuation amount of the gaze 213 exceeds a certain value, it is judged that the gaze 213 has moved. That is, in the case where the fluctuation amount of the gaze point G exceeds a certain value, it is judged that the gaze point G has moved. Furthermore, in the case where the fluctuation amount of the gaze 213 becomes lower than or equal to the certain value, it is judged that the gaze 213 has stopped moving, and the first region S1 to the third region S3 are determined. That is, in the case where the fluctuation amount of the gaze point G becomes lower than or equal to the certain value, it is judged that the gaze point G has stopped moving, and the first region S1 to the third region S3 are determined.

The functional circuit 40 performs control of the driver circuit 30 differently between a plurality of regions (the first region S1 to the third region S3) (Step E15). For example, the driving frequency is adjusted so as to be suited for the plurality of regions.

### Structure Example of Pixel Circuit

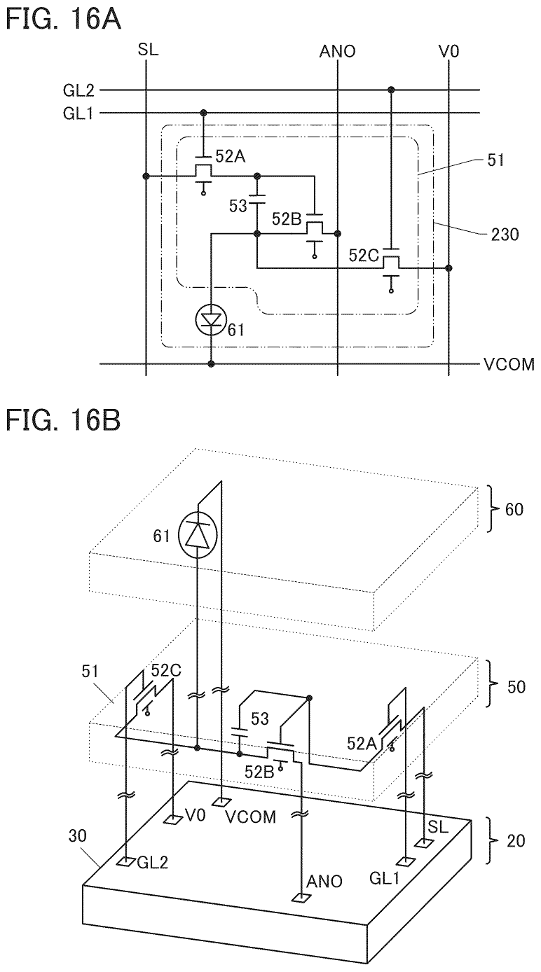

FIG. 16A and FIG. 16B illustrate a structure example of the pixel circuit 51 and the light-emitting element 61 connected to the pixel circuit 51. FIG. 16A schematically illustrates connection of the elements, and FIG. 16B schematically illustrates the vertical position relation of the layer 20 including the driver circuit, the layer 50 including a plurality of transistors of the pixel circuit, and the layer 60 including a light-emitting element.

The pixel circuit 51 illustrated as an example in FIG. 16A and FIG. 16B includes a transistor 52A, a transistor 52B, a transistor 52C, and a capacitor 53. The transistor 52A, the transistor 52B, and the transistor 52C can be OS transistors. Each of the OS transistors of the transistor 52A, the transistor 52B, and the transistor 52C preferably includes a back gate electrode, in which case the structure in which the back gate electrode is supplied with the same signals as those supplied to the gate electrode or the structure in which the back gate electrode is supplied with signals different from those supplied to the gate electrode can be used.

The transistor 52B includes the gate electrode electrically connected to the transistor 52A, a first electrode electrically connected to the light-emitting element 61, and a second electrode electrically connected to a wiring ANO. The wiring ANO is a wiring for supplying a potential for supplying a current to the light-emitting element 61.

The transistor 52A includes a first terminal electrically connected to the gate electrode of the transistor 52B, a second terminal electrically connected to the wiring SL which functions as a source line, and the gate electrode having a function of controlling the conduction state or non-conduction state on the basis of the potential of a wiring GL1 which functions as a gate line.

The transistor 52C includes a first terminal electrically connected to a wiring V0, a second terminal electrically connected to the light-emitting element 61, and the gate electrode having a function of controlling the conduction state or non-conduction state on the basis of the potential of a wiring GL2 which functions as a gate line. The wiring V0 is a wiring for supplying a reference potential and a wiring for outputting a current flowing through the pixel circuit 51 to the driver circuit 30 or the functional circuit 40.

The capacitor 53 includes a conductive film electrically connected to the gate electrode of the transistor 52B and a conductive film electrically connected to the second electrode of the transistor 52C.

The light-emitting element 61 includes a first electrode electrically connected to the first electrode of the transistor 52B and a second electrode electrically connected to a wiring VCOM. The wiring VCOM is a wiring for supplying a potential for supplying a current to the light-emitting element 61.

Accordingly, the intensity of light emitted from the light-emitting element 61 can be controlled in accordance with an image signal supplied to the gate electrode of the transistor 52B. Furthermore, variations in voltage between the gate and the source of the transistor 52B can be reduced by the reference potential of the wiring V0 supplied through the transistor 52C.

A current value that can be used for setting pixel parameters can be output from the wiring V0. Specifically, the wiring V0 can function as a monitor line for outputting a current flowing through the transistor 52B or a current flowing through the light-emitting element 61 to the outside. A current output to the wiring V0 is converted into a voltage by a source follower circuit or the like and output to the outside. Alternatively, the current output to the wiring V0 can be converted into a digital signal by an A-D converter or the like and output to the functional circuit 40 or the like.

Note that the light-emitting element described in one embodiment of the present invention refers to a self-luminous display element such as an organic EL element (also referred to as an OLED (Organic Light Emitting Diode)). Note that the light-emitting element electrically connected to the pixel circuit can be a self-luminous light-emitting element such as an LED (Light Emitting Diode), a micro LED, a QLED (Quantum-dot Light Emitting Diode), or a semiconductor laser.

Note that in the structure illustrated as an example in FIG. 16B, the wirings electrically connecting the pixel circuit 51 and the driver circuit 30 can be shortened, so that wiring resistance of the wirings can be reduced. Thus, data can be written at high speed, which enables high-speed driving of the display apparatus 10A. Therefore, even when the number of the pixel circuits 51 included in the display apparatus 10A is increased, a sufficiently long frame period can be ensured, and thus, the pixel density of the display apparatus 10A can be increased. In addition, the increased pixel density of the display apparatus 10A can increase the resolution of an image displayed by the display apparatus 10A. For example, the pixel density of the display apparatus 10A can be higher than or equal to 1000 ppi, higher than or equal to 5000 ppi, or higher than or equal to 7000 ppi. Thus, the display apparatus 10A can be, for example, a display apparatus for AR or VR and can be suitably used in an electronic device with a short distance between a display portion and the user, such as an HMD.

Although FIG. 16A and FIG. 16B illustrate, as an example, the pixel circuit 51 including three transistors in total, one embodiment of the present invention is not limited to the example. Structure examples and a driving method example of a pixel circuit which can be used for the pixel circuit 51 will be described below.

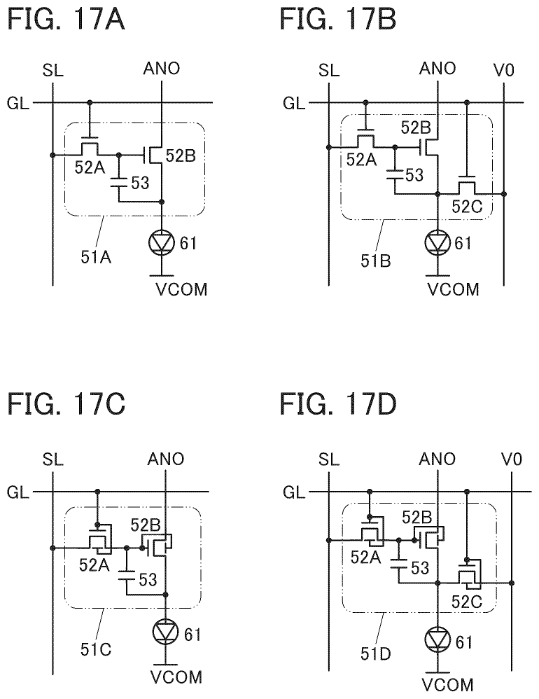

A pixel circuit 51A illustrated in FIG. 17A illustrates a transistor 52A, a transistor 52B, and a capacitor 53. FIG. 17A also illustrates a light-emitting element 61 connected to the pixel circuit 51A. The wiring SL, the wiring GL, the wiring ANO, and the wiring VCOM are electrically connected to the pixel circuit 51A. The pixel circuit 51A has a structure in which the transistor 52C is removed from the pixel circuit 51 illustrated in FIG. 16A and the wiring GL1 and the wiring GL2 are replaced with the wiring GL.

The gate of the transistor 52A is electrically connected to the wiring GL, one of the source and the drain of the transistor 52A is electrically connected to the wiring SL, and the other of the source and the drain of the transistor 52A is electrically connected to the gate of the transistor 52B and one electrode of a capacitor 53. One of a source and a drain of the transistor 52B is electrically connected to the wiring ANO and the other thereof is electrically connected to an anode of the light-emitting element 61. The other electrode of the capacitor 53 is electrically connected to the anode of the light-emitting element 61. A cathode of the light-emitting element 61 is electrically connected to the wiring VCOM.

A pixel circuit 51B illustrated in FIG. 17B has a structure in which the transistor 52C is added to the pixel circuit 51A. In addition, the wiring V0 is electrically connected to the pixel circuit 51B.

A pixel circuit 51C illustrated in FIG. 17C is an example when a transistor including a pair of gates electrically connected to each other is employed as each of the transistor 52A and the transistor 52B in the pixel circuit 51A. A pixel circuit 51D illustrated in FIG. 17D is an example where such transistors are employed in the pixel circuit 51B. Thus, the current that can flow through the transistor can be increased. Note that although the transistor in which a pair of gates are electrically connected to each other is used for each of the transistors here, one embodiment of the present invention is not limited thereto. A transistor that includes a pair of gates electrically connected to different wirings may be used. When, for example, a transistor in which one of gates is electrically connected to a source is used, the reliability can be increased.

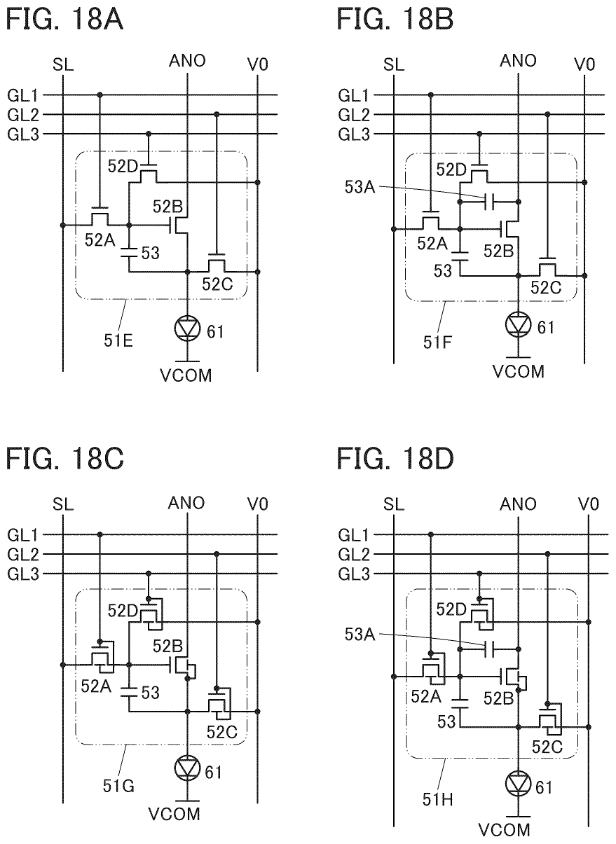

A pixel circuit 51E illustrated in FIG. 18A has a structure in which a transistor 52D is added to the pixel circuit 51B. The wiring GL1, the wiring GL2, and a wiring GL3 functioning as gate lines are electrically connected to the pixel circuit 51E. Note that in this embodiment and the like, the wiring GL1, the wiring GL2, and the wiring GL3 are collectively referred to as the wiring GL in some cases. Thus, the wiring GL is not limited to one wiring and includes a plurality of wirings in some cases.

A gate of the transistor 52D is electrically connected to the wiring GL3, one of a source and a drain of the transistor 52D is electrically connected to the gate of the transistor 52B, and the other of the source and the drain of the transistor 52D is electrically connected to the wiring V0. The gate of the transistor 52A is electrically connected to the wiring GL1, and the gate of the transistor 52C is electrically connected to the wiring GL2.

When the transistor 52C and the transistor 52D are turned on at the same time, the source and the gate of the transistor 52B have the same potential, so that the transistor 52B can be turned off. Thus, current flowing to the light-emitting element 61 can be blocked forcibly. Such a pixel circuit is suitable for the case of using a display method in which a display period and a non-lighting period are alternately provided.

A pixel circuit 51F illustrated in FIG. 18B is an example when a capacitor 53A is added to the pixel circuit 51E. The capacitor 53A functions as a storage capacitor.

A pixel circuit 51G illustrated in FIG. 18C and a pixel circuit 51H illustrated in FIG. 18D are each an example when a transistor including a pair of gates is employed in the pixel circuit 51E or the pixel circuit 51F. A transistor in which a pair of gates are electrically connected to each other is used as each of the transistor 52A, the transistor 52C, and the transistor 52D, and a transistor in which one of gates is electrically connected to a source is used as the transistor 52B.

Next, an example of a method for driving a display apparatus in which the pixel circuit 51E is used is described. Note that a similar driving method can be applied to display apparatuses in which the pixel circuits 51F, 51G, and 51H are used.

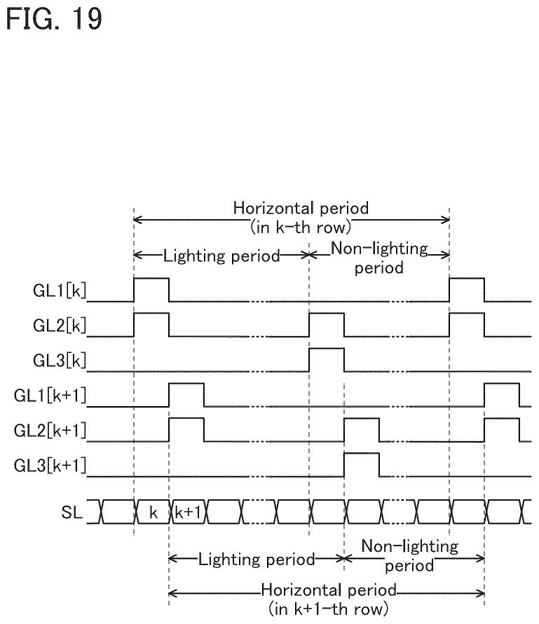

FIG. 19 shows a timing chart of a method for driving the display apparatus in which the pixel circuit 51E is used. Changes in the potentials of a wiring GL1[k], a wiring GL2[k], and a wiring GL3[k] that are gate lines of the k-th row and changes in the potentials of a wiring GL1[k+1], a wiring GL2[k+1], and a wiring GL3[k+1] that are gate lines in the k+1-th row are shown here. FIG. 19 also shows the timing of supplying a signal to the wiring SL functioning as a source line.

Here, an example of the driving method in which one horizontal period is divided into a lighting period and a non-lighting period is shown. A horizontal period of the k-th row is shifted from a horizontal period of the k+1-th row by a selection period of the gate line.

In the lighting period of the k-th row, first, the wiring GL1[k] and the wiring GL2[k] are supplied with a high-level potential and the wiring SL is supplied with a source signal. Thus, the transistor 52A and the transistor 52C are turned on, so that a potential corresponding to the source signal is written from the wiring SL to the gate of the transistor 52B. After that, the wiring GL1[k] and the wiring GL2[k] are supplied with a low-level potential, so that the transistor 52A and the transistor 52C are turned off and the gate potential of the transistor 52B is retained. Subsequently, in a lighting period of the k+1-th row, data is written by an operation similar to that described above.

Next, the non-lighting period is described. In the non-lighting period of the k-th row, the wiring GL2[k] and the wiring GL3[k] are supplied with a high-level potential. Accordingly, the transistor 52C and the transistor 52D are turned on, and the source and the gate of the transistor 52B are supplied with the same potential, so that almost no current flows through the transistor 52B. Thus, the light-emitting element 61 is turned off. All the subpixels that are positioned in the k-th row are turned off. The subpixels of the k-th row remain in the non-lighting state until the next lighting period.

Subsequently, in a non-lighting period of the k+1-th row, all the subpixels of the k+1-th row are in the non-lighting state in a manner similar to that described above.

Such a driving method described above, in which the pixels are not constantly on through one horizontal period and a non-lighting period is provided in one horizontal period, can be called duty driving. With duty driving, an afterimage phenomenon can be inhibited at the time of displaying moving images; therefore, a display apparatus with high performance in displaying moving images can be obtained. Particularly in a VR device and the like, a reduction in an afterimage can reduce what is called VR sickness.

In the duty driving, the proportion of the lighting period in one horizontal period can be called a duty cycle. For example, a duty cycle of 50% means that the lighting period and the non-lighting period have the same length. Note that the duty cycle can be set freely and can be adjusted appropriately within a range higher than 0% and lower than or equal to 100%, for example.

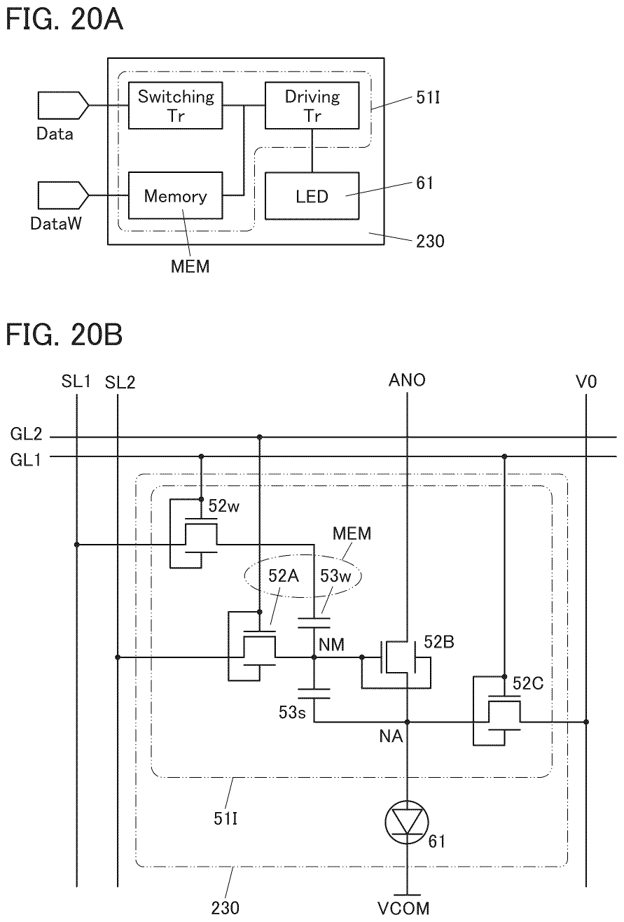

A structure different from the structures of the above-described pixel circuits is described with reference to FIG. 20A and FIG. 20B.

FIG. 20A is a block diagram of the pixel 230. The pixel 230 includes a pixel circuit 51I and the light-emitting element (LED) 61. The pixel circuit 51I illustrated in FIG. 20A includes a switching transistor (Switching Tr), a driving transistor (Driving Tr) and a memory circuit MEM (Memory). Image data Data is input to the switching transistor, and data DataW is input to the memory circuit MEM.

FIG. 20B is a specific circuit diagram of the pixel circuit 51I.

The pixel circuit 51I illustrated in FIG. 20B includes a transistor 52w, the transistor 52A, the transistor 52B, the transistor 52C, a capacitor 53s, and a capacitor 53w. The transistor 52A and the capacitor 53w constitute the memory circuit MEM. FIG. 20B illustrates the light-emitting element 61 connected to the pixel circuit 51I.

Data DataW is supplied to the memory circuit MEM through a wiring SL2 and the transistor 52A. When the data DataW is supplied to the pixel in addition to image data, a current flowing through the light-emitting element becomes large, so that the display apparatus can have high luminance.

The transistor 52w functions as a switching transistor. The transistor 52B functions as a driving transistor. One of a source and a drain of the transistor 52w is electrically connected to one electrode of the capacitor 53w. The other electrode of the capacitor 53w is electrically connected to one of the source and the drain of the transistor 52A. The one of the source and the drain of the transistor 52A is electrically connected to the gate of the transistor 52B. The gate of the transistor 52B is electrically connected to one electrode of the capacitor 53s. The other electrode of the capacitor 53s is electrically connected to one of the source and the drain of the transistor 52B. The one of the source and the drain of the transistor 52B is electrically connected to one of a source and a drain of the transistor 52C. The one of the source and the drain of the transistor 52C is electrically connected to one electrode of the light-emitting element 61. The transistors illustrated in FIG. 20B each include a back gate electrically connected to its gate; however, the connection of the back gate is not limited thereto. The transistors do not necessarily include the back gates.

Here, a node to which the other electrode of the capacitor 53w, the one of the source and the drain of the transistor 52A, the gate of the transistor 52B, and the one electrode of the capacitor 53s are connected is referred to as a node NM. A node to which the other electrode of the capacitor 53s, the one of the source and the drain of the transistor 52B, the one of the source and the drain of the transistor 52C, and the one electrode of the light-emitting element 61 are connected is referred to as a node NA.

A gate of the transistor 52w is electrically connected to the wiring GL1. The gate of the transistor 52C is electrically connected to the wiring GL1. The gate of the transistor 52A is electrically connected to the wiring GL2. The other of the source and the drain of the transistor 52w is electrically connected to a wiring SL1. The other of the source and the drain of the transistor 52C is electrically connected to a wiring V0. The other of the source and the drain of the transistor 52A is electrically connected to the wiring SL2. Note that in this embodiment and the like, the wiring SL1 and the wiring SL2 are collectively referred to as the wiring SL in some cases. Thus, the wiring SL is not limited to one wiring and consists of a plurality of wirings in some cases.

The other of the source and the drain of the transistor 52B is electrically connected to the wiring ANO. The other electrode of the light-emitting element 61 is electrically connected to the wiring VCOM.

The wiring GL1 and the wiring GL2 can have a function of signal lines for controlling the operation of the transistors. The wiring SL1 can have a function of a signal line for supplying the image data Data to the pixel. The wiring SL2 can have a function of a signal line for writing the data DataW to the memory circuit MEM. For example, the wiring SL2 can have a function of a signal line for supplying a correction signal to the pixel. The wiring V0 has a function of a monitor line for obtaining the electrical characteristics of the transistor 52B. A specific potential is supplied from the wiring V0 to the other electrode of the capacitor 53s through the transistor 52C, whereby writing of an image signal can be stable.

The transistor 52A and the capacitor 53w constitute the memory circuit MEM. The node NM is a memory node; when the transistor 52A is turned on, the data DataW supplied from the wiring SL2 can be written to the node NM. The use of an OS transistor with an extremely low off-state current as the transistor 52A allows the potential of the node NM to be retained for a long time.

In the pixel circuit 51I, the image data Data supplied from the wiring SL1 is supplied to the capacitor 53w through the transistor 52w. One of the source and the drain of the transistor 52w and the node NM are capacitively coupled. Thus, the potential of the node NM to which the data DataW is written changes depending on the image data Data. Furthermore, the node NA and the node NM are capacitively coupled through the capacitor 53s. Thus, the potential of the node NA changes depending on the data DataW and the image data Data.

Note that the transistor 52w functions as a selection transistor for determining whether or not the image data Data is to be supplied. The transistor 52C functions as a reset transistor for determining whether or not to set the potential of the node NA to be equal to that of the wiring V0.

### Variation

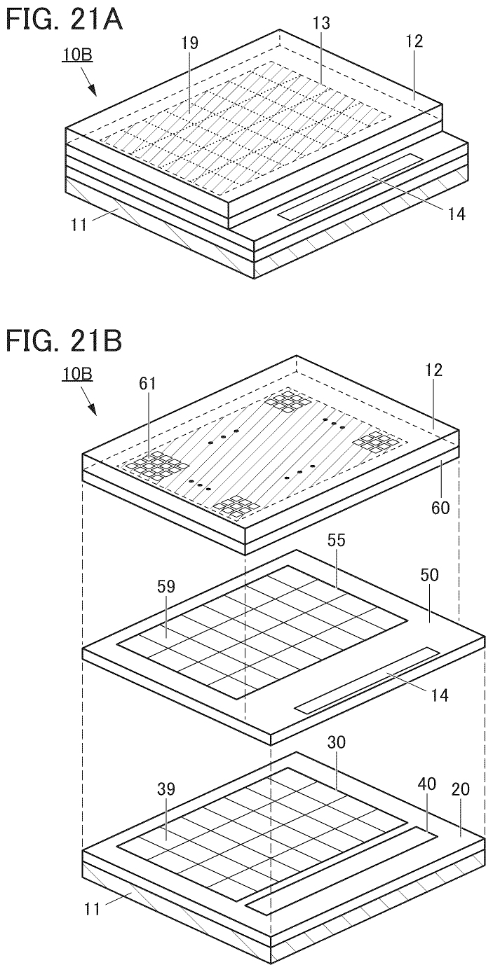

FIG. 21A and FIG. 21B are perspective views of a display apparatus 10B, which is a variation of the display apparatus 10A. FIG. 21B is a perspective view for illustrating structures of layers included in the display apparatus 10B. Description is made mainly on portions different from those of the display apparatus 10A to reduce repeated description.

In the display apparatus 10B, the driver circuit 30 and the pixel circuit group 55 including the plurality of pixel circuits 51 (not illustrated) overlap with each other. In the display apparatus 10B, the pixel circuit group 55 is divided into a plurality of sections 59 and the driver circuit 30 is divided into a plurality of sections 39. The plurality of sections 39 each include the source driver circuit 31 and the gate driver circuit 33.

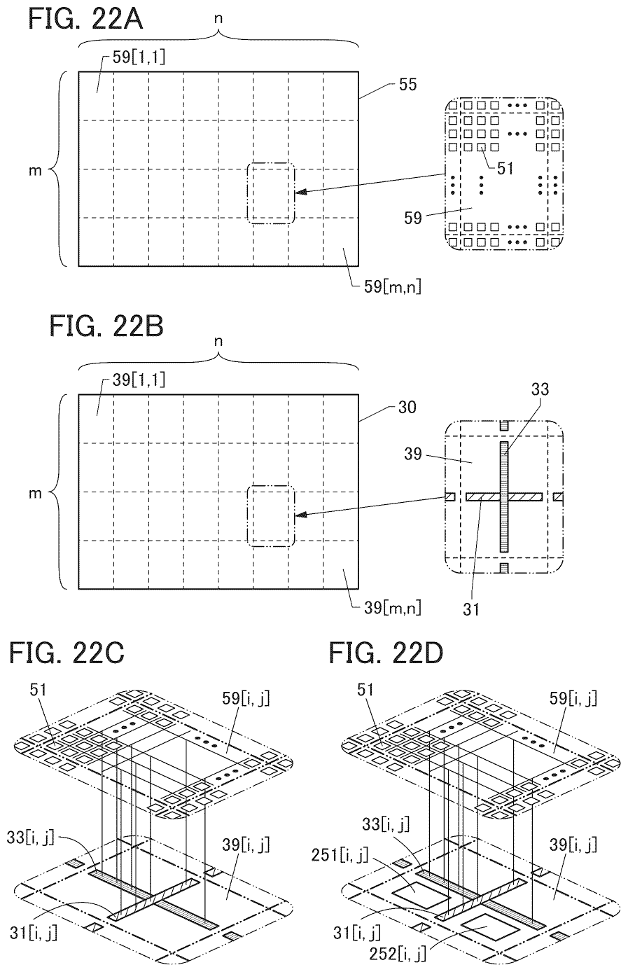

FIG. 22A illustrates a structure example of the pixel circuit group 55 included in the display apparatus 10B. FIG. 22B illustrates a structure example of the driver circuit 30 included in the display apparatus 10B. The sections 59 and the sections 39 are arranged in a matrix of m rows and n columns (m and n are each an integer greater than or equal to 1). In this specification and the like, the section 59 in the first row and the first column is denoted by a section 59[1,1], and the section 59 in the m-th row and the n-th column is denoted by a section 59[m,n]. Similarly, the section 39 in the first row and the first column is denoted by a section 39[1,1], and the section 39 in the m-th row and the n-th column is denoted by a section 39[m,n]. FIG. 22A and FIG. 22B illustrate a case where m is 4 and n is 8. That is, the pixel circuit group 55 and the driver circuit 30 are each divided into 32 sections.

The plurality of sections 59 each include the plurality of pixel circuits 51, the plurality of wirings SL, and the plurality of wirings GL. In each of the plurality of sections 59, one of the plurality of pixel circuits 51 is electrically connected to at least one of the plurality of wirings SL and at least one of the plurality of wirings GL.

One of the sections 59 and one of the sections 39 are provided to overlap with each other (see FIG. 22C). For example, a section 59[i,j] (i is an integer greater than or equal to 1 and less than or equal to m, and j is an integer greater than or equal to 1 and less than or equal to n) and the section 39[i,j] are provided to overlap with each other. A source driver circuit 31[i,j] included in the section 39[i,j] is electrically connected to the wiring SL included in the section 59[i,j]. A gate driver circuit 33[i,j] included in the section 39[i,j] is electrically connected to the wiring GL included in the section 59[i,j]. The source driver circuit 31[i,j] and the gate driver circuit 33[i,j] have a function of controlling the plurality of pixel circuits 51 included in the section 59[i,j].

When the section 59[i,j] and the section 39[i,j] are provided to overlap with each other, a connection distance (wiring length) between the pixel circuit 51 included in the section 59[i,j] and each of the source driver circuit 31 and the gate driver circuit 33 included in the section 39[i,j] can be made extremely short. As a result, the wiring resistance and the parasitic capacitance are reduced, and thus time taken for charging and discharging can be reduced and high-speed driving can be achieved. Moreover, power consumption can be reduced. Furthermore, the size and weight of the display apparatus can be reduced.

In addition, the display apparatus 10B has a structure in which the source driver circuit 31 and the gate driver circuit 33 are provided in each of the sections 39. Thus, the display portion 13 can be divided into the sections 59 corresponding to the sections 39, and image data rewriting can be performed in each section. For example, in the display portion 13, image data rewriting can be performed only in a section where an image has been changed and image data can be retained in a section with no change, so that power consumption can be reduced.

In this embodiment and the like, one section of the display portion 13 divided into the sections 59 is referred to as a sub-display portion 19. Thus, the sub-display portion 19 is also one of the display portion 13 divided into the sections 39. The display portion 13 includes a plurality of the sub-display portions 19. The display portion 13 can also be regarded as being formed of a plurality of sub-display portions 19. In the display apparatus 10B described with reference to FIG. 21 and FIG. 22, the display portion 13 is divided into 32 sub-display portions 19 (see FIG. 21A). Each of the sub-display portions 19 includes the plurality of pixels 230 illustrated in FIG. 16 and the like. Specifically, one of the sub-display portions 19 includes one of the sections 59 including the plurality of pixel circuits 51, and the plurality of light-emitting elements 61. Each of the sections 39 has a function of controlling the plurality of pixels 230 included in one of the sub-display portions 19.

In the display apparatus 10B, driving frequency at the time of displaying an image can be set freely for each of the sub-display portions 19 by the timing generation circuit 44 included in the functional circuit 40. The functional circuit 40 has a function of controlling operations in the plurality of sections 39 and the plurality of sections 59. In other words, the functional circuit 40 has a function of controlling driving frequency and operation timing of each of the plurality of sub-display portions 19 arranged in a matrix. In addition, the functional circuit 40 has a function of adjusting synchronization between the sub-display portions.

A timing generation circuit (timing generation circuit 251) and an input/output circuit (input/output circuit 252) may be provided for each of the sections 39 (see FIG. 22D). For the input/output circuit 252, an I2C (Inter-Integrated Circuit) interface can be used, for example. The timing generation circuit 251 included in the section 39[i,j] is denoted as a timing generation circuit 251 [i,j] in FIG. 22C and FIG. 22D. Furthermore, the input/output circuit 252 included the section 39[i,j] is denoted as an input/output circuit 252[i,j].

The functional circuit 40 supplies setting signals for the scan direction and driving frequency of the gate driver circuit 33[i,j] and operation parameters, such as the number of pixels in image data reduced for decreasing a resolution (the number of pixels where image data rewriting is not performed at the time of image data rewriting), to the input/output circuit 252[i,j], for example. The source driver circuit 31[i,j] and the gate driver circuit 33[i,j] operate in accordance with the operation parameters.

In the case where the sub-display portions 19 each include a light-receiving element, the input/output circuit 252 outputs information obtained by photoelectric conversion by the light-receiving element to the functional circuit 40.

In the display apparatus 10B in the electronic device of one embodiment of the present invention, the pixel circuit 51 and the driver circuit 30 are stacked and the driving frequency is different in each of the sub-display portions 19 in accordance with the motion of the user's gaze, whereby low power consumption can be achieved.

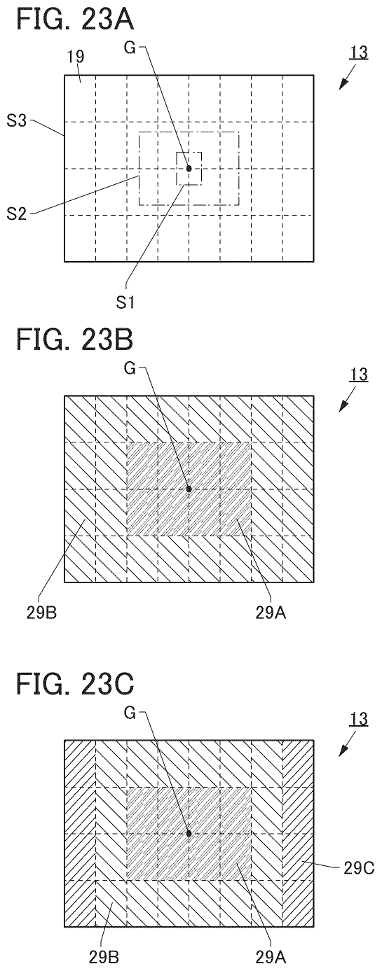

FIG. 23A illustrates the display portion 13 including the sub-display portions 19 in four rows and eight columns. FIG. 23A also illustrates the first region S1 to the third region S3 with the gaze point G as a center. The arithmetic portion 203 allocates the plurality of sub-display portions 19 to a first section 29A overlapping with the first region S1 or the second region S2 or a second section 29B overlapping with the third region S3. In other words, the arithmetic portion 203 distributes each of the plurality of sections 39 to either the first section 29A or the second section 29B. In this case, the first section 29A overlapping with the first region S1 or the second region S2 includes a region overlapping with the gaze point G. Furthermore, the second section 29B includes the sub-display portions 19 positioned outside the first section 29A (see FIG. 23B).

The operations of the driver circuits (the source driver circuit 31 and the gate driver circuit 33) included in each of the plurality of sections 39 are controlled by the functional circuit 40. For example, the second section 29B is a section overlapping with the third region S3 including the above-described stable visual field, inducting visual field, and supplementary visual field, and is hard for the user to discern. Thus, a reduction in practical display quality perceived by a user (hereinafter also referred to as “practical display quality”) is small even when the number of times of image data rewriting per unit time (hereinafter also referred to as “image rewriting frequency”) at the time of displaying an image is smaller in the second section 29B than in the first section 29A. In other words, a reduction in practical display quality is small even when the driving frequency of the sub-display portions 19 included in the second section 29B (also referred to as a “second driving frequency”) is lower than the driving frequency of the sub-display portions 19 included in the first section 29A (also referred to as a “first driving frequency”).

A decrease in the driving frequency can result in a reduction in power consumption of the display apparatus. On the other hand, a decrease in the driving frequency reduces the display quality. In particular, the display quality in displaying a moving image is reduced. According to one embodiment of the present invention, the second driving frequency is made lower than the first driving frequency; thus, power consumption can be reduced in a section where the visibility by the user is low and the reduction of the practical display quality can be suppressed. According to one embodiment of the present invention, both display quality maintenance and a reduction in power consumption can be achieved.

The first driving frequency can be higher than or equal to 30 Hz and lower than or equal to 500 Hz, preferably higher than or equal to 60 Hz and lower than or equal to 500 Hz. The second driving frequency is preferably lower than or equal to the first driving frequency, further preferably lower than or equal to a half of the first driving frequency, still further preferably lower than or equal to one fifth of the first driving frequency.

A section of the sub-display portions 19 overlapping with the third region S3 that is farther from the first section 29A may be set as a third section 29C (see FIG. 23C), and driving frequency of the sub-display portions 19 included in the third section 29C (also referred to as “third driving frequency”) may be made lower than the driving frequency in the second section 29B. The third driving frequency is preferably lower than or equal to the second driving frequency, further preferably lower than or equal to a half of the second driving frequency, still further preferably lower than or equal to one fifth of the second driving frequency. By significantly lowering the image rewriting frequency, power consumption can be further reduced. Note that rewriting of image data may be stopped if necessary. By stopping rewriting of image data, power consumption can be further reduced.

In the case where such a driving method is employed, a transistor with an extremely low off-state current is suitably used as a transistor included in the pixel circuit 51. For example, an OS transistor is suitably used as the transistor included in the pixel circuit 51. An OS transistor has an extremely low off-state current and thus can achieve long-term retention of image data supplied to the pixel circuit 51. It is particularly suitable to use an OS transistor as the transistor 52A.

In some cases, an image whose brightness, contrast, color tone, or the like is greatly different from that of the previous image is displayed as in the case where a video scene displayed on the display portion 13 is changed, for example. Such a case causes a mismatch of the timing at which an image is changed between the first section 29A and a section whose driving frequency is lower than that of the first section 29A. This might cause a great difference in the brightness, contrast, color tone, or the like between the sections, leading to the loss of the practical display quality. In such a case where a video scene is changed, image data rewriting can be temporarily performed in the section other than the first section 29A at a driving frequency which is the same as that of the first section 29A, and then the driving frequency of the section other than the first section 29A can be decreased.

Furthermore, in the case where the fluctuation amount of the gaze point G is judged to be exceeding a certain value, image data rewriting may be performed in the section other than the first section 29A at a driving frequency which is the same as that of the first section 29A, and the driving frequency of the section other than the first section 29A may be decreased when the fluctuation amount is judged to be within the certain value. In the case where the fluctuation amount of the gaze point G is judged to be small, the driving frequency of the sections other than the first section 29A may be further decreased.

In the case where the display apparatus 10B does not include a frame memory, which is a memory device for temporarily retaining image data, or includes one frame memory for the entire display portion 13, each of the second driving frequency and the third driving frequency needs to be an integral submultiple of the first driving frequency.

When the plurality of sub-display portions 19 are provided with respective frame memories, each of the second driving frequency and the third driving frequency can be set to a given value without limitation to an integral submultiple of the first driving frequency. When the second driving frequency and the third driving frequency are set to given values, the degree of freedom in setting the driving frequencies can be increased. As a result, a reduction in the practical display quality can be small.

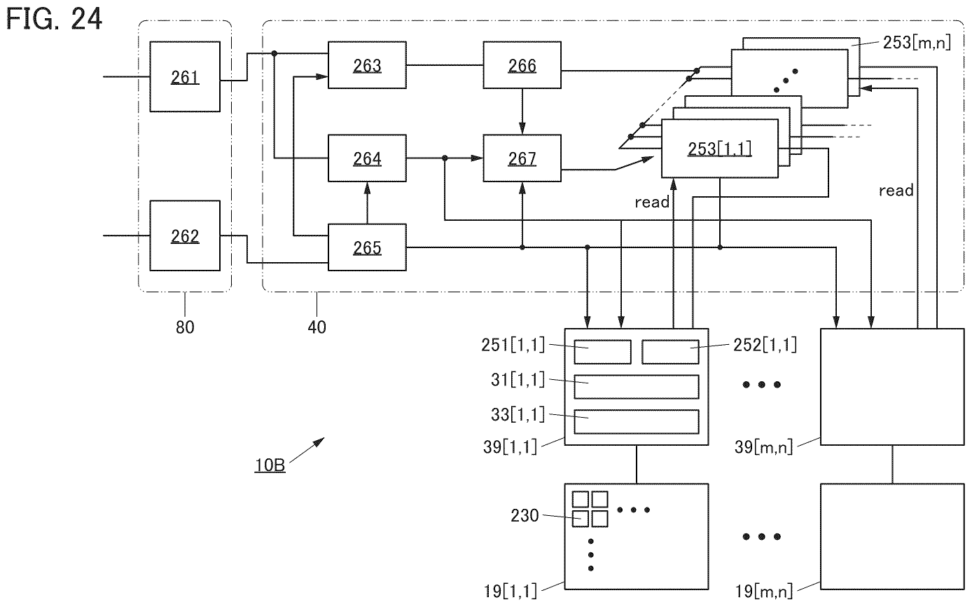

FIG. 24 is a block diagram illustrating a structure example of the display apparatus 10B including a frame memory 253 for each of the sub-display portions 19. In FIG. 24, the input/output circuit 80 includes an image information input portion 261 and a clock signal input portion 262. The functional circuit 40 includes an image data temporary retention portion 263, an operation parameter setting portion 264, an internal clock signal generating portion 265, an image processing portion 266, a memory controller 267, and a plurality of frame memories 253.

Alternatively, a flash memory, a MRAM, a PRAM, a ReRAM, an FeRAM, a DRAM, an SRAM, or the like may be used as the image data temporary memory portion 263 and the frame memory 253. As the image data temporary storage portion 263 and the frame memory 253, a DOSRAM (registered trademark), a NOSRAM (registered trademark), or the like may be used.

Each of the plurality of frame memories 253 has a function of retaining image data to be displayed on one of the plurality of sub-display portions 19. For example, a frame memory 253[1,1] has a function of retaining image data to be displayed on a sub-display portion 19[1,1]. Similarly, a frame memory 253[m,n] has a function of retaining image data to be displayed on a sub-display portion 19[m,n].

Each of the plurality of sub-display portions 19 is electrically connected to one of the plurality of sections 39. In FIG. 24, each of the plurality of sections 39 includes the source driver circuit 31, the gate driver circuit 33, the timing generation circuit 251, and the input/output circuit 252. In FIG. 24 and the like, the timing generation circuit 251 included in the section 39[1,1] is denoted as a timing generation circuit 251[1,1]. Furthermore, the input/output circuit 252 included the section 39[1,1] is denoted as an input/output circuit 252[1,1].

Image data to be displayed on the display portion 13 and operation parameters of the display apparatus 10B are supplied to the image information input portion 261 from the outside. A clock signal is supplied to the clock signal input portion 262 from the outside. The clock signal is supplied to the internal clock signal generating portion 265 via the clock signal input portion 262.

The internal clock signal generating portion 265 has a function of generating a clock signal used in the display apparatus 10B (also referred to as “internal clock signal”) with use of the clock signal supplied from the outside. The internal clock signal is supplied to the image data temporary retention portion 263, the operation parameter setting portion 264, the memory controller 267, the section 39, and the like and used for matching operation timing between the circuits included in the display apparatus 10B, for example.

The image data input via the image information input portion 261 is supplied to the image data temporary retention portion 263. The operation parameters input via the image information input portion 261 are supplied to the operation parameter setting portion 264.

The image data temporary retention portion 263 retains the supplied image data, and supplies the image data to the image processing portion 266 in synchronization with the internal clock signal. Thus, the image data temporary memory portion 263 is one kind of frame memory. Providing the image data temporary retention portion 263 can eliminate a mismatch between the timing at which image data is supplied from the outside and the timing at which the image data is processed in the display apparatus 10B.

The operation parameter setting portion 264 has a function of retaining the supplied operation parameters. The operation parameters include information for determining the driving frequency, scan direction, resolution, or the like for each of the plurality of sub-display portions 19.

The image processing portion 266 has a function of performing arithmetic processing of the image data retained in the image data temporary retention portion 263. For example, the image processing portion 266 has a function of performing contrast adjustment, brightness adjustment, and gamma correction of the image data. Furthermore, the image processing portion 266 has a function of dividing the image data retained in the image data temporary retention portion 263 for the sub-display portions 19.

The image processing portion 266 has a function of reading image data stored in each of the plurality of frame memories 253, performing arithmetic processing on the image data, and writing back the arithmetically processed image data to the frame memories 253. For example, when a still image is displayed on the display portion 13, arithmetic processing is performed on image data stored in some or all of the plurality of frame memories 253, whereby luminance, contrast, or the like can be adjusted.

The memory controller 267 has a function of controlling the operations of the plurality of frame memories 253. The image data is retained in the plurality of frame memories 253 after being divided by the image processing portion 266 for the sub-display portions 19. Each of the plurality of frame memories 253 has a function of supplying image data to the corresponding section 39 in response to a read request signal (read) from the section 39.

Note that the memory device 41 may be used instead of the frame memory 253. In other words, image data divided for the sub-display portions 19 may be retained in the memory device 41.

The frame memory 253 may be provided in a component other than the functional circuit 40. Alternatively, the frame memory 253 may be provided in a semiconductor device other than the display apparatus 10B.

Note that sections set for the display portion 13 are not limited to the three sections of the first section 29A, the second section 29B, and the third section 29C. The display portion 13 may include four or more sections. When a plurality of sections are set for the display portion 13 and the driving frequencies of the sections gradually decreases, a reduction in the practical display quality can be smaller.

The above-described upconversion processing may be performed on an image to be displayed on the first section 29A. When an image obtained by the upconversion processing is displayed on the first section 29A, the display quality can be increased. The above-described upconversion processing may be performed on an image to be displayed on the sections other than the first section 29A. When an image obtained by the upconversion processing is displayed on the sections other than the first section 29A, a reduction in the practical display quality that occurs in the case where the driving frequencies of the sections other than the first section 29A are lowered can be smaller.

Note that the upconversion processing of an image to be displayed on the first section 29A may be performed using an algorithm with high accuracy, and the upconversion processing of an image to be displayed on the sections other than the first section 29A may be performed using an algorithm with low accuracy. A reduction in the practical display quality that occurs in the case where the driving frequencies of the sections other than the first section 29A are lowered can be smaller also in such a case.

In the case where the resolution of image data is to be lower than the resolution of the display portion 13, or in the case where high-speed rewriting and low power consumption are made to have a priority, for example, downconversion processing may be performed on an image displayed on the sections other than the first section 29A in accordance with the purpose or the like. For example, high-speed rewriting and low power consumption can be achieved by rewriting an image displayed on the sections other than the first section 29A every several rows, every several columns, or every several pixels.

The resolutions of images displayed on the sections other than the first section 29A including a gaze point are lower than the resolution of an image displayed on the first section 29A, enabling a reduction in the load at the time of generation of a video signal (rendering). The above processing is also referred to as foveated rendering. With a combination of the reduction of a driving frequency of the sections other than the first section 29A and the foveated rendering, much lower power consumption can be achieved while a decrease in display quality is suppressed.

When image data rewriting performed in each of the sub-display portions 19 is performed concurrently in all of the sub-display portions 19, high-speed rewriting can be achieved. In other words, when image data rewriting performed in each of the sections 39 is performed concurrently in all of the sections 39, high-speed rewriting can be achieved.

In general, while pixels in one row are selected by a gate driver circuit, a source driver circuit writes image data to all of the pixels in one row concurrently in the case of line sequential driving. In the case where the display portion 13 is not divided into the sub-display portions 19 and the resolution is 4000×2000 pixels, for example, image data needs to be written to 4000 pixels by the source driver circuit while the pixels in one row are selected by the gate driver circuit. In the case where the frame frequency is 120 Hz, one frame period is approximately 8.3 msec. Accordingly, the gate driver circuit needs to select pixels in 2000 rows in approximately 8.3 msec, and the time for selecting pixels in one row, that is, the time for writing image data to each pixel is approximately 4.17 usec. In other words, it becomes more difficult to ensure sufficient time for rewriting image data as the resolution of the display portion increases or as the frame frequency increases.

The display portion 13 of the display apparatus 10B described as an example in this embodiment is divided into four parts in the row direction. Thus, the time for writing image data to each pixel in one sub-display portion 19 can be four times as long as that of the case where the display portion 13 is not divided. According to one embodiment of the present invention, the time for rewriting image data can be easily ensured even in the case where the frame frequency is 240 Hz or 360 Hz; thus, a display apparatus with high display quality can be provided.

Since the display portion 13 of the display apparatus 10B described as an example in this embodiment is divided into four parts in the row direction, the length of the wiring SL electrically connecting the source driver circuit and the pixel circuit becomes one fourth. Accordingly, each of the resistance value and parasitic capacitance of the wiring SL becomes one fourth, whereby the time required for writing (rewriting) image data can be shortened.

In addition, the display portion 13 of the display apparatus 10B described as an example in this embodiment is divided into eight parts in the column direction; thus, the length of the wiring GL electrically connecting the gate driver circuit and the pixel circuit becomes one eighth. Accordingly, each of the resistance value and parasitic capacitance of the wiring GL becomes one eighth, whereby degradation and delay of a signal can be reduced and the time for rewriting image data can be easily ensured.

According to the display apparatus 10B of one embodiment of the present invention, sufficient time for writing image data can be easily ensured, and thus high-speed rewriting of a display image can be achieved. Thus, a display apparatus with high display quality can be provided. In particular, a display apparatus that excels in displaying a moving image can be provided.

The display apparatus 10B according to one embodiment of the present invention is described as the example in which the display portion 13 is divided into the 32 sub-display portions 19. However, the division number of the display portion 13 in the display apparatus 10B of one embodiment of the present invention may be 16, 64, 128, or the like, without limitation to 32. As the division number of the display portion 13 increases, a reduction in practical display quality perceived by the user can be smaller.

At least part of the structure examples, the drawings corresponding thereto, and the like described in this embodiment can be combined with any of the other structure examples, the other drawings corresponding thereto, and the like as appropriate.

### Embodiment 3

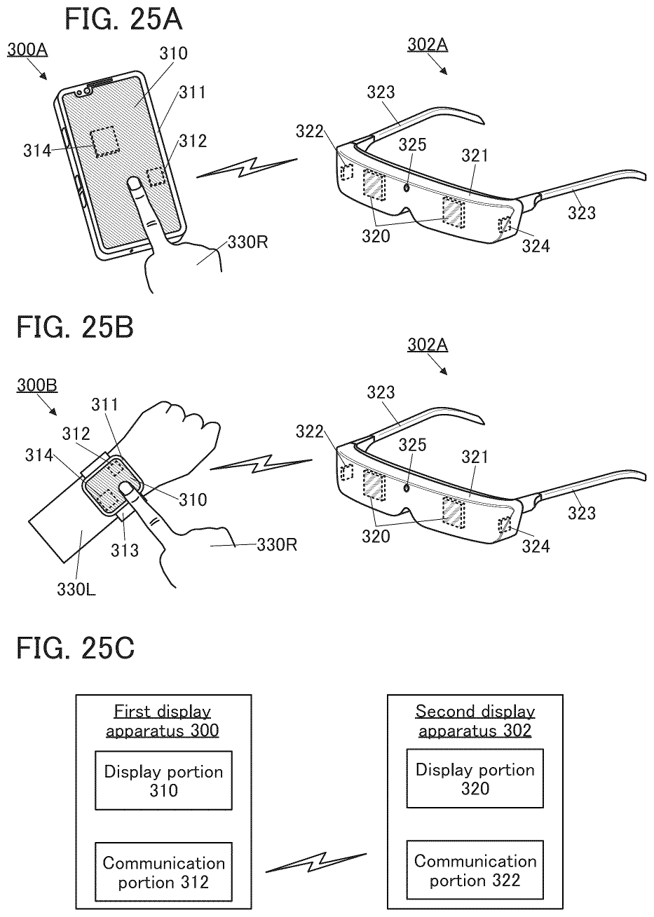

In this embodiment, display apparatuses and display systems of one embodiment of the present invention will be described with reference to FIG. 25 to FIG. 27.

### Structure Examples of Display Apparatus and Display System

FIG. 25A to FIG. 25C are diagrams illustrating structure examples of display apparatuses and display systems of one embodiment of the present invention.

As illustrated in FIG. 25A, a display system of one embodiment of the present invention includes a first display apparatus 300A and a second display apparatus 302A. The first display apparatus 300A and the second display apparatus 302A each have a wireless communication function. The second display apparatus 302A includes a region having a pixel density (also referred to as definition) higher than that of the first display apparatus 300A. With use of the above wireless communication function, a screen of the first display apparatus 300A or part of the screen can be displayed on the second display apparatus 302A.

As illustrated in FIG. 25A, the display system of one embodiment of the present invention includes a plurality of display apparatuses. The plurality of display apparatuses perform data communication using a wireless communication function and image data displayed on a screen of one display apparatus can be partly processed by a processing method such as up-conversion or down-conversion of the data, so that the processed data can be displayed on another display apparatus. Such a display system enables greater user convenience, displaying an image with the most suitable image quality for an individual display apparatus, or lower power consumption of the display apparatuses.

The first display apparatus 300A includes a display portion 310, a housing 311, a communication portion 312, and a control portion 314. Note that FIG. 25A illustrates a right hand 330R of the user. The second display apparatus 302A includes a display portion 320, a housing 321, a communication portion 322, a wearing portion 323, a control portion 324, and a camera portion 325. Wireless communication between the first display apparatus 300A and the second display apparatus 302A can be performed between the communication portion 312 and the communication portion 322, as illustrated in FIG. 25A. The communication portion 312 has a function of transmitting information to the second display apparatus 302A in accordance with the manipulation with the first display apparatus 300A. The communication portion 322 has a function of transmitting information to the first display apparatus 300A in accordance with the manipulation with the second display apparatus 302A.

The camera portion 325 included in the second display apparatus 302A has a function of obtaining external information. Data obtained by the camera portion 325 can be output to the display portion 320 or the display portion 310 included in the first display apparatus 300A, for example. The wearing portion 323 included in the second display apparatus 302A enables the user to put the second display apparatus 302A on the head. FIG. 25A or the like illustrates an example where the wearing portion 323 has a shape like a temple (also referred to as a joint or the like) of glasses; however, one embodiment of the present invention is not limited thereto. The wearing portion 323 can have any shape with which the user can wear and can have a shape of a helmet or a band, for example.

Although an example in which the camera portion 325 is provided is described here, a range sensor (hereinafter, also referred to as a sensing portion) that is capable of measuring a distance from an object may be provided. That is, the camera portion 325 is one embodiment of the sensing portion. As the sensing portion, an image sensor or a distance image sensor such as LIDAR (Light Detection and Ranging) can be used, for example. With use of images obtained by the camera and images obtained by the distance image sensor, more pieces of information can be obtained and a gesture operation with higher accuracy is possible.

The user can manipulate an image (also referred to as data or an object) displayed on the display portion 320 of the second display apparatus 302A with an intuitive gesture operation as if the image is an actual object. The user may register a specific gesture operation in advance in the second display apparatus 302A to link it to the specific processing.

It is preferable to provide a plurality of sensing portions in a display apparatus or an electronic device so that a highly accurate gesture operation by the user using a plurality of actions such as a movement using both hands can be provided for the operation of the display apparatus or the electronic device. This enables three-dimensional positional information on a plurality of objects to be detected with higher accuracy, so that input with a complicated gesture operation is possible.

Note that the processing that can be executed by the first display apparatus 300A and the second display apparatus 302A in this embodiment is merely an example, and various types of processing can be executed in accordance with application software incorporated in the first display apparatus 300A and the second display apparatus 302A.

Next, a structure example different from that illustrated in FIG. 25A is described with reference to FIG. 25B.

A first display apparatus 300B illustrated in FIG. 25B includes the display portion 310, the housing 311, the communication portion 312, a band 313, and the control portion 314. FIG. 25B illustrates the user's right hand 330R and a user's left hand 330L. The structure of the second display apparatus 302A illustrated in FIG. 25B is similar to the structure illustrated in FIG. 25A; thus, the description thereof is omitted here.

The first display apparatus 300A illustrated in FIG. 25A has a function of what is called a portable information terminal (typically, a smartphone and the like), and the first display apparatus 300B illustrated in FIG. 25B has a function of what is called a watch-type portable information terminal. Note that the first display apparatus 300A and the first display apparatus 300B have at least one or both of a calling function and a time display function. The second display apparatus 302A has a function of displaying contents of augmented reality (AR), virtual reality (VR), substitutional reality (SR), or mixed reality (MR).

Next, display apparatuses and display systems of one embodiment of the present invention are described with reference to FIG. 25C.

FIG. 25C is a diagram illustrating display apparatuses and a display system of one embodiment of the present invention. As illustrated in FIG. 25C, a first display apparatus 300 includes at least the display portion 310 and the communication portion 312, and a second display apparatus 302 includes the display portion 320 and the communication portion 322.

The display apparatus described in Embodiment 1 can be used for the display panel portion 320. The display apparatus described in Embodiment 1 can also be used for the display portion 310 of the first display apparatus 300B, which is a watch-type portable information terminal. Note that the display apparatus described in Embodiment 1 can also be used for the display portion 310 of the first display apparatus 300A, if possible.

Note that FIG. 25C illustrates an example in which the first display apparatus 300 and the second display apparatus 302 have the same function; however, one embodiment of the present invention is not limited thereto, and the first display apparatus 300 and the second display apparatus 302 may have different functions.

The display portion 320 preferably has a higher resolution than the display portion 310. The display portion 320 preferably has a higher pixel density (definition) than the display portion 310. Note that the display portion 310 and the display portion 320 may have different screen ratios (aspect ratios).

The display system of one embodiment of the present invention can include two display apparatuses that differ in at least one of the resolution and the pixel density. In that case, in order for one of the display apparatuses to have image data that can be suitably displayed on the other display apparatus, part or the whole of image data can be compressed or extended. Note that two display apparatuses having the same resolution and pixel density may be used; in that case, the same image data can be used.

By increasing the resolution or definition of the display portion 320, the pixels can be imperceptible (e.g., lines that might be caused between pixels can be invisible) to the user and accordingly the user can reach a higher level of immersion, realistic sensation, and sense of depth.

As illustrated in FIG. 25A, the first display apparatus 300A has a period during which display is not performed by the display portion, and functions as an input/output means (e.g., a controller) of the second display apparatus 302A in that period. Such a function can extend the usage period of a power supply portion included in the first display apparatus 300A. In other words, the display system of one embodiment of the present invention can achieve power saving.

Next, the components of the display apparatuses and the display systems illustrated in FIG. 25A to FIG. 25C are described below.

### Display Portion

The display portion 310 and the display portion 320 each have a function of performing display. For the display portion 310 and the display portion 320, one or more selected from a liquid crystal display device, a light-emitting device including organic EL, and a light-emitting device including a light-emitting diode such as a micro LED can be used, for example. In consideration of productivity and emission efficiency, a light-emitting device including organic EL is suitably used for the display portion 310 and the display portion 320.

In addition, the display portion 310 preferably has a function of a touch panel. In particular, a capacitive touch sensor is preferably used, in which case the thickness can be reduced. When the display portion 310 functions as a touch panel, the first display apparatus 300A (or the first display apparatus 300B) can be used alone as a portable information terminal. When the second display apparatus 302 is worn, the display portion 310 can be used as an input device such as a touch pad, which is preferable because it is not necessary to connect another input device such as a controller to the display portion 310.

### Communication Portion

The communication portion 312 and the communication portion 322 each have a wireless or wired communication function. It is particularly suitable that the communication portion 312 and the communication portion 322 each have a wireless communication function, in which case the number of components such as a cable for connection can be reduced.

When the communication portion 312 and the communication portion 322 each have a wireless communication function, the communication portion 312 and the communication portion 322 can communicate through an antenna. As the communication means (communication method) between the communication portion 312 and the communication portion 322, for example, a computer network such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network) can be used. For wireless communication, it is possible to use, as a communication protocol or a communication technology, a communication standard such as the fourth-generation mobile communication system (4G) or the fifth-generation mobile communication system (5G), or a communication standard developed by IEEE such as Wi-Fi (registered trademark) or Bluetooth (registered trademark).

The first display apparatus 300 and the second display apparatus 302 may each independently include components described below.

### Control Portion

The control portion has a function of controlling the display portion. The control portion includes a pixel circuit, a backup circuit, and an image conversion circuit, for example. Note that the image conversion circuit can perform up-conversion processing or down-conversion processing of image data. Thus, image data with low resolution can be up-converted or image data with high resolution can be down-converted according to the resolution of the display portion, which enables the display portion to display an image with high display quality.

### Power Supply Portion

The power supply portion has a function of supplying power to the display portion. As the power supply portion, a primary battery or a secondary battery can be used, for example. As the secondary battery, a lithium-ion secondary battery can be preferably used, for example.

### Sensor Portion

The sensor portion has a function of obtaining information on one or more of the senses of sight, hearing, touch, taste, and smell of the user. Specifically, the sensor portion has a function of measuring at least one of force, displacement, position, speed, acceleration, angular velocity, rotational frequency, distance, light, magnetism, temperature, sound, time, electric field, current, voltage, electric power, radiation, humidity, gradient, oscillation, a smell, and infrared rays.

The sensor portion preferably has a function of measuring brain waves in addition to the above function. For example, the sensor portion, which has a plurality of electrodes in contact with the user's head, can have a mechanism of measuring brain waves from a weak current flowing through the electrodes. With the sensor portion having a function of measuring brain waves, the display portion 320 can display an image on a (coordinate) that the user expects. In that case, the user does not need to use both hands to operate the display apparatus and can perform an input operation or the like with nothing in the hands (with both hands being free).

### Example of Image

Next, examples of images of the display apparatus and the display system of one embodiment of the present invention are described.

Hereinafter, examples of a manipulation method that a user can experience with the display system of one embodiment of the present invention and examples of an image that can be presented to the user are described.

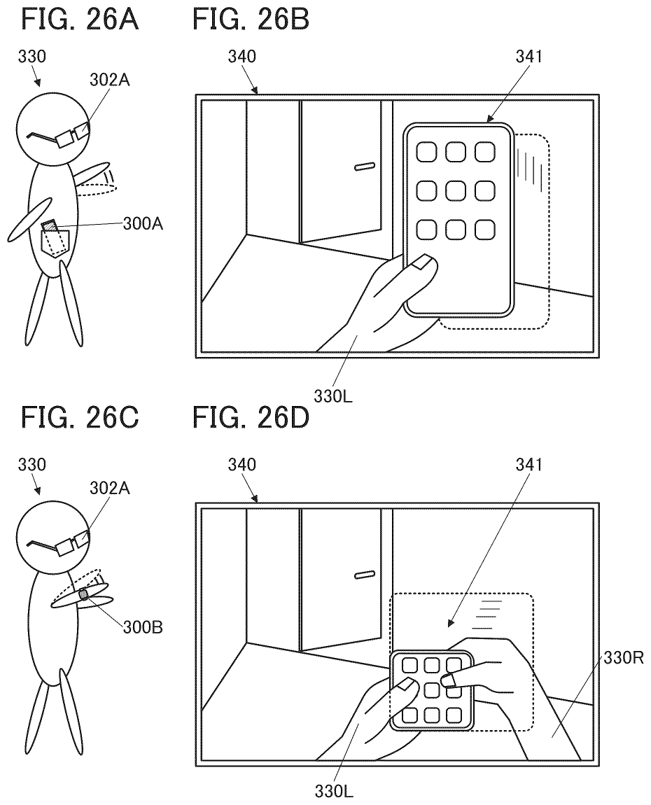

FIG. 26A illustrates a state where a user 330 wearing the second display apparatus 302A with an eyeglass-like shape performs a gesture operation. At this time, the display portion of the first display apparatus 300A is off, so that the power consumption of the first display apparatus 300A can be reduced. In addition, the first display apparatus 300A is in a pocket of the clothes of the user 330; thus, the user 330 can operate the display system with both hands being free.

FIG. 26B illustrates an example of an image 340 in the field of view of the user 330 illustrated in FIG. 26A in a room. In the image 340 illustrated in FIG. 26B, image information 341 is superimposed on a captured image of a real-world indoor scenery including a floor, a wall, a door, and the like. Here, the image information 341 is part of an image displayed on the display portion of the first display apparatus 300A. The user 330 wearing the second display apparatus 302A can operate the first display apparatus 300A (e.g., a smartphone) that is paired with the second display apparatus 302A.

When the user 330 performs a movement of holding a space where the image information 341 is shown with the left hand 330L, the second display apparatus 302A recognizes this movement as a gesture operation and makes the position of the image information 341 changeable. The movement of the left hand 330L of the user 330 in this state can change the position of the image information 341 in accordance with the movement of the left hand 330L, as illustrated in FIG. 26B. At this time, the image information 341 can be not only moved left and right, up and down, and back and forth but also rotated in accordance with the movement of the left hand 330L. The image information 341 may be scrolled.

FIG. 26C illustrates a state where the user 330 performs a gesture operation using both hands. The user 330 wears the first display apparatus 300B with the display portion turned off on his/her arm.

When the user 330 performs a movement of holding the space where the image information 341 is shown with the left hand 330L and the right hand 330R as illustrated in FIG. 26D, the second display apparatus 302A recognizes this movement as a gesture operation and makes the shape of the image information 341 changeable. When the left hand 330L and the right hand 330R become close to each other in this state, the shape of the image information 341 is changed such that the image information 341 is downsized as illustrated in FIG. 26D. By contrast, when the left hand 330L and the right hand 330R become apart from each other, the image information 341 can be enlarged. At this time, the image information 341 can be moved or rotated in accordance with the movements of the left hand 330L and the right hand 330R. The image information 341 may be scrolled.

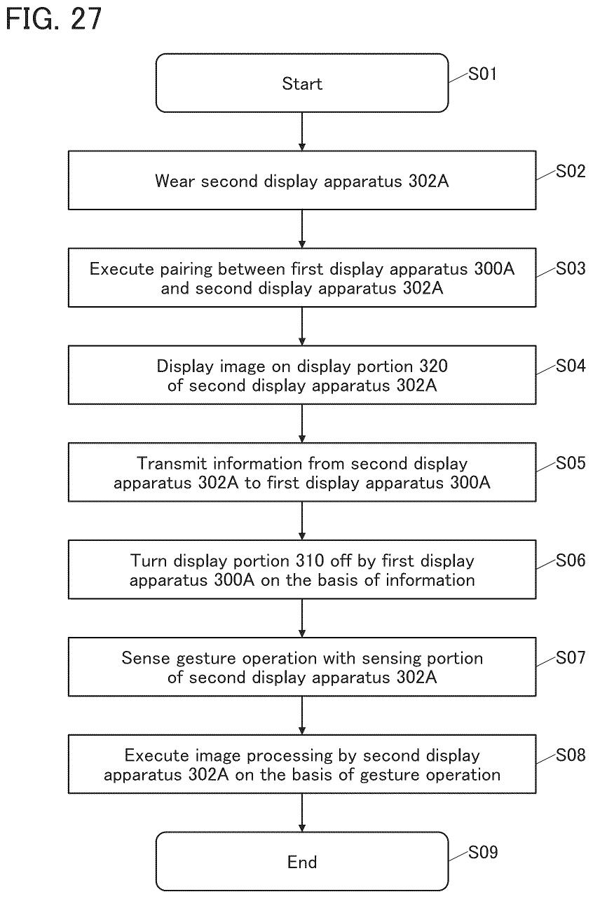

Next, an example of an operation method of the display system of one embodiment of the present invention is described with reference to FIG. 27.

### Operation Method Example of Display System

An example of an operation method of the display system is described below. FIG. 27 is a flowchart for the operation method of the display system.

In Step S01, the operation starts. At this time, the first display apparatus 300A is in a start-up state (a state where a manipulation is possible), and the second display apparatus 302A is in a power-on state.

In Step S02, the user wears the second display apparatus 302A. The second display apparatus 302A recognizes being worn, and the system starts. In Step S02, for example, when the second display apparatus 302A has a goggles-type shape, an image of the front view of a camera may be presented to the user or an image of other contents may be displayed.

In Step S03, pairing between the first display apparatus 300A and the second display apparatus 302A is executed. When the pairing is completed, the first display apparatus 300A and the second display apparatus 302A are in a state where two-way data communication is possible.

In Step S04, a first image displayed on the display portion 310 of the first display apparatus 300A is displayed on the display portion 320 of the second display apparatus 302A. Accordingly, the user can see information displayed on the second display apparatus 302A without looking at the screen of the first display apparatus 300A.

At this time, since the pixel density of the display portion differs between the first display apparatus 300A and the second display apparatus 302A, instead of displaying the first image as it is, a second image, which is obtained by performing image processing such as up-conversion or down-conversion on the first image so that the image can have an optimal size when displayed on the display portion 320 of the second display apparatus 302A, is preferably displayed on the second display apparatus 302A.

In Step S05, information is transmitted from the second display apparatus 302A to the first display apparatus 300A. The information includes, for example, a code that means the completion of display of the first image.

In Step S06, the display portion 310 of the first display apparatus 300A is turned off on the basis of the received information. At this time, the first display apparatus 300A maintains a touch sensor of the display portion 310 in an active state. Accordingly, the display portion 310 of the first display apparatus 300A functions as an input means (a touch pad) or the like.

In Step S07, the second display apparatus 302A senses a gesture operation of the user with the sensing portion included in the second display apparatus 302A and obtains gesture information corresponding to the gesture operation. In the case where the second display apparatus 302A includes a plurality of sensing portions, a gesture operation is sensed by all or two or more of the plurality of sensing portions. This enables three-dimensional positional information on a plurality of objects to be detected with higher accuracy, so that input with a complicated gesture operation is possible.

In Step S08, the second display apparatus 302A executes various types of processing on the basis of the gesture information. For example, image processing is performed on image information displayed on the display portion 320 of the second display apparatus 302A, and the image information that has been subjected to the image processing can be displayed on the display portion 320.

In Step S09, the processing ends. Step S09 corresponds to detaching the second display apparatus 302A, turning off the power of the first display apparatus 300A or the second display apparatus 302A, or canceling the pairing between the first display apparatus 300A and the second display apparatus 302A, for example.

The above is the description of the operation method example of the display system of one embodiment of the present invention.

At least part of this embodiment can be implemented in combination with the other embodiments described in this specification as appropriate.

### Embodiment 4

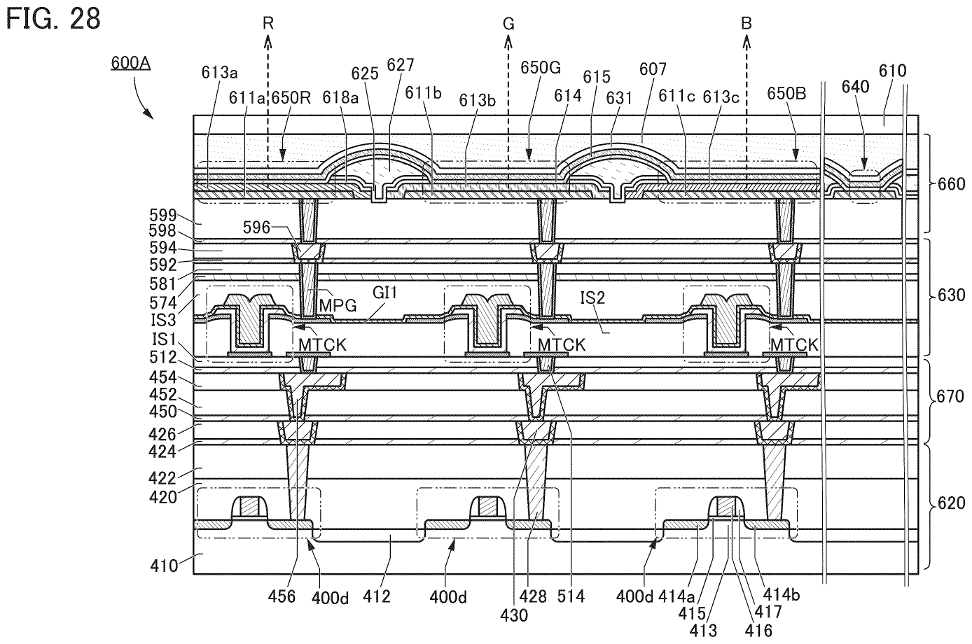

In this embodiment, display apparatuses of one embodiment of the present invention will be described with reference to FIG. 28 to FIG. 34. The display apparatus exemplified below can be used as the display apparatus (semiconductor device) included in the electronic device described in the above embodiment.

### Structure Example 1 of Display Apparatus

FIG. 28 is a cross-sectional view of a display apparatus 600A. The display apparatus 600A is an example of a display apparatus having an MML (metal maskless) structure. In other words, the display apparatus 600A includes a light-emitting device that is formed without using a fine metal mask.

An island-shaped light-emitting layer of the light-emitting device included in the display apparatus having an MML structure is formed in the following manner: a light-emitting layer is formed on the entire surface, and then, the light-emitting layer is processed by a photolithography method. Accordingly, a high-definition display apparatus or a display apparatus with a high aperture ratio, which has been difficult to achieve, can be manufactured. Moreover, light-emitting layers can be formed separately for the respective colors, enabling the display apparatus to perform extremely clear display with high contrast and high display quality. For example, in the case where the display apparatus includes three kinds of light-emitting devices, which are a light-emitting device emitting blue light, a light-emitting device emitting green light, and a light-emitting device emitting red light, three kinds of island-shaped light-emitting layers can be formed by repeating the set of formation of a light-emitting layer and processing by photolithography three times.

Note that a device having an MML structure can be manufactured without using a metal mask, and thus can break through the definition limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having an MML structure. An MML structure can reduce the manufacturing cost as described above, and thus is suitable for mass production of the device.

It is not necessary to conduct a pseudo improvement in definition by employing a unique pixel arrangement such as a PenTile arrangement in a display apparatus employing an MML structure; thus, the display apparatus can achieve high definition (e.g., higher than or equal to 500 ppi, higher than or equal to 1000 ppi, higher than or equal to 2000 ppi, higher than or equal to 3000 ppi, or higher than or equal to 5000 ppi) while having what is called a stripe arrangement where R, G, and B subpixels are arranged in one direction.

Moreover, providing a sacrificial layer over the light-emitting layer can reduce damage to the light-emitting layer in the manufacturing process of the display apparatus, resulting in an improvement in reliability of the light-emitting device. Note that the sacrificial layer may remain in the completed display apparatus or may be removed in the fabrication process. For example, a sacrificial layer 618a illustrated in FIG. 28 to FIG. 30 is part of the sacrificial layer provided over the light-emitting layer.

A light-emitting device can be manufactured through a relatively simple process, by employing a film formation step using an area mask and a processing step using a resist mask.

FIG. 28 is a schematic cross-sectional view of the display apparatus 600A that is a display apparatus (a semiconductor device) of one embodiment of the present invention. For example, the display apparatus 600A is an example of a cross section of the semiconductor device 130 described in Embodiment 1. The display apparatus 600A has a structure including a pixel circuit, a driver circuit, and the like provided over a substrate 410. Note that in the display apparatus 600A in FIG. 28, a wiring layer 670 is illustrated in addition to an element layer 620, an element layer 630, and an element layer 660. The wiring layer 670 is a layer provided with a wiring.

A pixel circuit of the display apparatus is preferably provided in the element layer 630. A driver circuit (one or both of a gate driver and a source driver) of the display apparatus is preferably provided in the element layer 620. One or more of a variety of circuits such as an arithmetic circuit and a memory circuit may be provided in the element layer 620.

The element layer 620 includes the substrate 410, for example, and a transistor 400d is formed over the substrate 410. The wiring layer 670 is provided above the transistor 400d, and a wiring for electrically connecting the transistor 400d to a conductive layer, a transistor, or the like provided in the element layer 630 (a conductor 514 in FIG. 28) is provided in the wiring layer 670. The element layer 630 and the element layer 660 are provided above the wiring layer 670, and the element layer 630 includes the transistors MTCK and the like, for example. The element layer 660 includes light-emitting devices 650 (a light-emitting device 650R, a light-emitting device 650G, and a light-emitting device 650B in FIG. 28), and the like.

The transistor 400d is an example of a transistor included in the element layer 620. The transistor MTCK is an example of a transistor included in the element layer 630. The light-emitting devices (the light-emitting device 650R, the light-emitting device 650G, and the light-emitting device 650B) are examples of the light-emitting devices included in the element layer 660.

As the substrate 410, a semiconductor substrate (e.g., a single crystal substrate containing silicon or germanium as a material) can be used, for example. Besides the semiconductor substrate, for example, an SOI (Silicon On Insulator) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, or paper or a base material film containing a fibrous material can be used as the substrate 410. In description of this embodiment, the substrate 410 is a semiconductor substrate containing silicon as a material. Therefore, a transistor included in the element layer 620 can be a Si transistor.

The transistor 400d includes an element isolation layer 412, a conductor 416, an insulator 415, an insulator 417, a semiconductor region 413 that is part of the substrate 410, and a low-resistance region 414a and a low-resistance region 414b that function as a source region and a drain region. Thus, the transistor 400d is a Si transistor. Although FIG. 28 illustrates a structure in which one of a source and a drain of the transistor 400d is electrically connected to the conductor 514 provided in the element layer 630 through a conductor 428, a conductor 430, and a conductor 456, the electrical connection structure in the display apparatus of one embodiment of the present invention is not limited thereto.

The transistor 400d can be a Fin type when, for example, the top surface of the semiconductor region 413 and the side surface thereof in the channel width direction are covered with the conductor 416 with the insulator 415 functioning as a gate insulator therebetween. The effective channel width can be increased in the Fin-type transistor 400d, so that the on-state characteristics of the transistor 400d can be improved. In addition, since contribution of an electric field of a gate electrode can be increased, the off-state characteristics of the transistor 400d can be improved. Alternatively, the transistor 400d may have a planar structure instead of a Fin-type structure.

Note that the transistor 400d can be either a p-channel transistor or an n-channel transistor. Alternatively, a plurality of the transistors 400d may be provided and both the p-channel transistor and the n-channel transistor may be used.

A region of the semiconductor region 413 where a channel is formed, a region in the vicinity thereof, and the low-resistance region 414a and the low-resistance region 414b that function as the source region and the drain region preferably contain a silicon-based semiconductor, specifically, preferably contain single crystal silicon. Alternatively, each of the regions may be formed using germanium, silicon germanium, gallium arsenide, aluminum gallium arsenide, or gallium nitride, for example. A structure using silicon whose effective mass is controlled by applying stress to a crystal lattice and changing lattice spacing may be employed. Alternatively, the transistor 400d may be a HEMT (High Electron Mobility Transistor) using gallium arsenide and aluminum gallium arsenide, for example.

For the conductor 416 functioning as a gate electrode, a semiconductor material such as silicon containing an element that imparts n-type conductivity, such as arsenic or phosphorus, or an element that imparts p-type conductivity, such as boron or aluminum, can be used. Alternatively, for the conductor 416, a conductive material such as a metal material, an alloy material, or a metal oxide material can be used, for example.

Note that since a work function depends on the material of the conductor, the threshold voltage of the transistor can be adjusted by selecting the material of the conductor. Specifically, it is preferable to use one or both of titanium nitride and tantalum nitride as the material of the conductor. Moreover, for both conductivity and embeddability, it is preferable to use stacked layers of metal materials of one or both of tungsten and aluminum as the conductor, and it is particularly preferable to use tungsten in terms of heat resistance.

The element isolation layer 412 is provided to separate a plurality of transistors formed on the substrate 410 from each other. The element isolation layer can be formed by, for example, a LOCOS (Local Oxidation of Silicon) method, an STI (Shallow Trench Isolation) method, or a mesa isolation method.

Over the transistor 400d illustrated in FIG. 28, an insulator 420 and an insulator 422 are sequentially stacked from the substrate 410 side.

For each of the insulator 420 and the insulator 422, one or more selected from silicon oxide, silicon oxynitride, silicon nitride oxide, silicon nitride, aluminum oxide, aluminum oxynitride, aluminum nitride oxide, and aluminum nitride are used, for example.

The insulator 422 may have a function of a planarization film for eliminating a level difference caused by the transistor 400d or the like covered with the insulator 420 and the insulator 422. For example, a top surface of the insulator 422 may be planarized by planarization treatment using a chemical mechanical polishing (CMP) method or the like to improve planarity.

The conductor 428 connected to the transistor MTCK and the like provided above the insulator 422 is embedded in the insulator 420 and the insulator 422. The conductor 428 has a function of a plug or a wiring.

In the display apparatus 600A, the wiring layer 670 is provided over the transistor 400d. The wiring layer 670 includes, for example, an insulator 424, an insulator 426, the conductor 430, an insulator 450, an insulator 452, an insulator 454, and the conductor 456.

Over the insulator 422 and the conductor 428, the insulator 424 and the insulator 426 are sequentially stacked. An opening is formed in the insulator 424 and the insulator 426 in a region overlapping with the conductor 428. In addition, the conductor 430 is embedded in the opening.

The insulator 450, the insulator 452, and the insulator 454 are sequentially stacked over the insulator 426 and the conductor 430. An opening is formed in the insulator 450, the insulator 452, and the insulator 454 in a region overlapping with the conductor 430. The conductor 456 is embedded in the opening.

The conductor 430 and the conductor 456 have a function of a plug or a wiring that is connected to the transistor 400d.

Note that like an insulator 592 described later, for example, the insulator 424 and the insulator 450 are preferably formed using an insulator having a barrier property against one or more selected from hydrogen, oxygen, and water. Like an insulator 594 described later, each of the insulator 426, the insulator 452, and the insulator 454 is preferably formed using an insulator having a relatively low dielectric constant to reduce parasitic capacitance generated between wirings. Each of the insulator 426, the insulator 452, and the insulator 454 has functions of an interlayer insulating film and a planarization film. Furthermore, each of the insulator 426, the insulator 452, and the insulator 454 preferably includes an insulator having a barrier property against one or more selected from hydrogen, oxygen, and water.

For the conductor having a barrier property against hydrogen, tantalum nitride is preferably used, for example. In addition, using a stack of tantalum nitride and tungsten, which has high conductivity, can inhibit diffusion of hydrogen from the transistor 400d while the conductivity of a wiring is kept. In that case, the tantalum nitride layer having a barrier property against hydrogen is preferably in contact with the insulator 450 having a barrier property against hydrogen.

An insulator 512 is provided above the insulator 454 and the conductor 456. An insulator IS1 is provided over the insulator 512. A conductor functioning as a plug or a wiring is embedded in the insulator IS1 and the insulator 512. Thus, the transistor 400d can be electrically connected to the conductor 514 provided in the element layer 630. Alternatively, a source or a drain of the transistor MTCK and the source or the drain of the transistor 400d may be electrically connected to each other.

The transistor MTCK is provided over the insulator IS1. An insulator IS3, an insulator 574, and an insulator 581 are stacked in this order over the transistor MTCK. A conductor MPG functioning as a plug or a wiring is embedded in the insulator IS3, the insulator 574, and the insulator 581. Note that the transistor MTCK and an insulator, a conductor, and a semiconductor which are around the transistor MTCK are described later in this embodiment.

The insulator 574 preferably has a function of inhibiting diffusion of impurities such as water and hydrogen (e.g., one or both of a hydrogen atom and a hydrogen molecule). In other words, the insulator 574 preferably functions as a barrier insulating film that inhibits the entry of the impurities into the transistor MTCK. Moreover, the insulator 574 preferably has a function of inhibiting diffusion of oxygen (e.g., one or both of an oxygen atom and an oxygen molecule). For example, the insulator 574 preferably has a lower oxygen permeability than an insulator IS2 and the insulator IS3.

Thus, the insulator 574 preferably functions as a barrier insulating film that inhibits diffusion of impurities such as water and hydrogen. Accordingly, it is preferable to use, for the insulator 574, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (an insulating material through which the impurities are unlikely to pass). Alternatively, it is preferable to use an insulating material having a function of inhibiting diffusion of oxygen (e.g., one or both of an oxygen atom and an oxygen molecule) (an insulating material through which the oxygen is unlikely to pass).

An insulator having a function of inhibiting the passage of oxygen and impurities such as water and hydrogen can be formed to have a single layer or a stacked layer including an insulator containing one or more selected from boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum, for example. Specific examples of the insulator having a function of inhibiting the passage of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulator having a function of inhibiting the passage of oxygen and impurities such as water and hydrogen include oxides containing aluminum and hafnium (hafnium aluminate). Other examples of the insulator having a function of inhibiting the passage of oxygen and impurities such as water and hydrogen include metal nitrides such as aluminum nitride, aluminum titanium nitride, titanium nitride, silicon nitride oxide, and silicon nitride.

In particular, aluminum oxide or silicon nitride is preferably used for the insulator 574. Accordingly, it is possible to inhibit diffusion of impurities such as water and hydrogen to the transistor MTCK side from above the insulator 574. In addition, it is possible to inhibit diffusion of oxygen contained in the insulator IS3 or the like to above the insulator 574.

The insulator 581 is preferably a film functioning as an interlayer film and having a lower permittivity than the insulator 574. When a material with a lower permittivity is used for an interlayer film, parasitic capacitance generated between wirings can be reduced. The dielectric constant of the insulator 581 is preferably lower than 4, further preferably lower than 3, for example. The dielectric constant of the insulator 581 is, for example, preferably 0.7 times or less, further preferably 0.6 times or less the dielectric constant of the insulator 574. When a material with a low permittivity is used for the insulator 581 functioning as an interlayer film, parasitic capacitance generated between wirings can be reduced.

The concentration of impurities such as water and hydrogen in the insulator 581 is preferably reduced. In this case, for the insulator 581, silicon oxide, silicon oxynitride, silicon nitride oxide, or silicon nitride can be used, for example. Alternatively, for the insulator 581, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulator 581, a resin can be used. A material that can be used for the insulator 581 may be an appropriate combination of the above-described materials.

An insulator 592 and an insulator 594 are stacked in this order over the insulator 574 and the insulator 581.

For the insulator 592, it is preferable to use an insulating film having a barrier property (referred to as a barrier insulating film) which can prevent diffusion of impurities such as water and hydrogen from the substrate 410 or the transistor MTCK to a region above the insulator 592 (e.g., the region where the light-emitting device 650R, the light-emitting device 650G, the light-emitting device 650B, and the like are provided). Accordingly, for the insulator 592, it is preferable to use an insulating material that has a function of inhibiting diffusion of impurities such as a hydrogen atom, a hydrogen molecule, and a water molecule (through which the above impurities are less likely to pass). Furthermore, depending on the situation, for the insulator 592, it is preferable to use an insulating material that has a function of inhibiting diffusion of impurities such as a nitrogen atom, a nitrogen molecule, a nitrogen oxide molecule (e.g., N₂O, NO, and NO₂), and a copper atom (an insulating material through which the above oxygen is less likely to pass). It is preferable that the insulator 592 have a function of inhibiting diffusion of oxygen (e.g., one or both of an oxygen atom and an oxygen molecule).

For the film having a barrier property against hydrogen, silicon nitride formed by a CVD method can be used, for example.

The amount of released hydrogen can be analyzed by thermal desorption spectroscopy (TDS), for example. The amount of hydrogen released from the insulator 424 that is converted into hydrogen atoms per area of the insulator 424 is less than or equal to 10×10¹⁵ atoms/cm², preferably less than or equal to 5×10¹⁵ atoms/cm², in the TDS analysis in a film-surface temperature range of 50° C. to 500° C., for example.

Like the insulator 581, the insulator 594 is preferably an interlayer film with a low permittivity. Thus, for the insulator 594, a material that can be used for the insulator 581 can be used.

Note that the insulator 594 preferably has a lower permittivity than the insulator 592. The dielectric constant of the insulator 594 is preferably lower than 4, further preferably lower than 3, for example. The dielectric constant of the insulator 594 is, for example, preferably 0.7 times or less, further preferably 0.6 times or less the dielectric constant of the insulator 592. When a material with a low permittivity is used for the insulator 594 functioning as an interlayer film, parasitic capacitance generated between wirings can be reduced.

A conductor MPG functioning as a plug or a wiring is embedded in the insulator GI1 and the insulator IS3, and a conductor 596 functioning as a plug or a wiring is embedded in the insulator 592 and the insulator 594. In particular, the conductor MPG and the conductor 596 are electrically connected to the light-emitting device or the like provided above the insulator 594. A plurality of conductors functioning as plugs or wirings are collectively denoted by the same reference numeral in some cases. In this specification and the like, a wiring and a plug connected to the wiring may be a single component. That is, part of a conductor functions as a wiring in some cases and part of the conductor functions as a plug in other cases.

As a material of each of plugs and wirings (e.g., the conductor MPG, the conductor 428, the conductor 430, the conductor 456, the conductor 514, and the conductor 596), a single layer or a stacked layer of one or more conductive materials selected from a metal material, an alloy material, a metal nitride material, and a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used for formation. The use of a low-resistance conductive material can reduce wiring resistance.

An insulator 598 and an insulator 599 are sequentially formed over the insulator 594 and the conductor 596.

Like the insulator 592, for example, the insulator 598 is preferably formed using an insulator having a barrier property against one or more selected from hydrogen, oxygen, and water. Like the insulator 594, the insulator 599 is preferably formed using an insulator having a relatively low dielectric constant to reduce parasitic capacitance generated between wirings. The insulator 599 has functions of an interlayer insulating film and a planarization film.

The light-emitting device 650 and a connection portion 640 are formed over the insulator 599. Note that structure examples of the light-emitting device will be described later in Embodiment 5.

The connection portion 640 is referred to as a cathode contact portion in some cases, and is electrically connected to cathode electrodes of the light-emitting device 650R, the light-emitting device 650G, and the light-emitting device 650B. In the connection portion 640 illustrated in FIG. 28, a conductor formed using the same material in the same step as a conductor 611a to a conductor 611c is electrically connected to a common electrode 615 described later. Although FIG. 28 illustrates an example where the conductor is electrically connected to the common electrode 615 through a common layer 614 described later, the conductor and the common electrode 615 may be in direct contact with each other.

Note that the connection portion 640 may be provided to surround four sides of the display portion in the plan view, or may be provided in the display portion (e.g., between adjacent light-emitting devices 650) (not illustrated).

The light-emitting device 650R includes the conductor 611a as a pixel electrode. Similarly, the light-emitting device 650G includes the conductor 611b as a pixel electrode, and the light-emitting device 650B includes the conductor 611c as a pixel electrode.

The conductor 611a, the conductor 611b, and the conductor 611c are connected to the conductor 596 embedded in the insulator 594 through a conductor (plug) embedded in the insulator 599.

The light-emitting device 650R includes a layer 613a, the common layer 614 over the layer 613a, and the common electrode 615 over the common layer 614. The light-emitting device 650G includes a layer 613b, the common layer 614 over the layer 613b, and the common electrode 615 over the common layer 614. The light-emitting device 650B includes a layer 613c, the common layer 614 over the layer 613c, and the common electrode 615 over the common layer 614.

The display apparatus 600A employs an SBS structure. The SBS structure can optimize materials and structures of light-emitting devices and thus can extend freedom of choice of materials and structures, whereby the luminance and the reliability can be easily improved.

The display apparatus 600A has a top-emission structure. The aperture ratio of pixels in a top-emission structure can be higher than that of pixels in a bottom-emission structure because a transistor and the like can be provided so as to overlap with a light-emitting region of a light-emitting device in the top-emission structure.

Note that the layer 613a is formed to cover the top and side surfaces of the conductor 611a. Similarly, the layer 613b is formed to cover the top and side surfaces of the conductor 611b. Similarly, the layer 613c is formed to cover the top and side surfaces of the conductor 611c. Accordingly, regions provided with the conductor 611a, the conductor 611b, and the conductor 611c can be entirely used as the light-emitting regions of the light-emitting device 650R, the light-emitting device 650G, and the light-emitting device 650B, respectively, increasing the aperture ratio of the pixels.

In the light-emitting device 650R, the layer 613a and the common layer 614 can be collectively referred to as an EL layer. Similarly, in the light-emitting device 650G, the layer 613b and the common layer 614 can be collectively referred to as an EL layer. Similarly, in the light-emitting device 650B, the layer 613c and the common layer 614 can be collectively referred to as an EL layer

There is no particular limitation on the structure of the light-emitting device in this embodiment, and the light-emitting device can have a single structure or a tandem structure.

The layer 613a, the layer 613b, and the layer 613c are each processed into an island shape by a photolithography method. At each of end portions of the layer 613a, the layer 613b, and the layer 613c, an angle between the top surface and side surface is approximately 90°. By contrast, for example, an organic film formed using an FMM (Fine Metal Mask) tends to have a thickness that gradually decreases with decreasing distance to an end portion, and has a sloped top surface in an area ranging from 1 μm to 10 μm, both inclusive, toward the end portion for example; thus, such an organic film has a shape whose top surface and side surface cannot be easily distinguished from each other.

The top surface and the side surface of each of the layer 613a, the layer 613b, and the layer 613c are clearly distinguished from one another. Accordingly, regarding the layer 613a and the layer 613b which are adjacent to each other, one of the side surfaces of the layer 613a and one of the side surfaces of the layer 613b are placed to face each other. This applies to a combination of any two of the layer 613a, the layer 613b, and the layer 613c.

The layer 613a, the layer 613b, and the layer 613c each include at least a light-emitting layer. It is preferable that the layer 613a include a red-light-emitting layer, the layer 613b include a green-light-emitting layer, and the layer 613c include a blue-light-emitting layer, for example. Other than the above colors, cyan, magenta, yellow, or white can be employed for the light-emitting layers.

The layer 613a, the layer 613b, and the layer 613c each preferably include a light-emitting layer and a carrier-transport layer (an electron-transport layer or a hole-transport layer) over the light-emitting layer. Since the surfaces of the layer 613a, the layer 613b, and the layer 613c are exposed in the manufacturing process of the display apparatus, providing the carrier-transport layer over the light-emitting layer inhibits the light-emitting layer from being exposed on the outermost surface, so that damage to the light-emitting layer can be reduced. Accordingly, the reliability of the light-emitting devices can be improved.

The common layer 614 includes, for example, an electron-injection layer or a hole-injection layer. Alternatively, the common layer 614 may include a stack of an electron-transport layer and an electron-injection layer, or may include a stack of a hole-transport layer and a hole-injection layer. The common layer 614 is shared between the light-emitting device 650R, the light-emitting device 650G, and the light-emitting device 650B. Note that the common layer 614 is not necessarily provided, and the whole EL layer included in the light-emitting device may be provided in an island shape like the layer 613a, the layer 613b, and the layer 613c.

The common electrode 615 is shared by the light-emitting device 650R, the light-emitting device 650G, and the light-emitting device 650B. As illustrated in FIG. 28, the common electrode 615 shared by the plurality of light-emitting devices is electrically connected to a conductor included in the connection portion 640.

An insulator 625 preferably has a function of a barrier insulating layer against one or both of water and oxygen. Alternatively, the insulator 625 preferably has a function of inhibiting diffusion of one or both of water and oxygen. Alternatively, the insulator 625 preferably has a function of capturing or fixing (also referred to as gettering) one or both of water and oxygen. When the insulator 625 has a function of a barrier insulating layer or a gettering function, entry of impurities (typically, one or both of water and oxygen) that would be diffused into the light-emitting devices from the outside can be inhibited. With this structure, a highly reliable light-emitting device and a highly reliable display apparatus can be provided.

The insulator 625 preferably has a low impurity concentration. Accordingly, degradation of the EL layer, which is caused by entry of impurities into the EL layer from the insulator 625, can be inhibited. In addition, when the impurity concentration is reduced in the insulator 625, a barrier property against one or both of water and oxygen can be increased. For example, it is desirable that one or both of the hydrogen concentration and the carbon concentration in the insulator 625 be sufficiently low.

As an insulator 627, an insulating layer containing an organic material can be favorably used. As the organic material, a photosensitive organic resin is preferably used; for example, a photosensitive resin composition containing an acrylic resin may be used. Note that in this specification and the like, an acrylic resin refers to not only a polymethacrylic acid ester or a methacrylic resin, but also all the acrylic-based polymers in a broad sense in some cases.

The organic material that can be used for the insulator 627 is not limited to the materials given above. For the insulator 627, an acrylic resin, a polyimide resin, an epoxy resin, an imide resin, a polyamide resin, a polyimide-amide resin, a silicone resin, a siloxane resin, a benzocyclobutene-based resin, a phenol resin, or a precursor of any of these resins can be used in some cases, for example. Alternatively, an organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be employed for the insulator 627 in some cases. For the insulator 627, for example, a photoresist can be used as the photosensitive resin in some cases. Note that as the photosensitive resin, a positive material or a negative material can be used.

For the insulator 627, a material absorbing visible light may be used. When the insulator 627 absorbs light from the light-emitting device, leakage of light (stray light) from the light-emitting device to the adjacent light-emitting device through the insulator 627 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). A resin material obtained by stacking or mixing color filter materials of two colors or three or more colors is particularly preferably used to enhance the effect of blocking visible light. In particular, mixing color filter materials of three or more colors enables the formation of a black or nearly black resin layer.

For example, the insulator 627 can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film to be the insulator 627 is preferably formed by spin coating.

The insulator 627 is formed at a temperature lower than the heat resistance temperature of the EL layer. The typical substrate temperature in formation of the insulator 627 is lower than or equal to 200° C., preferably lower than or equal to 180° C., further preferably lower than or equal to 160° C., still further preferably lower than or equal to 150° C., yet still further preferably lower than or equal to 140° C.

In the above, the insulator 627 preferably has a tapered side surface. Such a forward tapered shape (less than 90°, preferably less than or equal to 60°, further preferably less than or equal to) 45° of the end portion of the side surface of the insulator 627 can prevent disconnection, local thinning, or the like from occurring in the common layer 614 and the common electrode 615 which are provided over the end portion of the side surface of the insulator 627, leading to film formation with good coverage. Accordingly, the in-plane uniformity of the common layer 614 and the common electrode 615 can be improved, leading to higher display quality of the display apparatus.

The top surface of the insulator 627 preferably has a convex shape in a cross-sectional view of the display apparatus. The top surface of the insulator 627 preferably has a convex shape that bulges gradually toward the center. The insulator 627 preferably has a shape such that the projecting portion at the center portion of the top surface is connected smoothly to the tapered portion of the end portion of the side surface. When the insulator 627 has such a shape, the common layer 614 and the common electrode 615 can be formed with good coverage over the whole the insulator 627.

The insulator 627 is formed in a region between two EL layers (e.g., a region between the first layer 613a and the second layer 613b). At this time, part of the insulator 627 is placed at a position sandwiched between an end portion of the side surface of one of the EL layers (e.g., the layer 613a) and an end portion of the side surface of the other of the EL layers (e.g., the layer 613b).

One end portion of the insulator 627 preferably overlaps with the conductor 611a serving as a pixel electrode, and the other end portion of the insulator 627 preferably overlaps with the conductor 611b serving as a pixel electrode. Such a structure enables the end portion of the insulator 627 to be formed over flat or substantially flat region in the layer 613a (layer 613b). This makes it relatively easy to process the tapered shape of the insulator 627 as described above.

By providing the insulator 627 and the like in the above manner, a disconnected portion and a locally thinned portion can be prevented from being formed in the common layer 614 and the common electrode 615 from a flat or substantially flat region in the layer 613a to a flat or substantially flat region in the layer 613b. Thus, between the light-emitting devices, a connection defect caused by the disconnected portion and an increase in electric resistance caused by the locally thinned portion can be inhibited from occurring in the common layer 614 and the common electrode 615.

In the display apparatus of this embodiment, the distance between the light-emitting devices can be short. Specifically, the distance between the light-emitting devices, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display apparatus of this embodiment includes a region where a distance between two adjacent island-shaped EL layers is less than or equal to 1 μm, preferably less than or equal to 0.5 μm (500 nm), further preferably less than or equal to 100 nm. The distance between light-emitting devices is shortened in this manner, whereby a high-definition display apparatus with a high aperture ratio can be provided.

A protective layer 631 is provided over the light-emitting device 650. The protective layer 631 is a film serving as a passivation film for protecting the light-emitting devices 650. Provision of the protective layer 631 covering the light-emitting device can inhibit an impurity such as water and oxygen from entering the light-emitting device, and increase the reliability of the light-emitting device 650. For the protective layer 631, aluminum oxide, silicon nitride, or silicon nitride oxide can be used, for example.

The protective layer 631 and a substrate 610 are bonded to each other with an adhesive layer 607. A solid sealing structure, a hollow sealing structure, or the like can be employed to seal the light-emitting devices. In FIG. 28, a solid sealing structure is employed in which a space between the substrate 410 and the substrate 610 is filled with the adhesive layer 607. Alternatively, a hollow sealing structure may be employed, in which the space is filled with an inert gas (e.g., nitrogen or argon). Here, the adhesive layer 607 may be provided not to overlap with the light-emitting devices. The space may be filled with a resin other than the frame-shaped adhesive layer 607.

For the adhesive layer 607, a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-liquid-mixture-type resin may be used. An adhesive sheet may be used.

The display apparatus 600A has a top-emission structure. Light from the light-emitting device is emitted toward the substrate 610 side. Thus, for the substrate 610, a material having a high visible-light-transmitting property is preferably used. For example, as the substrate 610, a substrate having a high visible-light-transmitting property may be selected from substrates usable as the substrate 410. The pixel electrode contains a material that reflects visible light, and a counter electrode (the common electrode 615) contains a material that transmits visible light.

Note that the display apparatus of one embodiment of the present invention may be not a top-emission display apparatus but a bottom-emission display apparatus where light from the light-emitting device is emitted to the substrate 410 side. In that case, a substrate having a high visible-light-transmitting property is selected as the substrate 410.

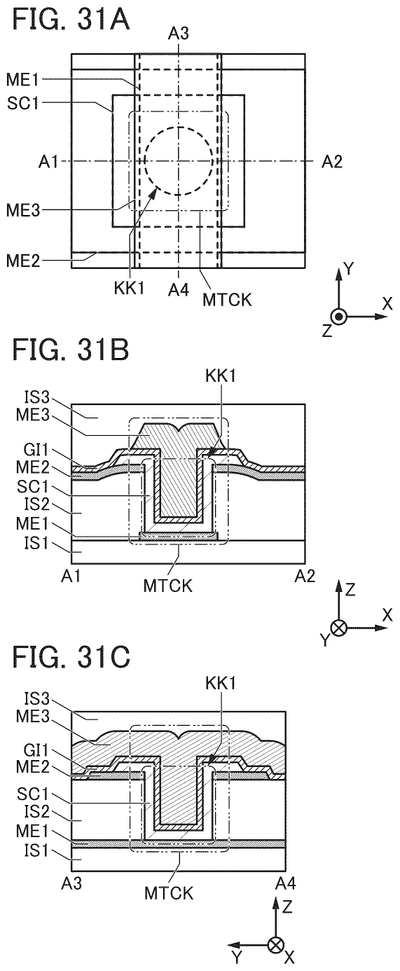

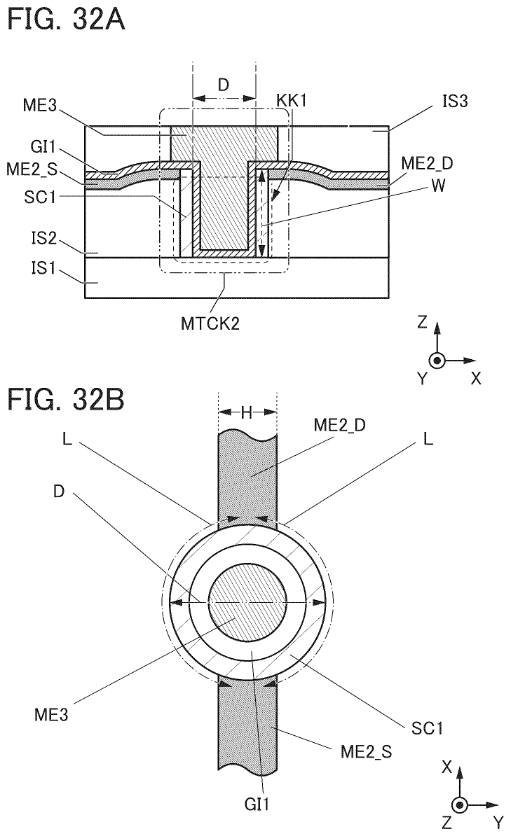

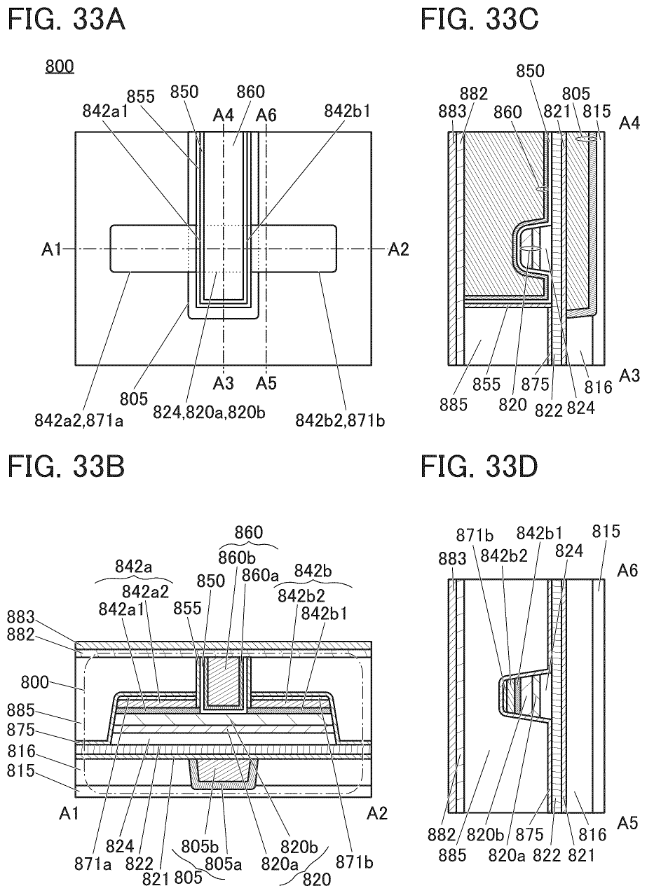

Although the element layer 630 of the display apparatus 600A in FIG. 28 includes the transistor MTCK, one embodiment of the present invention is not limited thereto. Note that there is no particular limitation on the structure of the transistor included in the display apparatus of one embodiment of the present invention. One or more kinds of transistors can be used in the display apparatus of one embodiment of the present invention. For example, one or more of the transistor MTCK illustrated in FIG. 31, a transistor MTCK2 illustrated in FIG. 32, and a transistor 800 illustrated in FIG. 33 can be used. One or both of an OS transistor and a Si transistor can be used in the display apparatus of one embodiment of the present invention.

### Structure Example 2 of Display Apparatus

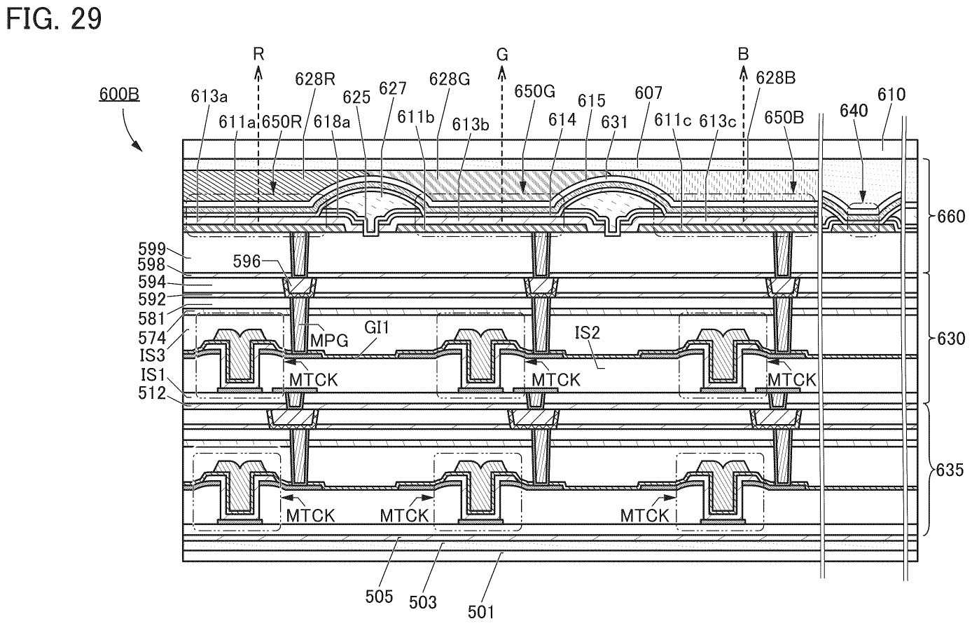

FIG. 29 is a cross-sectional view of a display apparatus 600B.

The display apparatus 600B can be a display apparatus having flexibility (also referred to as flexible display device) when a flexible substrate is used as each of a substrate 501 and the substrate 610. The substrate 501 is bonded to an insulating layer 505 with an adhesive layer 503. The substrate 610 is bonded to the protective layer 631 with the adhesive layer 607. An example of a manufacturing method of a flexible device is described later in this embodiment.

The element layer 660 of the display apparatus 600B is different from the element layer 660 of the display apparatus 600A mainly in that the layer 613a, the layer 613b, and the layer 613c have the same structure and that a coloring layer 628R, a coloring layer 628G, and a coloring layer 628B are provided.

The layer 613a, the layer 613b, and the layer 613c are formed using the same material in the same step. The layer 613a, the layer 613b, and the layer 613c are separated from one another. When the EL layer is provided in an island shape for each light-emitting device, a leakage current between adjacent light-emitting devices (sometimes referred to as a horizontal-direction leakage current, a horizontal leakage current, or a lateral leakage current) can be inhibited. Accordingly, unintentional light emission due to crosstalk can be prevented, and color mixture between adjacent light-emitting devices can be inhibited, so that a display apparatus with extremely high contrast can be obtained.

The light-emitting devices 650R, 650G, and 650B illustrated in FIG. 29 emit white light, for example. White light emitted from the light-emitting devices 650R, 650G, and 650B passes through the coloring layer 628R, the coloring layer 628G, and the coloring layer 628B, whereby light of a desired color can be obtained.

In the case where the light-emitting device configured to emit white light has a microcavity structure, light with a specific wavelength such as red, green, or blue is sometimes intensified and emitted.

Light emitted by the light-emitting device 650R is extracted as red light to the outside of the display apparatus 600B through the coloring layer 628R. Similarly, light emitted by the light-emitting device 650G is extracted as green light to the outside of the display apparatus 600B through the coloring layer 628G. Light emitted by the light-emitting device 650B is extracted as blue light to the outside of the display apparatus 600B through the coloring layer 628B.

A light-emitting device that emits white light preferably has a tandem structure. A structure example of the light-emitting device having a tandem structure is described in detail in Embodiment 5.

Alternatively, the light-emitting devices 650R, 650G, and 650B illustrated in FIG. 29 emit blue light, for example. In this case, the layer 613a, the layer 613b, and the layer 613c include one or more light-emitting layers that emit blue light. In a subpixel that emits blue light, blue light emitted from the light-emitting device 650B can be extracted. In each of the subpixel emitting red light and the subpixel emitting green light, a color conversion layer is provided between the light-emitting device 650R and the coloring layer 628R and between the light-emitting device 650G and the coloring layer 628G, so that blue light emitted from the light-emitting device 650R or the light-emitting device 650G is converted into light with a longer wavelength and red light or green light can be extracted. When light transmitted through the color conversion layer is extracted through the coloring layer, light other than light of the intended color can be absorbed by the coloring layer, and color purity of light exhibited by the subpixel can be improved.

The coloring layer is a colored layer that selectively transmits light in a specific wavelength range and absorbs light in the other wavelength ranges. For example, a red (R) color filter transmitting light in the red wavelength range, a green (G) color filter transmitting light in the green wavelength range, a blue (B) color filter transmitting light in the blue wavelength range, or the like can be used. For each coloring layer, one or more of a metal material, a resin material, a pigment, and a dye can be used. Each coloring layer is formed in a desired position by a printing method, an inkjet method, an etching method using a photolithography method, or the like.

The element layer 630 of the display apparatus 600B has a structure similar to that of the element layer 630 of the display apparatus 600A; thus, the detailed description thereof is omitted.

The display apparatus 600B is different from the display apparatus 600A in not including the element layer 620 but including an element layer 635. The element layer 635 has a structure similar to that of the element layer 630.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display apparatus are preferably provided in the element layer 635.

Although FIG. 29 illustrates an example where two element layers (the element layer 630 and the element layer 635) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display apparatus, the uppermost layer be used for the pixel circuit of the display apparatus, and one or more layers between them be used for the pixel circuit or the driver circuit.

A Si transistor is typically formed on a single crystal Si wafer, and thus is difficult to have flexibility. Meanwhile, as illustrated in FIG. 21, in the case where the display apparatus is formed using only OS transistors without using a Si transistor, the display apparatus can have flexibility through a relatively simple manufacturing process.

### Structure Example 3 of Display Apparatus

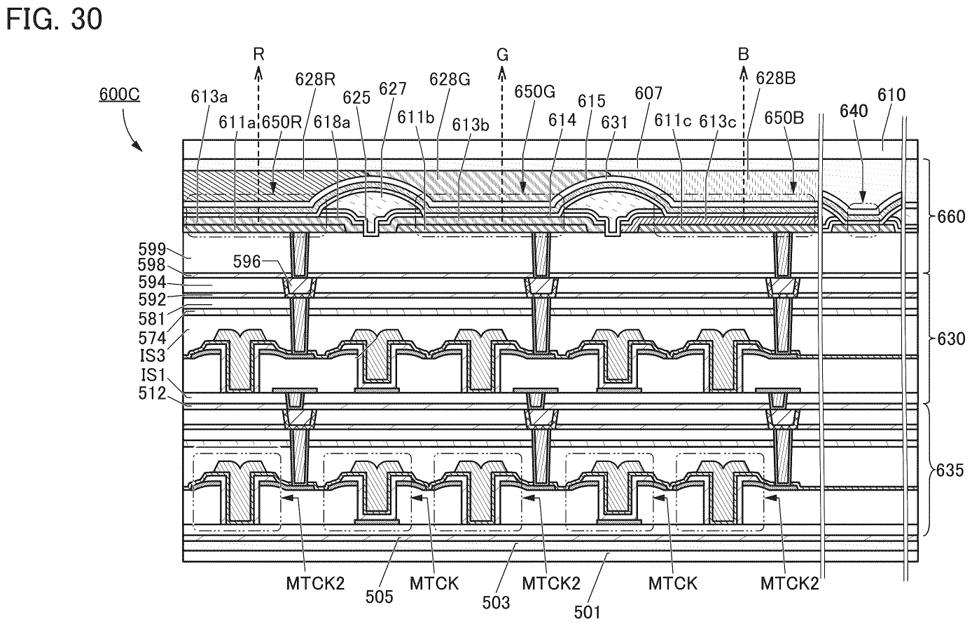

FIG. 30 is a cross-sectional view of a display apparatus 600C.

The element layer 660 of the display apparatus 600C has a structure similar to that of the element layer 660 of the display apparatus 600B; thus, the detailed description thereof is omitted.

The element layer 630 and the element layer 635 of the display apparatus 600C each include a plurality of transistors MTCK and a plurality of transistors MTCK2.

The transistor MTCK has an extremely small channel length and can have a large channel width, so that a high on-state current can be achieved. Meanwhile, the transistor MTCK2 has an extremely small channel width and can have a large channel length, so that an appropriate on-state current can be obtained and the transistor design is facilitated. The manufacturing process of the transistor MTCK2 and the transistor MTCK can share some of the steps, and the transistor MTCK2 and the transistor MTCK can be formed separately over one substrate. For example, in the pixel circuit (corresponding to the element layer 630) of the display apparatus, the transistor MTCK2 can be used as a driving transistor for controlling current flowing through the light-emitting device, and the transistor MTCK can be used as a transistor serving as a switch. The combination of the transistor MTCK and the transistor MTCK2 can achieve a driver circuit (corresponding to one or both of a gate driver and a source driver, here, corresponding to the element layer 635) of the display apparatus. Since two kinds of transistors can be used independently depending on the usage of the transistors included in the circuit, the semiconductor device can have higher functionality and higher reliability.

Note that the stacking order of the element layer 630 and the element layer 635 is not limited to the above structure. For example, the element layer 635 may be provided over the element layer 630, that is, the driver circuit of the display apparatus may be provided over the pixel circuit of the display apparatus.

The other components are the same as those in the display apparatus 600B; thus, the above description can be referred to.

### Structure Example 1 of Transistor

FIG. 31A to FIG. 31C illustrate an example of a semiconductor device (showing, for example, a pixel circuit or a driver circuit) including the transistor MTCK. Specifically, FIG. 31A is a schematic plan view of the transistor MTCK. FIG. 31B is a schematic cross-sectional view corresponding to a portion along the dashed-dotted line A1-A2 illustrated in FIG. 31A, and is also a schematic cross-sectional view of the transistor MTCK. FIG. 31C is a schematic cross-sectional view corresponding to a portion along the dashed-dotted line A3-A4 illustrated in FIG. 31A, and is also a schematic cross-sectional view of the transistor MTCK.

Note that in FIG. 31A to FIG. 31C, the direction of the dashed-dotted line A1-A2 is an X direction, and the direction of the dashed-dotted line A3-A4 is a Y direction. Moreover, a direction perpendicular to the X direction and the Y direction is a Z direction. The X direction and the Y direction can be directions perpendicular to each other. The definition of the X direction, the Y direction, and the Z direction applies to some of the following drawings and does not apply to other drawings. In the description of the schematic plan view in FIG. 31A and the like, in some cases, the right side, the left side, the upper side, and the lower side are referred to as the X direction, a −X direction, the Y direction, and a −Y direction, respectively. In the description of the schematic cross-sectional view in FIG. 31B and the like, in some cases, the right side, the left side, the upper side, and the lower side are referred to as the X direction, the −X direction, the Z direction, and a −Z direction, respectively. In the description of the schematic cross-sectional view such as FIG. 31C, in some cases, the right side, the left side, the upper side, and the lower side are referred to as the −Y direction, a +Y direction, the Z direction, and the −Z direction, respectively.

The transistor MTCK in FIG. 31A to FIG. 31C includes the insulator IS1 to the insulator IS3, the insulator GI1, a conductor ME1 to a conductor ME3, and a semiconductor SC1.

The insulator IS1 functions as, for example, a base film above which a source, a drain, and a channel formation region of the transistor MTCK are to be provided. For the insulator IS1, silicon oxide, silicon oxynitride, silicon nitride oxide, or silicon nitride may be used, for example. Alternatively, for the insulator IS1, silicon oxide to which fluorine is added, silicon oxide to which carbon is added, silicon oxide to which carbon and nitrogen are added, or porous silicon oxide can be used, for example. In particular, silicon oxide and silicon oxynitride, which are thermally stable, are preferable. In particular, materials such as silicon oxide, silicon oxynitride, and porous silicon oxide are preferably used, in which case a region containing oxygen to be released by heating can be easily formed. Alternatively, for the insulator IS1, a resin can be used, for example. A material used for the insulator IS1 may be an appropriate combination of the above-described insulating materials.

The conductor ME1 is a conductor (sometimes rephrased as a terminal, a wiring, or the like) functioning as one of the source and the drain in the transistor MTCK. The conductor ME2 is a conductor (sometimes rephrased as a terminal, a wiring, or the like) functioning as the other of the source and the drain in the transistor MTCK.

Note that in FIG. 31A to FIG. 31C, the conductor ME1 is provided as a wiring to extend in the Y direction, for example. The conductor ME2 is provided as a wiring to extend in the X direction, for example.

For the conductive film ME1, the conductor ME2, and the conductor ME3, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing two or more selected from the above metal elements; or an alloy containing a combination of two or more selected from the above metal elements, for example. As the conductive film ME1, the conductor ME2, and the conductor ME3, it is preferable to use tantalum nitride, titanium nitride, tungsten nitride, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. As the conductor, a semiconductor having high electrical conductivity, typified by polycrystalline silicon containing an impurity element (e.g., phosphorus or arsenic), or silicide (e.g., nickel silicide) may be used, for example.

An oxide conductor may be used for the conductor ME1, the conductor ME2, and the conductor ME3. Examples of an oxide conductor include indium oxide, zinc oxide, In—Sn oxide (ITO), In—Zn oxide (also denoted as IZO (registered trademark)), In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A conductive oxide including indium has high conductivity, and thus is particularly preferable.

A stack of a plurality of conductive films formed of the above-described materials may be used. For example, a stacked-layer structure combining a material containing the above metal element and a conductive material containing oxygen may be employed. Specific examples of the stacked-layer structure of the conductive film include a stacked-layer structure of indium oxide and a metal film containing ruthenium. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

The insulator IS2 functions as, for example, an interlayer film that separates the source and the drain in the transistor MTCK. For the insulating film IS2, a material that can be used for the insulator IS1 can be used, for example. In the case where the semiconductor SC1 is a metal oxide functioning as an oxide semiconductor, for example, silicon oxide, silicon oxynitride, and porous silicon oxide are preferably used. With these materials, a region containing oxygen released by heating can be easily formed, and the released oxygen can be supplied to the metal oxide. This reduces the carrier concentration of the metal oxide at the interface between the semiconductor SC1 and the insulator IS2 in contact with each other and the vicinity of the interface, so that the interface and the vicinity of the interface in the semiconductor SC1 become i-type or substantially i-type. Accordingly, the interface of the semiconductor SC1 and the vicinity of the interface can function as the channel formation region of the transistor MTCK.

The semiconductor film SC1 can be a metal oxide functioning as an oxide semiconductor, for example. In this case, the transistor MTCK is an OS transistor. The metal oxide preferably contains at least indium or zinc, for example. In particular, indium and zinc are preferably contained. In addition to them, an element M is preferably contained. As the element M, one or more selected from aluminum, gallium, silicon, yttrium, tin, copper, vanadium, beryllium, boron, titanium, iron, nickel, germanium, zirconium, molybdenum, lanthanum, cerium, neodymium, hafnium, tantalum, tungsten, magnesium, cobalt, and antimony can be used. In particular, the element M is preferably one or more of aluminum, gallium, yttrium, and tin. The element M further preferably contains one or both of gallium and tin.

More specific examples of the metal oxide include indium oxide, gallium oxide, zinc oxide, indium zinc oxide (In—Zn oxide, also denoted as IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be given as an example. Note that a material that does not contain Zn, such as indium oxide, is preferred in that it improves the compatibility with an LSI manufacturing process. By contrast, a material that contains Zn is preferred in that crystallinity can be easily increased.

When the semiconductor SC1 is a metal oxide functioning as an oxide semiconductor, it is preferably formed by an ALD (Atomic Layer Deposition) method. As illustrated in FIG. 31B and FIG. 31C, when the semiconductor SC1 is formed in a region having a step, an ALD method enables favorable coverage.

In the case where a metal oxide functioning as an oxide semiconductor is used as the semiconductor SC1, microwave treatment is preferably performed in an oxygen-containing atmosphere during or after the deposition of the metal oxide to reduce the impurity concentration in the metal oxide. Specific examples of the impurity include hydrogen and carbon. The microwave treatment can increase the crystallinity of the metal oxide in some cases. Here, the microwave treatment refers to, for example, treatment using an apparatus including a power source that generates high-density plasma with use of a microwave.

It is preferable to use a metal oxide layer having crystallinity as the semiconductor SC1. For example, a metal oxide layer having a CAAC (c-axis aligned crystal) structure, a polycrystalline structure, a nano-crystal (nc) structure, or the like can be used. With use of the metal oxide layer having crystallinity as the semiconductor SC1, the density of defect states in the semiconductor SC1 can be reduced, which enables the semiconductor device to have high reliability.

For the semiconductor SC1, for example, an In—Ga—Zn oxide is preferably used. In particular, the In—Ga—Zn oxide is further preferably a metal oxide with a composition of In:Ga:Zn=1:1:1 [atomic ratio] or in the neighborhood thereof, a composition of 4:2:3 [atomic ratio] or in the neighborhood thereof, or a composition of 3:1:2 [atomic ratio] or in the neighborhood thereof. For another example, an In—Zn oxide is preferably used for a semiconductor film SCIA. In particular, the In—Zn oxide is further preferably a metal oxide with a composition of In:Zn=4:1 [atomic ratio] or in the neighborhood thereof.

The semiconductor SC1 preferably has a stacked-layer structure of a plurality of oxide layers that differ in the atomic ratio of metal atoms. As the metal oxide, for example, a first metal oxide and a second metal oxide formed over the first metal oxide are considered. For example, in the case where the metal oxides each contain at least indium (In) and the element M, the proportion of the number of atoms of the element M contained in the first metal oxide to the number of atoms of all elements that constitute the first metal oxide is preferably higher than the proportion of the number of atoms of the element M contained in the second metal oxide to the number of atoms of all elements that constitute the second metal oxide. In addition, the atomic ratio of the element M to In in the first metal oxide is preferably greater than the atomic ratio of the element M to In in the second metal oxide.

Specifically, as the first metal oxide, a metal oxide with a composition of In:Ga:Zn=1:3:4 [atomic ratio] or in the neighborhood thereof, 1:3:2 [atomic ratio] or in the neighborhood thereof, or 1:1:0.5 [atomic ratio] or in the neighborhood thereof can be used. As the second metal oxide, a metal oxide with a composition of In:Ga:Zn=1:1:1 [atomic ratio] or in the neighborhood thereof, 4:2:3 [atomic ratio] or in the neighborhood thereof, or 3:1:2 [atomic ratio] or in the neighborhood thereof can be used. Note that the neighborhood of the atomic ratio includes ±30% of an intended atomic ratio.

In this case, the second metal oxide serves as a main carrier path. When the first metal oxide has the above structure, the density of defect states at the interface between the first metal oxide and the second metal oxide can be made low. Thus, the influence of interface scattering on carrier conduction is small, and the transistor can have a high on-state current and high frequency characteristics.

In a region of the insulator IS2 where the transistor MTCK is provided, an opening KK1 whose side surface is substantially perpendicular (a taper angle greater than or equal to 70° and less than or equal to) 110° to an X-Y plane is formed. The semiconductor SC1 including the channel formation region of the transistor MTCK is provided to be in contact with the conductor ME1 and the conductor ME2 through the opening KK1.

In the transistor MTCK, the insulator GI1 is provided over the semiconductor SC1. Specifically, the insulator GI1 is positioned above and overlaps with the channel formation region included in the semiconductor SC1 in the plan view. The insulator GI1 functions as a gate insulating film of the transistor MTCK.

Thus, for the insulator GI1, a single layer or a stacked layer using an insulator containing what is called a high-k material, such as aluminum oxide, hafnium oxide, tantalum oxide, zirconium oxide, lead zirconate titanate (PZT), strontium titanate (SrTiO₃), or (Ba,Sr) TiO₃ (BST) is preferably used. Alternatively, for the insulator GI1, as an insulator with a high dielectric constant, an oxide containing aluminum and hafnium, an oxynitride containing aluminum and hafnium, an oxide containing silicon and hafnium, an oxynitride containing silicon and hafnium, or a nitride containing silicon and hafnium may be used. A material that can be used for the insulator IS1 may be used for the insulator GI1. For the insulator GI1, silicon oxide, silicon oxynitride, silicon nitride oxide, or silicon nitride may be used, for example.

In the transistor MTCK, the conductor ME3 is provided over the insulator GI1 to fill the opening KK1. The conductor ME3 is a conductor (sometimes rephrased as a terminal, a wiring, or the like) functioning as a gate in the transistor MTCK.

Note that in FIG. 31A to FIG. 31C, the conductor ME3 is provided as a wiring to extend in the Y direction, for example.

The insulator IS3 is a film functioning as an interlayer film, for example. Thus, the insulator IS3 preferably contains an insulating material with a low dielectric constant. When an insulating material with a low dielectric constant is used for an interlayer film, parasitic capacitance generated between wirings can be reduced.

For the insulator IS3, a material that can be used for the insulator IS1 can be used, for example.

As described above, in the transistor MTCK illustrated in FIG. 31A to FIG. 31C, the conductor ME1 functioning as one of the source and the drain is positioned below the insulator IS2 serving as an interlayer film, and the conductor ME2 functioning as the other of the source and the drain is positioned above the insulator IS2. Thus, the transistor MTCK has a structure in which the channel formation region is provided along the opening in the insulator IS2.

In the transistor MTCK, the source and the drain are positioned at different levels, so that a current flows in the semiconductor layer in the height direction. In other words, the channel length direction can be regarded as having a component of the height direction (the vertical direction); accordingly, the transistor MTCK can also be referred to as a VFET (Vertical Field Effect Transistor), a vertical transistor, a vertical-channel transistor, a vertical-channel-type transistor, and the like.

As illustrated in FIG. 31A to FIG. 31C, when the channel formation region of the transistor is provided along the side surface of the opening in the insulator functioning as an interlayer film, the area occupied by the transistor can be smaller than that in the case where the channel formation region of the transistor is provided along the X-Y plane. Thus, when a circuit is formed using one or both of the transistor MTCK, the area of the circuit can be small. This results in a reduction in size of a semiconductor device including the circuit or a display apparatus including the circuit.

### Structure Example 2 of Transistor

FIG. 32A is a cross-sectional view of the transistor MTCK2, along the XZ plane, having a structure different from that in FIG. 31B. FIG. 32B is a cross-sectional view taken along the XY plane.

The transistor MTCK2 is different from the transistor MTCK mainly in that the conductor ME1 is not included, conductors ME2_S and ME2_D are included instead of the conductor ME2, and the semiconductor SC1 has a different shape. The conductor ME2_S functions as a source electrode, and the conductor ME2_D functions as a drain electrode.

The semiconductor SC1 has a circular shape. The semiconductor SC1 includes a region in contact with the side surface of the conductor ME2_S, a region in contact with the side surface of the conductor ME2_D, and a region in contact with the side surface of the insulator IS2 in the opening KK1. Here, the semiconductor SC1 is not in contact with the top surfaces of the conductors ME2_S and ME2_D. The semiconductor SC1 having such a shape can be formed by processing by anisotropic etching, for example. Note that as illustrated in FIG. 30, the semiconductor SC1 may be in contact with the top surfaces of the conductor ME2_S and ME2_D.

As illustrated in FIG. 32B, the widths H of the conductor ME2_S and the conductor ME2_D are smaller than the maximum width D of the opening KK1. In this case, the circumferential direction of the opening KK1 corresponds to the channel length direction of the transistor MTCK2. Here, since the semiconductor SC1 has a circular shape, two kinds of current paths (i.e., channels) from the conductor ME2_S to the conductor ME2_D exist. Note that the semiconductor SC1 does not necessarily have a circular shape and may be in contact with both the conductor ME2_S and the conductor ME2_D.

The channel length can be controlled by the shape and size of the opening KK1. For example, in the case where the channel length is desired to be large, the perimeter of the opening KK1 is made long. Although this embodiment describes the example where the opening KK1 has a circular shape in the plan view, the present invention is not limited thereto. For example, the opening KK1 can have an elliptical shape or a quadrangular shape with rounded corners besides the circular shape in the plan view. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased. Alternatively, an elliptical shape, a polygonal shape with rounded corners, a closed curve in which a straight line and a curve are combined, or the like can be employed. In that case, the maximum width of the opening KK1 is calculated as appropriate in accordance with the shape of the uppermost portion of the opening KK1. For example, in the case where the opening portion is square or rectangular in the plan view, the maximum width of the opening KK1 may be the length of a diagonal line of the uppermost portion of the opening KK1.

Note that the semiconductor SC1 of the transistor MTCK2 is provided along the perimeter direction of the opening KK1 as described above, so that current flows in the lateral direction. Furthermore, it can be said that the transistor MTCK2 also includes a component through which current flows in the height direction (the vertical direction). Accordingly, the transistor of one embodiment of the present invention can be referred to as a VLFET (Vertical Lateral Field Effect Transistor), for example.

As illustrated in FIG. 32A, the height of the semiconductor SC1 is the channel width W1 of the transistor MTCK2. Thus, the channel width W of the transistor MTCK2 can be controlled by the thickness of the insulator IS2. Thus, the transistor MTCK2 can have an extremely small channel width less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm).

The transistor MTCK has an extremely small channel length and can have a large channel width, so that a high on-state current can be achieved. Meanwhile, the transistor MTCK2 has an extremely small channel width and can have a large channel length, so that an appropriate on-state current can be obtained and the transistor design is facilitated. The manufacturing process of the transistor MTCK and the transistor MTCK2 can share some of the steps, and the transistor MTCK and the transistor MTCK2 can be formed separately over one substrate. For example, as in the display apparatus illustrated in FIG. 30, the transistor MTCK2 can be used as a driving transistor for controlling current flowing through the light-emitting device, and the transistor MTCK can be used as a transistor serving as a switch. Furthermore, since the transistor MTCK and the transistor MTCK2 can be combined to form a driver circuit, the display apparatus can have higher functionality and higher reliability.

### Structure Example 3 of Transistor

FIG. 33A is a schematic top view of the transistor 800. FIG. 33B is a cross-sectional view taken along the dashed-dotted line A1-A2 in FIG. 33A. FIG. 33B is also a cross-sectional view of the transistor 800 in the channel length direction. FIG. 33C is a cross-sectional view taken along the dashed-dotted line A3-A4 in FIG. 33A. FIG. 33C is also a cross-sectional view of the transistor 800 in the channel width direction. FIG. 33D is a cross-sectional view taken along a dashed-dotted line A5-A6 in FIG. 33A. FIG. 33D is also a cross-sectional view of the transistor 800 in the channel width direction. Note that for clarity of the drawing, some components are not illustrated in the top view of FIG. 33A.

The transistor 800 includes a conductor 805 (a conductor 805a and a conductor 805b) provided to be embedded in an insulator 816; an insulator 821 over the insulator 816 and the conductor 805; an insulator 822 over the insulator 821; an insulator 824 over the insulator 822; an oxide 820 (an oxide 820a and an oxide 820b) over the insulator 824; a conductor 842a (a conductor 842a1 and a conductor 842a2) and a conductor 842b (a conductor 842b1 and a conductor 842b2) over the oxide 820; an insulator 871a over the conductor 842a; an insulator 871b over the conductor 842b; an insulator 850 over the oxide 820; and a conductor 860 (a conductor 860a and a conductor 860b) over the insulator 850.

An insulator 875 is provided over the insulators 871a and 871b, and an insulator 885 is provided over the insulator 875. An insulator 855, the insulator 850, and the conductor 860 are placed in an opening provided in the insulator 885 and the insulator 875. An insulator 882 is provided over the insulator 885 and the conductor 860. An insulator 883 is provided over the insulator 882. An insulator 815 is provided below the insulator 816 and the conductor 805. The insulator 855 is provided between the insulator 850 and the conductor 842a2, the conductor 842b2, the insulator 871a, the insulator 871b, the insulator 875, and the insulator 885.

Note that the insulator 815, the insulator 816, the conductor 805, the insulator 821, the insulator 822, the insulator 824, the oxide 820, the conductor 842a, the conductor 842b, the insulator 871a, the insulator 871b, the insulator 875, the insulator 885, the insulator 855, the insulator 850, the conductor 860, the insulator 882, and the insulator 883 may each have a single-layer structure or a stacked-layer structure.

The oxide 820 includes a region functioning as a channel formation region of the transistor 800. The conductor 860 includes a region functioning as a first gate electrode (an upper gate electrode) of the transistor 800. The insulator 850 includes a region functioning as a first gate insulator of the transistor 800. The conductor 805 includes a region functioning as a second gate electrode (a lower gate electrode) of the transistor 800. The insulator 824, the insulator 822, and the insulator 821 each include a region functioning as a second gate insulator of the transistor 800.

The conductor 842a includes a region functioning as one of a source electrode and a drain electrode of the transistor 800. The conductor 842b includes a region functioning as the other of the source electrode and the drain electrode of the transistor 800.

The oxide 820 preferably includes the oxide 820a over the insulator 824 and the oxide 820b over the oxide 820a. Including the oxide 820a under the oxide 820b makes it possible to inhibit diffusion of impurities into the oxide 820b from components formed below the oxide 820a.

Note that the oxide 820 is not limited to having a two-layer structure of the oxide 820a and the oxide 820b. The oxide 820 may have a single-layer structure of the oxide 820b or a stacked-layer structure of three or more layers, for example.

The oxide 820b includes the channel formation region of the transistor 800 and a source region and a drain region provided to sandwich the channel formation region. At least part of the channel formation region overlaps with the conductor 860. The source region overlaps with the conductor 842a, and the drain region overlaps with the conductor 842b. Note that the source region and the drain region can be interchanged with each other.

The channel formation region has a smaller amount of oxygen vacancies or a lower impurity concentration than the source region and the drain region, and thus is a high-resistance region with a low carrier concentration. Thus, the channel formation region can be regarded as being i-type (intrinsic) or substantially i-type.

The source region and the drain region have a large amount of oxygen vacancies or a high concentration of an impurity such as hydrogen, nitrogen, or a metal element, and thus are each a low-resistance region with a high carrier concentration. In other words, the source region and the drain region are each an n-type region (low-resistance region) having a higher carrier concentration than the channel formation region.

Note that the channel formation region, the source region, and the drain region may each be formed not only in the oxide 820b but also in the oxide 820a.

In the oxide 820, the boundary of each region is difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region may have lower concentrations of a metal element and impurity elements such as hydrogen and nitrogen.

An oxide semiconductor is preferably used for the oxide 820 (the oxide 820a and the oxide 820b).

The oxide 820 preferably has a stacked-layer structure of a plurality of oxide layers with different chemical compositions. For example, the atomic ratio of the element M to a metal element that is a main component in the metal oxide used for the oxide 820a is preferably greater than the atomic ratio of the element M to a metal element that is a main component in the metal oxide used for the oxide 820b. Moreover, the atomic ratio of the element M to In in the metal oxide used for the oxide 820a is preferably greater than the atomic ratio of the element M to In in the metal oxide used for the oxide 820b. With this structure, impurities and oxygen can be inhibited from diffusing into the oxide 820b from the components formed below the oxide 820a.

Furthermore, the atomic ratio of In to the element M in the metal oxide used for the oxide 820b is preferably greater than the atomic ratio of In to the element M in the metal oxide used for the oxide 820a. With this structure, the transistor 800 can have a high on-state current and excellent frequency characteristics.

When the oxide 820a and the oxide 820b contain a common element as the main component besides oxygen, the density of defect states at the interface between the oxide 820a and the oxide 820b can be decreased. The density of defect states at the interface between the oxide 820a and the oxide 820b can be decreased. Thus, the influence of interface scattering on carrier conduction is reduced, and the transistor 800 can have a high on-state current and high frequency characteristics.

Specifically, for the oxide 820a, a metal oxide with a composition of In:M:Zn=1:3:2 [atomic ratio] or in the neighborhood thereof, a composition of In:M:Zn=1:3:4 [atomic ratio] or in the neighborhood thereof, or a composition of In:M:Zn=1:1:0.5 [atomic ratio] or in the neighborhood thereof can be used. For the oxide 820b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that the neighborhood of the atomic ratio includes +30% of an intended atomic ratio. Gallium is preferably used as the element M. In the case where a single layer of the oxide 820b is provided as the oxide 820, a metal oxide that can be used for the oxide 820a may be used for the oxide 820b. The compositions of the metal oxides that can be used for the oxide 820a and the oxide 820b are not limited to the above. For example, the composition of the metal oxide that can be used for the oxide 820a may be applied to the oxide 820b. Similarly, the composition of the metal oxide that can be used for the oxide 820b may be applied to the oxide 820a.

When the metal oxide is deposited by a sputtering method, the above atomic ratio is not limited to the atomic ratio of the deposited metal oxide and may be the atomic ratio of a sputtering target used for depositing the metal oxide.

The oxide 820b preferably has crystallinity. It is particularly preferable to use a CAAC-OS for the oxide 820b.

When an oxide having crystallinity, such as a CAAC-OS, is used for the oxide 820b, oxygen extraction from the oxide 820b by the source electrode or the drain electrode can be inhibited. This can reduce oxygen extraction from the oxide 820b even when heat treatment is performed; thus, the transistor 800 is stable with respect to high temperatures in the manufacturing process (what is called thermal budget).

Examples of materials that can be used for the conductors, the insulators, and the oxide semiconductor included in the transistor 800 include the above-described materials that can be used for the conductor ME1 to the conductor ME3. A typical example is described below.

The conductor 842a has a stacked structure of the conductor 842a1 and the conductor 842a2 over the conductor 842a1, and the conductor 842b has a stacked structure of the conductor 842b1 and the conductor 842b2 over the conductor 842b1. The conductor 842a1 and the conductor 842b1 in contact with the oxide 820b are preferably conductors that are not easily oxidized, such as metal nitride. Thus, the conductor 842a and the conductor 842b can be prevented from being oxidized excessively by oxygen contained in the oxide 820b. The conductor 842a2 and the conductor 842b2 are preferably conductors having higher conductivity than the conductor 842a1 and the conductor 842b1, such as a metal layer. Accordingly, the conductor 842a and the conductor 842b can each function as a wiring or an electrode with high conductivity.

For example, tantalum nitride or titanium nitride can be used for the conductor 842a1 and the conductor 842b1, and tungsten can be used for the conductor 842a2 and the conductor 842b2.

The opening formed in the insulator 885 and the insulator 875 overlap with a region between the conductor 842a2 and the conductor 842b2. In a plan view, the side surface of the opening in the insulator 885 is aligned or substantially aligned with the side surface of the conductor 842a2 and the side surface of the conductor 842b2. The conductor 842a1 and the conductor 842b1 are formed to partly extend toward the inside of the opening. Here, part of a top surface of the conductor 842a1 is in contact with the conductor 842a2, and part of a top surface of the conductor 842b1 is in contact with the conductor 842b2. Thus, the insulator 855 is in contact with another part of the top surface of the conductor 842a1, another part of the top surface of the conductor 842b1, and the side surface of the conductor 842a2, and the side surface of the conductor 842b2 in the opening. The insulator 850 is in contact with the top surface of the oxide 820, the side surface of the conductor 842a1, the side surface of the conductor 842b1, and the side surface of the insulator 855.

The insulator 855 is preferably an insulator that is not easily oxidized, such as nitride. By anisotropic etching, the insulator 855 is formed in a sidewall shape to be in contact with the sidewall of the opening formed in the insulator 885 and the like (here, the sidewall of the opening corresponds to, for example, the side surface of the insulator 885 or the like). The insulator 855 is formed in contact with the side surface of the conductor 842a2 and the side surface of the conductor 842b2 and has a function of protecting the conductor 842a2 and the conductor 842b2. In order to supply oxygen to the oxide 820b, heat treatment in an atmosphere containing oxygen is preferably performed after the separation into the conductor 842a1 and the conductor 842b1 and before the formation of the insulator 850. At this time, since the insulator 855 is formed in contact with the side surface of the conductor 842a2 and the side surface of the conductor 842b2, excessive oxidation of the conductor 842a2 and the conductor 842b2 can be prevented. The insulator 855 can be formed using silicon nitride, for example.

An insulator containing oxygen that is released by heating (hereinafter sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 800. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Accordingly, in the oxide semiconductor, the channel formation region is preferably i-type or substantially i-type with a reduced carrier concentration, whereas the source region and the drain region are preferably n-type with high carrier concentrations. That is, the amounts of oxygen vacancies and V_{O}H in the channel formation region of the oxide semiconductor are preferably reduced. Supply of an excess amount of oxygen to the source region and the drain region and excessive reduction in the amount of V_{O}H in the source region and the drain region are preferably inhibited. In addition, a structure in which conductivity of the conductor 860, the conductor 842a, the conductor 842b, and the like is less likely to be reduced is preferably employed. For example, oxidation of the conductor 860, the conductor 842a, the conductor 842b, and the like is preferably inhibited. Note that hydrogen in the oxide semiconductor can form V_{O}H; thus, the hydrogen concentration needs to be reduced in order to reduce the amount of V_{O}H.

The transistor 800 has a structure in which the hydrogen concentration in the channel formation region is reduced, oxidation of the conductor 842a, the conductor 842b, and the conductor 860 is inhibited, and a reduction in the hydrogen concentration in the source region and the drain region is inhibited.

The insulator 850 in contact with the channel formation region of the oxide 820b preferably has a function of capturing or fixing hydrogen. Thus, the hydrogen concentration in the channel formation region of the oxide 820b can be reduced. Accordingly, V_{O}H in the channel formation region can be reduced, so that the channel formation region can be an i-type or substantially i-type region.

The insulator 850 functions as a gate insulator. The insulator 850 is provided in the opening formed in the insulator 885, together with the insulator 855 and the conductor 860. The thickness of the insulator 850 is preferably small for miniaturization of the transistor 800. The thickness of each layer included in the insulator 850 is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm. Each of the layers included in the insulator 850 at least partly includes a region with the above-described thickness.

To form the insulator 850 having a small thickness, an ALD method is preferably used for deposition. Furthermore, in the case where the insulator 850 and the insulator 855 are provided in the opening in the insulator 885 and the like, an ALD method is preferably employed. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because it enables film formation at a lower temperature.

The thickness of the insulator 855 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulator 855 has a thickness in the above range, excessive oxidation of the conductor 842a2 and the conductor 842b2 can be inhibited. In this case, at least part of the insulator 855 has a region with the above-described thickness. When the thickness of the insulator 855 is set excessively large, the time for forming the insulator 855 by an ALD method is long, which decreases the productivity; for this reason, the thickness of the insulator 855 is preferably in the above range.

A structure in which hydrogen is inhibited from entering the transistor 800 and the like is preferably employed for the semiconductor device illustrated in FIG. 33A and the like. For example, an insulator having a function of inhibiting diffusion of hydrogen is preferably provided to cover one or both of the upper portion and the lower portion of the transistor 800 and the like. Accordingly, each of the insulator 815, the insulator 821, the insulator 822, the insulator 882, and the insulator 883 preferably includes an insulator having a function of inhibiting diffusion of oxygen and impurities such as water and hydrogen. Examples of the insulator include aluminum oxide, magnesium oxide, hafnium oxide, zirconium oxide, oxide containing aluminum and hafnium (hafnium aluminate), oxide containing hafnium and zirconium (hafnium zirconium oxide), gallium oxide, silicon nitride, and silicon nitride oxide. For example, silicon nitride, which has a higher hydrogen barrier property, is preferably used for the insulator 883 and the insulator 821. For example, the insulator 882 preferably contains aluminum oxide or the like, which has a function of capturing and fixing hydrogen well. For example, hafnium oxide, which has high capability of capturing or fixing hydrogen and is a high dielectric constant (high-k) material, is preferably used for the insulator 822. With such a structure where the transistor 800 is surrounded by upper and lower insulators having a function of inhibiting diffusion of oxygen and impurities such as water and hydrogen, excess oxygen and hydrogen can be inhibited from diffusing into the oxide semiconductor. Thus, the semiconductor device can have improved electrical characteristics and reliability.

Here, it is preferable that a region of the insulator 875 not overlapping with the oxide 820 be in contact with the insulator 822, a side end portion of the insulator 875 be in contact with the insulator 855, and an upper end portion of the insulator 855 and an upper end portion of the insulator 850 be in contact with the insulator 882. With the above structure, in a region sandwiched between the insulator 883 and the insulator 821, the insulator 885 is isolated from the oxide 820 by the insulator 875, and the insulator 885 is separated from the insulator 850 by the insulator 855. Accordingly, diffusion of impurities contained in the insulator 885, such as water and hydrogen, into the oxide 820 and the insulator 850 can be inhibited. Hydrogen contained in the insulator 850 can be captured and fixed in the insulator 882. With such a structure, the amount of hydrogen diffusing into the oxide semiconductor can be further reduced. Thus, the semiconductor device can have improved electrical characteristics and reliability.

In the transistor 800, the conductor 805 is placed to overlap with the oxide 820 and the conductor 860. Here, the conductor 805 is preferably provided to be embedded in an opening portion formed in the insulator 816. Moreover, the conductor 805 is preferably provided to extend in the channel width direction as illustrated in FIG. 33A and FIG. 33C. With such a structure, the conductor 805 functions as a wiring when a plurality of transistors are provided.

As illustrated in FIG. 33B and FIG. 33C, the conductor 805 preferably includes the conductor 805a and the conductor 805b. The conductor 805a is provided in contact with the bottom surface and the sidewall of the opening portion. The conductor 805b is provided to fill a depressed portion that is defined by the conductor 805a and formed along the opening portion. Here, the top surface of the conductor 805 is level or substantially level with the top surface of the insulator 816.

When the conductor 805a is formed using a conductive material having a function of inhibiting diffusion of hydrogen, impurities such as hydrogen contained in the conductor 805b can be prevented from diffusing into the oxide 820 through the insulator 816 and the like. When a conductive material having a function of inhibiting diffusion of oxygen is used for the conductor 805a, the conductivity of the conductor 805b can be inhibited from being lowered because of oxidation. Examples of the conductive material having a function of inhibiting diffusion of oxygen include titanium, titanium nitride, tantalum, tantalum nitride, ruthenium, and ruthenium oxide. The conductor 805a can have a single-layer structure or a stacked-layer structure of the above conductive material. For example, the conductor 805a preferably contains titanium nitride.

The conductor 805b is preferably formed using a conductive material containing tungsten, copper, or aluminum as its main component. For example, the conductor 805b preferably contains tungsten.

The conductor 805 can function as the second gate electrode. In that case, by changing a potential applied to the conductor 805 not in conjunction with but independently of a potential applied to the conductor 860, the threshold voltage (Vₜₕ) of the transistor 800 can be controlled. In particular, by applying a negative potential to the conductor 805, Vₜₕ of the transistor 800 can be higher, and its off-state current can be reduced. Thus, a drain current at the time when a potential applied to the conductor 860 is 0 V can be lower in the case where a negative potential is applied to the conductor 805 than in the case where the negative potential is not applied to the conductor 805.

The electrical resistivity of the conductor 805 is designed in consideration of the potential applied to the conductor 805, and the thickness of the conductor 805 is set in accordance with the electrical resistivity. The thickness of the insulator 816 is substantially equal to that of the conductor 805. Here, the conductor 805 and the insulator 816 are preferably as thin as possible in the allowable range of the design of the conductor 805. When the thickness of the insulator 816 is reduced, the absolute amount of impurities such as hydrogen contained in the insulator 816 can be reduced, inhibiting diffusion of the impurities into the oxide 820.

The insulator 824 that is in contact with the oxide 820 preferably includes silicon oxide or silicon oxynitride, for example. Accordingly, oxygen can be supplied from the insulator 824 to the oxide 820, so that oxygen vacancies can be reduced.

The insulator 824 is preferably processed into an island shape in the same manner as the oxide 820. In that case, the plurality of transistors 800 provided include the insulators 824 having substantially the same sizes. Accordingly, substantially the same amount of oxygen is supplied from the insulator 824 to the oxide 820 in the transistors 800. This can reduce variations in electrical characteristics of the transistors 800 in the substrate plane. Note that the structure is not limited to this, and it is possible not to pattern the insulator 824 as in the case of the insulator 822.

A conductive material that is less likely to be oxidized or a conductive material having a function of inhibiting diffusion of oxygen is preferably used for each of the conductor 842a, the conductor 842b, and the conductor 860. Examples of the conductive material include a conductive material containing nitrogen and a conductive material containing oxygen. Thus, a decrease in the conductivity of the conductor 842a, the conductor 842b, and the conductor 860 can be inhibited.

The insulator 871a and the insulator 871b are inorganic insulators functioning as etching stoppers in the processing into the conductor 842a2 and the conductor 842b2 and protecting the conductor 842a2 and the conductor 842b2. Since the insulator 871a and the insulator 871b are respectively in contact with the conductor 842a and the conductor 842b, the insulator 871a and the insulator 871b are preferably inorganic insulators that are less likely to oxidize the conductors 842a and 842b. The insulator 871a and the insulator 871b preferably have a stacked-layer structure of a nitride insulator and an oxide insulator, for example.

Note that in this specification and the like, a transistor structure where a channel formation region is electrically surrounded by at least the electric field of a first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. Note that in this specification and the like, the Fin-type structure refers to a structure where at least two or more surfaces (specifically, two surfaces, three surfaces, four surfaces, or the like) of a channel are covered with a gate electrode. With the Fin-type structure and the S-channel structure, resistance to a short-channel effect can be increased, that is, a transistor in which a short-channel effect does not easily occur can be provided.

When the transistor 800 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 800 has the S-channel structure, the GAA structure, or the LGAA structure, the channel formation region that is formed at the interface between the oxide 820 and the gate insulator or in the vicinity of the interface can be formed in the entire bulk of the oxide 820. Accordingly, the density of a current flowing through the transistor can be increased, which can be expected to increase the on-state current of the transistor or increase the field-effect mobility of the transistor.

In this embodiment, the insulator 824 with an island shape is provided as described above. Accordingly, as illustrated in FIG. 33C, at least part of the bottom surface of the conductor 860 can be positioned lower than the bottom surface of the oxide 820b. Thus, the conductor 860 can be provided to face the top surface and the side surface of the oxide 820b, so that an electric field of the conductor 860 can be applied to the top surface and the side surface of the oxide 820b. When the insulator 824 with an island shape is provided in this manner, the transistor 800 can have an S-channel structure.

The conductor 860 preferably includes the conductor 860a and the conductor 860b placed over the conductor 860a. For example, the conductor 860a is preferably placed to cover the bottom surface and the side surface of the conductor 860b. In this case, a conductive material that is less likely to be oxidized or a conductive material having a function of inhibiting diffusion of oxygen is preferably used for the conductor 860a. When the conductor 860a has a function of inhibiting diffusion of oxygen, the conductivity of the conductor 860b can be inhibited from being lowered because of oxidation due to oxygen contained in the insulator 885 or the like. As the conductive material having a function of inhibiting diffusion of oxygen, for example, titanium, titanium nitride, tantalum, tantalum nitride, ruthenium, or ruthenium oxide is preferably used.

As the conductor 860b, a conductor having high conductivity is preferably used. For example, a conductive material containing tungsten, copper, or aluminum as its main component can be used as the conductor 860b. The conductor 860b may have a stacked-layer structure; for example, a stacked-layer structure of the conductive material and titanium or titanium nitride may be employed.

The insulator 816 and the insulator 885 each preferably have a lower permittivity than the insulator 822. When a material with a low permittivity is used for an interlayer film, parasitic capacitance generated between wirings can be reduced.

### Manufacturing Method Example of Flexible Device

An example of a manufacturing method of a flexible device is described below.

After an element layer is formed over a support substrate, the element layer can be separated from the support substrate and transferred to a flexible substrate.

Here, a layer including components of the device is comprehensively referred to as an element layer. For example, in the case of manufacturing a flexible semiconductor device, the element layer includes an element such as a transistor. For example, in the case of manufacturing a flexible display apparatus, the element layer includes at least one of a display element, a wiring electrically connected to the display element, an element such as a transistor used in a pixel and a circuit, and optical members such as a coloring layer and a light-blocking layer.

Here, two members having flexibility and holding the element layer therebetween are each referred to as a substrate (or a flexible substrate). Examples of the substrate include an extremely thin film with a thickness greater than or equal to 10 nm and less than or equal to 300 μm.

For example, an applicable method is as follows: a separation layer and an insulating layer are stacked over a support substrate; an element layer is formed over the insulating layer; separation is caused between support substrate and the element layer; and the element layer is transferred to a substrate. At this time, selected is a material inducing the separation at an interface between the support substrate and the separation layer, at an interface between the separation layer and the insulating layer, or in the separation layer. This method is preferable because a material having high heat resistance is used for the support substrate and the separation layer, whereby the upper limit of the temperature applied when the element layer is formed can be increased, and thus the formed element layer can include a more highly reliable element.

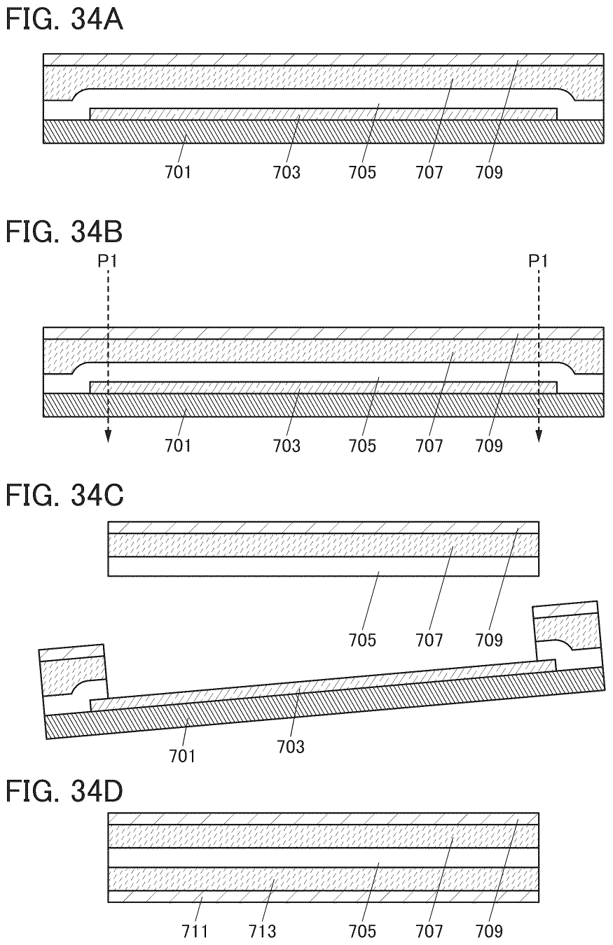

Next, an example of a specific manufacturing method is described with reference to FIG. 34.

First, an island-shaped separation layer 703 is formed over a support substrate 701, and a layer 705 to be separated is formed over the separation layer 703. After that, the support substrate 701 and a flexible substrate 709 are bonded to each other with an adhesive layer 707, so that the adhesive layer 707 is cured (FIG. 34A).

As the support substrate 701, a substrate having at least heat resistance high enough to withstand process temperatures in a manufacturing process is used. As the support substrate 701, for example, a glass substrate, a quartz substrate, a sapphire substrate, a semiconductor substrate, a ceramic substrate, a metal substrate, a resin substrate, a plastic substrate, and the like can be used.

As the semiconductor substrate, a circular substrate (wafer) is suitable; for example, a silicon (Si) substrate (also referred to as a silicon wafer), a silicon carbide (SiC) substrate, and a gallium nitride (GaN) substrate can be given.

An insulating film such as a silicon oxide film, a silicon oxynitride film, a silicon nitride film, or a silicon nitride oxide film is preferably formed as a base film between the support substrate 701 and the separation layer 703, in which case contamination from the support substrate 701 can be prevented.

The separation layer 703 can be formed to have a single-layer structure of a stacked-layer structure using one or more of an element selected from tungsten, molybdenum, titanium, tantalum, niobium, nickel, cobalt, zirconium, zinc, ruthenium, rhodium, palladium, osmium, iridium, and silicon, an alloy material containing any of the elements, a compound material containing any of the elements, and the like. A crystal structure of a layer containing silicon may be any of amorphous, microcrystal, and polycrystal. Furthermore, a metal oxide such as aluminum oxide, gallium oxide, zinc oxide, titanium dioxide, indium oxide, indium tin oxide, indium zinc oxide, or In—Ga—Zn oxide may be used.

The separation layer 703 can be formed by, for example, a sputtering method, a plasma CVD method, a coating method (including a spin coating method, a droplet discharging method, and a dispensing method), or a printing method.

The thickness of the separation layer 703 is preferably greater than or equal to 10 nm and less than or equal to 200 nm, and further preferably greater than or equal to 20 nm and less than or equal to 100 nm.

The separation layer 703 is preferably formed using a high-melting point metal material such as tungsten, titanium, or molybdenum, in which case the degree of freedom of the process for forming the layer 705 to be separated can be increased. As the separation layer 703, a tungsten layer, a molybdenum layer, a layer containing a mixture of tungsten and molybdenum, a layer containing an oxide or an oxynitride of tungsten, a layer containing an oxide or an oxynitride of molybdenum, or a layer containing an oxide or an oxynitride of a mixture of tungsten and molybdenum may be formed, for example. Note that a mixture of tungsten and molybdenum corresponds to an alloy of tungsten and molybdenum, for example.

The separation layer 703 may have a stacked-layer structure of a metal film and a metal oxide film. Specific examples include a stacked-layer structure of tungsten and tungsten oxide, a stacked-layer structure of molybdenum and molybdenum oxide, and a stacked-layer structure of titanium and titanium oxide. In the case of forming such a stacked-layer structure of a metal film and a metal oxide film, the following formation may be utilized: a layer containing a metal may be formed and an insulating film formed of an oxide may be formed over the layer containing the metal, whereby a layer containing an oxide of the metal is formed at the interface between the metal layer and the insulating film. Furthermore, a layer containing an oxide of the metal may be formed by performing thermal oxidation treatment, oxygen plasma treatment, nitrous oxide (N₂O) plasma treatment, treatment with a highly oxidizing solution such as ozone water, or the like on the surface of a layer containing a metal. Plasma treatment or heat treatment may be performed in an atmosphere of oxygen, nitrogen, or nitrous oxide alone, or a mixed gas of any of these gasses and another gas. A surface condition of the separation layer 703 is changed by the plasma treatment or heat treatment, whereby adhesion between the separation layer 703 and an insulating film formed later can be controlled.

Alternatively, an organic resin may be used for the separation layer 703. Examples of the organic resin include a polyimide resin, an acrylic resin, an epoxy resin, a polyamide resin, a polyimide-amide resin, a siloxane resin, a benzocyclobutene-based resin, and a phenol resin.

Note that the separation layer 703 is not necessarily provided in the case where separation at an interface between the support substrate 701 and the layer 705 to be separated is possible.

Although an example in which the separation layer 703 is formed to have an island shape is described here, one embodiment of the present invention is not limited to this example. Is selected, in this step, such a material as to induce the separation at the interface between the support substrate 701 and the separation layer 703, the interface between the separation layer 703 and the layer 705 to be separated, or in the separation layer 703 when the support substrate 701 and the layer 705 to be separated are separated from each other. Although an example in which separation occurs at the interface between the separation layer 703 and the layer 705 to be separated is described in this embodiment, one embodiment of the present invention is not limited to such an example and depends on combination of materials used for the separation layer 703 and the layer 705 to be separated. Note that in the case where the layer 705 to be separated has a stacked-layer structure, a layer in contact with the separation layer 703 is particularly referred to as a first layer.

There is no particular limitation on a layer formed as the layer 705 to be separated. The insulating layer (the first layer) in contact with the separation layer 703 preferably has a single-layer structure or a stacked-layer structure including at least one of a silicon nitride film, a silicon oxynitride film, a silicon oxide film, a silicon nitride oxide film, and the like. Note that a material for the insulating layer is not limited thereto, and an optimum material can be selected depending on a material used for the separation layer 703.

The insulating layer can be formed by a sputtering method, a plasma-enhanced CVD method, a coating method, a printing method, or the like. For example, the insulating layer is formed at temperatures ranging from 250° C. to 400° C. by a plasma-enhanced CVD method, whereby the insulating layer can be a dense film with high moisture resistance. The thickness of the insulating layer is preferably greater than or equal to 10 nm and less than or equal to 3000 nm, further preferably greater than or equal to 200 nm and less than or equal to 1500 nm.

At least one component of the device, such as a transistor or a display element, is formed over the first layer, whereby the layer 705 to be separated can be formed.

Note that the support substrate 701 and the substrate 709 are preferably bonded together in a reduced-pressure atmosphere.

The adhesive layer 707 is positioned at least to overlap with the separation layer 703 and the layer 705 to be separated. Note that an end portion of the adhesive layer 707 may be positioned more inwardly than that of the separation layer 703. In that case, strong adhesion between the support substrate 701 and the substrate 709 can be inhibited; thus, a decrease in the yield of a subsequent separating process can be inhibited.

As the adhesive layer 707, various curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC resin, a PVB resin, and an EVA resin. In particular, a material with low moisture permeability, such as an epoxy resin, is preferable. For the adhesive, a material having fluidity low enough to dispose the material only in a desired region is preferably used. For example, an adhesive sheet, a bonding sheet, or a sheet-like or film-like adhesive can be used. For instance, an OCA (optical clear adhesive) film can be preferably used.

The adhesive may have adhesion before attachment or exhibit adhesion after attachment by heating, light irradiation, or the like.

Furthermore, the resin may include a drying agent. For example, it is possible to use a substance that adsorbs moisture by chemical adsorption, such as oxide of an alkaline earth metal (e.g., calcium oxide or barium oxide). Alternatively, a substance that adsorbs moisture by physical adsorption, such as zeolite or silica gel, may be used. The drying agent is preferably included, in which case it can suppress deterioration of the functional element due to entry of moisture in the air and can improve the reliability of the device.

For the flexible substrate 709, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (e.g., nylon or aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. For the substrate 709, any of a variety of materials such as glass, quartz, a resin, a metal, an alloy, and a semiconductor (silicon), each of which is thin enough to be flexible, may also be used.

Next, a separation starting point is formed (FIG. 34B).

There is no particular limitation on the method for forming the separation starting point, and examples include irradiation with laser light, application of mechanical force, etching of the separation layer 703, and permeation of liquid into the separation interface. Alternatively, separation may be performed by heating or cooling the support substrate 701 by utilizing a difference in thermal expansion coefficients of the two layers forming the separation interface.

The separation starting point may be formed first, and the separation may proceed from the starting point. The separation starting point can be formed by, for example, locally heating part of the first layer or the separation layer 703 with laser light or the like or physically cutting or penetrating part of the first layer or the separation layer 703 with a sharp member.

Although FIG. 34B illustrates an example in which the separation starting point is formed on the substrate 709 side, the separation starting point may be formed on the support substrate 701 side.

For example, a region where the cured adhesive layer 707, the layer 705 to be separated, and the separation layer 703 overlap with each other is irradiated with laser light (see arrows P1 in FIG. 34B). At least part of the first layer is removed, whereby the separation starting point can be formed. At this time, not only the first layer but also another layer included in the layer 705 to be separated, the separation layer 703, and the adhesive layer 707 may be removed at least partly.

Then, the layer 705 to be separated and the support substrate 701 are separated from each other from the formed separation starting point (FIG. 34C). As a result, the layer 705 to be separated can be transferred from the support substrate 701 to the flexible substrate 709.

For example, the layer 705 to be separated and the support substrate 701 can be separated from the separation starting point by mechanical force (e.g., a separation process with a human hand or a jig, or a separation process by rotation of a roller).

The support substrate 701 and the layer 705 to be separated may be separated from each other by filling the interface between the separation layer 703 and the layer 705 to be separated with a liquid such as water. A portion between the separation layer 703 and the layer 705 to be separated absorbs a liquid through capillarity, so that the separation layer 703 can be separated easily. Furthermore, an adverse effect of static electricity caused at separation on the functional element included in the layer 705 to be separated (e.g., damage to a semiconductor element from static electricity) can be suppressed.

Note that in the case where the separation layer 703 has a stacked-layer structure of a metal film and a metal oxide film, for example, part of the separation layer 703 (here, a metal oxide film) may remain on the side of the layer 705 to be separated when the separation occurs at the interface between the metal film and the metal oxide film (or in the vicinity of the interface) or in the metal oxide film. Moreover, the separation layer remaining on the side of the layer 705 to be separated may be removed after separation.

In the case where a plurality of devices are manufactured over the support substrate 701 and the plurality of devices are taken out into chip forms by dividing the support substrate 701 for each device, a step of cutting the support substrate 701 along a dicing line (also referred to as a scribe line, a dividing line, or a cutting line) may also serve as one or both of a step of forming a separation starting point and a step of separation.

Next, the exposed layer 705 is attached to a substrate 711 with an adhesive layer 713, and the adhesive layer 713 is cured (FIG. 34D).

The material that can be used for the substrate 709 can be used for the substrate 711.

The material that can be used for the adhesive layer 707 can be used for the adhesive layer 713.

Note that the layer 705 and the substrate 711 are preferably attached to each other in a reduced-pressure atmosphere.

In the above manner, the layer 705 can be sandwiched between the pair of flexible substrates (the substrate 711 and the substrate 709).

By the above method, a flexible device can be manufactured. For example, the layer 705 to be separated has the structure described in the above embodiment, leading to manufacture of a flexible display apparatus.

Although not described in detail here, as a method for manufacturing a flexible device, there is a method in which an element layer is formed over a substrate which does not have flexibility and the substrate is thinned by polishing or the like to have flexibility.

This embodiment can be combined with the other embodiments as appropriate.

### Embodiment 5

In this embodiment, a light-emitting device that can be used in the display apparatus of one embodiment of the present invention will be described.

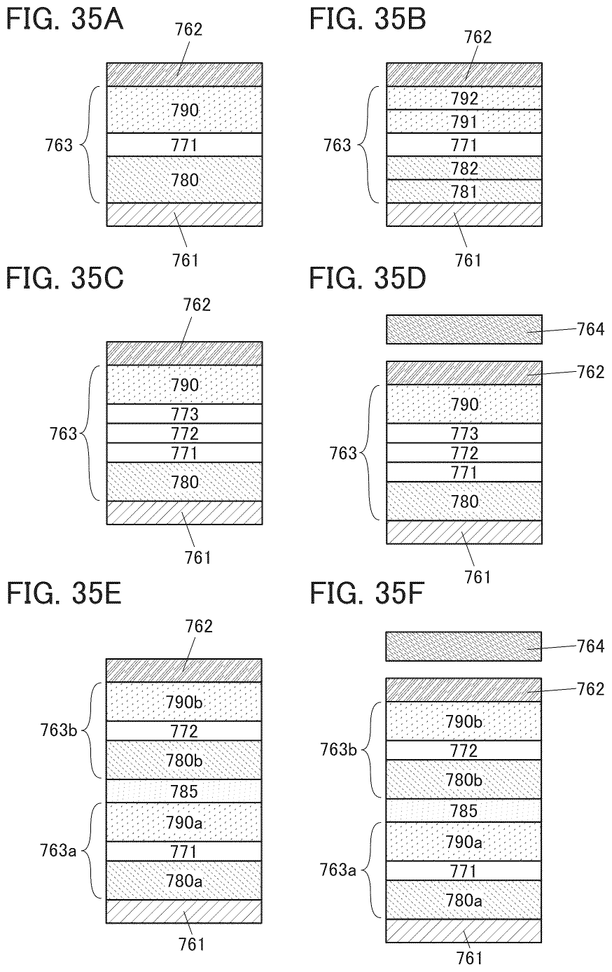

As illustrated in FIG. 35A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer including a substance having a high hole-injection property (hole-injection layer), a layer including a substance having a high hole-transport property (hole-transport layer), and a layer including a substance having a high electron-blocking property (electron-blocking layer). Furthermore, the layer 790 includes one or more of a layer including a substance having a high electron-injection property (electron-injection layer), a layer including a substance having a high electron-transport property (electron-transport layer), and a layer including a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 35A is referred to as a single structure in this specification.

FIG. 35B is a variation example of the EL layer 763 included in the light-emitting device illustrated in FIG. 35A. Specifically, the light-emitting device illustrated in FIG. 35B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layer 771, a light-emitting layer 772, and a light-emitting layer 773) are provided between the layer 780 and the layer 790 as illustrated in FIG. 35C and FIG. 35D are other variations of the single structure. Although FIG. 35C and FIG. 35D illustrate the examples where three light-emitting layers are included, the light-emitting layer in the light-emitting device with a single structure may include two or four or more light-emitting layers. A light-emitting device having a single structure may include a buffer layer between two light-emitting layers. The buffer layer can be formed using a material that can be used for the hole-transport layer or the electron-transport layer, for example.

A structure where a plurality of light-emitting units (a light-emitting unit 763a and a light-emitting unit 763b) are connected in series with a charge-generation layer 785 (also referred to as an intermediate layer) therebetween as illustrated in FIG. 35E and FIG. 35F is referred to as a tandem structure in this specification. The tandem structure may be referred to as a stack structure. A tandem structure enables a light-emitting device capable of high-luminance light emission. Furthermore, the amount of current needed for obtaining a predetermined luminance can be smaller in a tandem structure than in a single structure; thus, a tandem structure enables higher reliability.

Note that FIG. 35D and FIG. 35F illustrate examples where the display apparatus includes a layer 764 overlapping with the light-emitting device. FIG. 35D illustrates an example in which the layer 764 overlaps with the light-emitting device illustrated in FIG. 35C, and FIG. 35F illustrates an example in which the layer 764 overlaps with the light-emitting device illustrated in FIG. 35E. In FIG. 35D and FIG. 35F, a conductive film transmitting visible light is used for the upper electrode 762 to extract light to the upper electrode 762 side.

One or both of a color conversion layer and a color filter (coloring layer) can be used as the layer 764.

In FIG. 35C and FIG. 35D, light-emitting substances emitting light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 35D for converting blue light emitted from the light-emitting device into light with a longer wavelength, so that red or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by the subpixel can be improved.

In FIG. 35C and FIG. 35D, light-emitting substances emitting light of different colors may be used for the light-emitting layer 771, the light-emitting layer 772, and the light-emitting layer 773. When the light-emitting layer 771, the light-emitting layer 772, and the light-emitting layer 773 emit light of complementary colors, white light emission can be obtained. The light-emitting device having a single structure preferably includes a light-emitting layer including a light-emitting substance emitting blue light and a light-emitting layer including a light-emitting substance emitting visible light with a longer wavelength than blue light, for example.

A color filter is preferably provided as the layer 764 illustrated in FIG. 35D. When white light passes through a color filter, light of a desired color can be obtained.

In the case where the light-emitting device having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance emitting blue (B) light and a light-emitting layer including a light-emitting substance emitting yellow (Y) light are preferably included. This structure may be referred to as a BY single structure.

In the light-emitting device that emits white light, two or more kinds of light-emitting substances are preferably included. To obtain white light emission by using two light-emitting layers, light-emitting substances are selected such that emission colors of the two light-emitting layers are complementary colors. For example, when emission colors of a first light-emitting layer and a second light-emitting layer are complementary colors, the light-emitting device can emit white light as a whole. To obtain white light emission by using three or more light-emitting layers, the light-emitting device is configured to emit white light as a whole by combining emission colors of the three or more light-emitting layers.

Note that also in FIG. 35C and FIG. 35D, each of the layer 780 and the layer 790 may independently have a stacked-layer structure of two or more layers as illustrated in FIG. 35B.

In FIG. 35E and FIG. 35F, light-emitting substances emitting light of the same color, or moreover, the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In the subpixel that emits red light and the subpixel that emits green light, by providing a color conversion layer as the layer 764 illustrated in FIG. 35F, blue light emitted from the light-emitting device can be converted into light with a longer wavelength, and red light or green light can be extracted. As the layer 764, both a color conversion layer and a coloring layer are preferably used.

In FIG. 35E and FIG. 35F, light-emitting substances emitting light of different colors may be used for the light-emitting layer 771 and the light-emitting layer 772. When the light-emitting layer 771 and the light-emitting layer 772 emit light of complementary colors, white light emission can be obtained. A color filter is preferably provided as the layer 764 illustrated in FIG. 35F. When white light passes through a color filter, light of a desired color can be obtained.

Although FIG. 35E and FIG. 35F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

In addition, although FIG. 35E and FIG. 35F illustrate the light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In FIG. 35E and FIG. 35F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of fabricating the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

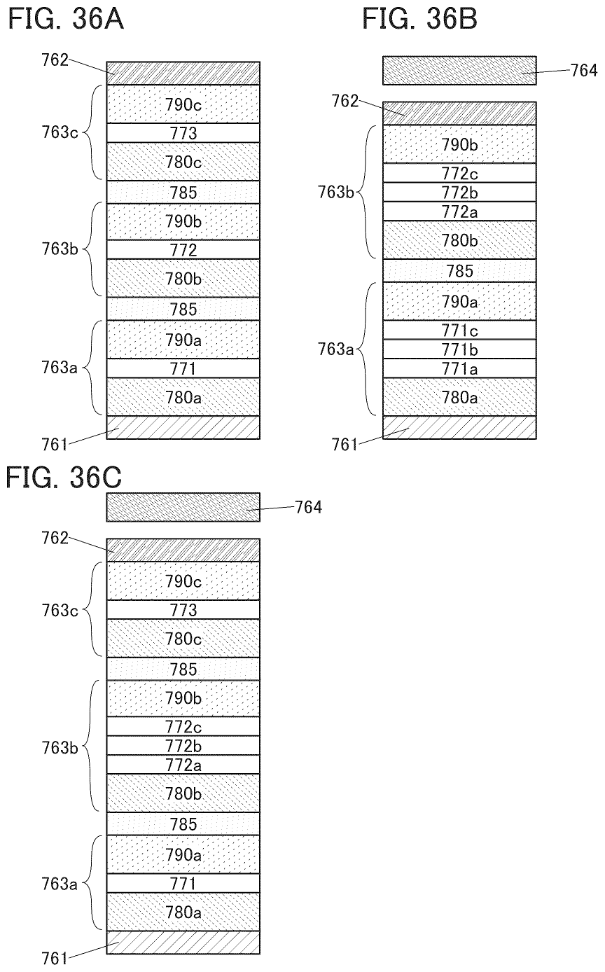

As examples of the light-emitting device with a tandem structure, structures illustrated in FIG. 36A to FIG. 36C can be given.

FIG. 36A illustrates a structure including three light-emitting units. In FIG. 36A, a plurality of light-emitting units (the light-emitting unit 763a, the light-emitting unit 763b, and a light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 36A, the light-emitting layer 771, the light-emitting layer 772, and the light-emitting layer 773 can include light-emitting substances that emit light of the same color. Specifically, a structure where the light-emitting layer 771, the light-emitting layer 772, and the light-emitting layer 773 each include a blue (B) light-emitting substance (what is called a three-unit tandem structure of B\B\B) can be employed. Note that “a\b” means that a light-emitting unit containing a light-emitting substance that emits light of b is provided over a light-emitting unit containing a light-emitting substance that emits light of a with a charge-generation layer therebetween, where a and b represent colors.

In FIG. 36A, light-emitting substances that emit light of different colors can be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

FIG. 36B illustrates a tandem light-emitting device in which light-emitting units each including a plurality of light-emitting layers are stacked. FIG. 36B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 36B, the light-emitting unit 763a is configured to emit white (W) light by selecting light-emitting substances for the light-emitting layer 771a, the light-emitting layer 771b, and the light-emitting layer 771c so that their emission colors are complementary colors. Furthermore, the light-emitting unit 763b is configured to emit white (W) light by selecting light-emitting substances for the light-emitting layer 772a, the light-emitting layer 772b, and the light-emitting layer 772c such that their emission colors are complementary colors. In other words, the structure illustrated in FIG. 36B is a two-unit tandem structure of WWW. Note that there is no particular limitation on the stacking order of the light-emitting substances satisfying the relationship of complementary colors. The practitioner can select the optimal stacking order as appropriate. Although not illustrated, a three-unit tandem structure of WWW or a tandem structure with four or more units may be employed.

Other examples of the structure of a light-emitting device having a tandem structure include a B\Y or Y\B two-unit tandem structure including a light-emitting unit that emits yellow (Y) light and a light-emitting unit that emits blue (B) light; an R×G\B or B\R×G two-unit tandem structure including a light-emitting unit that emits red (R) and green (G) light and a light-emitting unit that emits blue (B) light; a B\Y\B three-unit tandem structure including a light-emitting unit that emits blue (B) light, a light-emitting unit that emits yellow (Y) light, and a light-emitting unit that emits blue (B) light in this order; a B\YG\B three-unit tandem structure including a light-emitting unit that emits blue (B) light, a light-emitting unit that emits yellowish green (YG) light, and a light-emitting unit that emits blue (B) light in this order; and a B\G\B three-unit tandem structure including a light-emitting unit that emits blue (B) light, a light-emitting unit that emits green (G) light, and a light-emitting unit that emits blue (B) light in this order. Note that “a×b” means that one light-emitting unit contains a light-emitting substance that emits light of a and a light-emitting substance that emits light of b.

As illustrated in FIG. 36C, a light-emitting unit including one light-emitting layer and a light-emitting unit including a plurality of light-emitting layers may be used in combination.

Specifically, in the structure illustrated in FIG. 36C, a plurality of light-emitting units (the light-emitting unit 763a, the light-emitting unit 763b, and the light-emitting unit 763c) are each connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 36C can be, for example, a three-unit tandem structure of B\R×G×YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display apparatus includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display apparatus.

Examples of a material that forms the pair of electrodes of the light-emitting device include a metal, an alloy, an electrically conductive compound, and a mixture thereof. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing an appropriate combination of any of these metals. Other examples of the material include indium tin oxide (In—Sn oxide, also referred to as ITO), an In—Si—Sn oxide (also referred to as ITSO), indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a micro optical resonator (microcavity) structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified. The color purity can be increased when the light-emitting device has a microcavity structure.

That is, as the electrode through which light is extracted in the light-emitting device, an electrode having a visible-light-transmitting property (a transparent electrode) or a transflective electrode can be used.

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (also referred to as a substance with a high electron-transport property and a high hole-transport property or a bipolar material), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

As the light-emitting substance, a fluorescent material, a phosphorescent material, a substance exhibiting thermally activated delayed fluorescence (a thermally activated delayed fluorescent (TADF) material), a quantum dot material, or the like can be used.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, any of after-mentioned substances with a high hole-transport property that can be used for the hole-transport layer can be used. As the electron-transport material, it is possible to use any of after-mentioned substances with a high electron-transport property that can be used for the electron-transport layer. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of the light-emitting device can be achieved at the same time.

The hole-injection layer injects holes from the anode to the hole-transport layer and includes a substance having a high hole-injection property. Examples of the substance having a high hole-injection property include an aromatic amine compound and a composite material including a hole-transport material and an acceptor material (electron-accepting material).

As the hole-transport material, any of after-mentioned substances with a high hole-transport property that can be used for the hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferred because it is stable in the air, has a low hygroscopic property, and is easy to handle. Alternatively, an organic acceptor material containing fluorine can be used. An organic acceptor material such as a quinodimethane derivative, a chloranil derivative, or a hexaazatriphenylene derivative can be used.

As the substance having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material is preferably a substance having a hole mobility higher than or equal to 1×10⁻⁶ cm²/Vs. Note that other substances can also be used as long as the substances have a hole-transport property higher than an electron-transport property. As the hole-transport material, substances having a high hole-transport property, such as a n-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material is preferably a substance having an electron mobility higher than or equal to 1×10⁻⁶ cm²/Vs. Note that other substances can also be used as long as the substances have an electron-transport property higher than a hole-transport property. As the electron-transport material, any of the following substances having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a T-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and includes a substance having a high electron-injection property. As the substance having a high electron-injection property, an alkali metal, an alkaline earth metal, or a compound thereof can be used. As the substance having a high electron-injection property, a composite material including an electron-transport material and a donor material (electron-donating material) can also be used.

The LUMO level of the substance having a high electron-injection property preferably has a small difference (specifically, less than or equal to 0.5 eV) from the work function of a material used for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato) lithium (abbreviation: Liq), 2-(2-pyridyl) phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-a:2′,3′-c] phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a substance having a high electron-injection property. The layer can also be referred to as an electron-injection buffer layer. The electron-injection buffer layer is preferably provided between the charge-generation region and the electron-transport layer. Providing the electron-injection buffer layer can reduce an injection barrier between the charge-generation region and the electron-transport layer; thus, electrons generated in the charge-generation region can be easily injected into the electron-transport layer.

The electron-injection buffer layer preferably includes an alkali metal or an alkaline earth metal, and can include an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper(II) phthalocyanine (abbreviation: CuPc) or zinc phthalocyanine (ZnPc), or a metal complex having a metal-oxygen bond and an aromatic ligand is preferably used.

Note that distinction between the charge-generation region, the electron-injection buffer layer, and the electron-relay layer on the basis of the cross-sectional shape or properties cannot be made clearly in some cases.

The charge-generation layer may include a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

At least part of this embodiment can be implemented in combination with the other embodiments described in this specification as appropriate.

### REFERENCE NUMERALS

10_L: display apparatus, 10_R: display apparatus, 10A: display apparatus, 10B: display apparatus, 10: display apparatus, 11: substrate, 12: substrate, 13: display portion, 14: terminal portion, 19: sub-display portion, 20: layer, 21: transistor, 22: channel formation region, 29A: first section, 29B: second section, 29C: third section, 30: driver circuit, 31: source driver circuit, 32: digital-analog converter circuit, 33: gate driver circuit, 34: level shifter, 35: amplifier circuit, 36: inspection circuit, 37: video generation circuit, 38: video distribution circuit, 39: section, 40: functional circuit, 41: memory device, 42a: color irregularity correction, 42b: upconversion, 42: GPU, 43: EL correction circuit, 44: timing generation circuit, 45: CPU, 46: sensor controller, 47: power supply circuit, 48: temperature sensor, 49: luminance correction circuit, 50: layer, 51A: pixel circuit, 51B: pixel circuit, 51C: pixel circuit, 51D: pixel circuit, 51E: pixel circuit, 51F: pixel circuit, 51G: pixel circuit, 51H: pixel circuit, 51I: pixel circuit, 51: pixel circuit, 52A: transistor, 52B: transistor, 52C: transistor, 52D: transistor, 52w: transistor, 52: transistor, 53A: capacitor, 53s: capacitor, 53w: capacitor, 53: capacitor, 54: channel formation region, 55: pixel circuit group, 59[1,1]: section, 59[i,j]: section, 59[m,n]: section, 59: section, 60: layer, 61: light-emitting element, 80: input/output circuit, 100: semiconductor device, 110: light-exposure region, 112: region, 120: light-exposure region, 122: sealing region, 124: non-chip region, 126: terminal region, 130: semiconductor device, 132: substrate, 134: substrate, 136: display portion, 138: pixel, 140: terminal portion, 142: layer, 144: layer, 146: layer, 150: driver circuit, 152: functional circuit, 154: input/output circuit, 156: pixel circuit, 158: pixel circuit group, 160: light-emitting device, 200: electronic device, 201: motion detection portion, 202: gaze detection portion, 203: arithmetic portion, 204: communication portion, 205: housing, 206A: earphone, 206B: earphone, 206: wearing portion, 207: cushion, 208: lens, 209: input terminal, 210: output terminal, 211: image data, 212: user, 213A: direction, 213B: direction, 213: gaze, 214A: image, 214B: image, 214: image, 220A: electronic device, 221: operation button, 224: wearing tool, 225: sensor, 226: dial, 230: pixel, 240: display module, 241: printed wiring board, 242: terminal portion, 243: wire, 244: FPC, 245: connection portion, 251: timing generation circuit, 252: input/output circuit, 253: frame memory, 261: image information input portion, 262: clock signal input portion, 263: retention portion, 264: operation parameter setting portion, 265: internal clock signal generating portion, 266: image processing portion, 267: memory controller, 300A: first display apparatus, 300B: first display apparatus, 300: first display apparatus, 302A: second display apparatus, 302: second display apparatus, 310: display portion, 311: housing, 312: communication portion, 313: band, 314: control portion, 320: display portion, 321: housing, 322: communication portion, 323: wearing portion, 324: control portion, 325: camera portion, 330L: left hand, 330R: right hand, 330: user, 340: image, 341: image information, 400d: transistor, 410: substrate, 412: element isolation layer, 413: semiconductor region, 414a: low-resistance region, 414b: low-resistance region, 415: insulator, 416: conductor, 417: insulator, 420: insulator, 422: insulator, 424: insulator, 426: insulator, 428: conductor, 430: conductor, 450: insulator, 452: insulator, 454: insulator, 456: conductor, 501: substrate, 503: adhesive layer, 505: insulating layer, 512: insulator, 514: conductor, 574: insulator, 581: insulator, 592: insulator, 594: insulator, 596: conductor, 598: insulator, 599: insulator, 600A: display apparatus, 600B: display apparatus, 600C: display apparatus, 607: adhesive layer, 610: substrate, 611a: conductor, 611b: conductor, 611c: conductor, 613a: layer, 613b: layer, 613c: layer, 614: common layer, 615: common electrode, 618a: sacrificial layer, 620: element layer, 625: insulator, 627: insulator, 628B: coloring layer, 628G: coloring layer, 628R: coloring layer, 630: element layer, 631: protective layer, 635: element layer, 640: connection portion, 650B: light-emitting device, 650G: light-emitting device, 650R: light-emitting device, 650: light-emitting device, 660: element layer, 670: wiring layer, 701: support substrate, 703: separation layer, 705: layer to be separated, 707: adhesive layer, 709: substrate, 711: substrate, 713: adhesive layer, 761: lower electrode, 762: upper electrode, 763a: light-emitting unit, 763b: light-emitting unit, 763c: light-emitting unit, 763: EL layer, 764: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800: transistor, 805a: conductor, 805b: conductor, 805: conductor, 815: insulator, 816: insulator, 820a: oxide, 820b: oxide, 820: oxide, 821: insulator, 822: insulator, 824: insulator, 842a: conductor, 842b: conductor, 850: insulator, 855: insulator, 860a: conductor, 860b: conductor, 860: conductor, 871a: insulator, 871b: insulator, 875: insulator, 882: insulator, 883: insulator, 885: insulator

1. An electronic device comprising:
a lens and a display apparatus,
wherein the lens is at a position where light from the display apparatus passes,
wherein the display apparatus comprises a display portion and a transistor,
wherein the display portion comprises a light-emitting device,
wherein the transistor is below the light-emitting device,
wherein the display portion has a diagonal size greater than or equal to 1.0 inch and less than or equal to 2.5 inches,
wherein the transistor comprises an oxide semiconductor in a channel formation region, and
wherein the transistor is configured to control driving of the light-emitting device.

2. An electronic device comprising:
a lens and a display apparatus,
wherein the lens is at a position where light from the display apparatus passes,
wherein the display apparatus comprises a display portion and a transistor,
wherein the display portion comprises a light-emitting device,
wherein the transistor is below the light-emitting device,
wherein the display portion has a diagonal size greater than or equal to 1.0 inch and less than or equal to 2.5 inches,
wherein the transistor comprises an oxide semiconductor in a channel formation region,
wherein the light-emitting device is an organic EL element, and
wherein the transistor is configured to control driving of the organic EL element.

3. An electronic device comprising:
a lens and a display apparatus,
wherein the lens is at a position where light from the display apparatus passes,
wherein the display apparatus comprises a display portion, a first transistor, and a second transistor,
wherein the display portion comprises a light-emitting device,
wherein the first transistor is below the light-emitting device,
wherein the second transistor is below the first transistor,
wherein the display portion has a diagonal size greater than or equal to 1.0 inch and less than or equal to 2.5 inches,
wherein the light-emitting device is an organic EL element,
wherein the first transistor constitutes a part of a pixel circuit, and
wherein the second transistor constitutes a part of a driver circuit or a functional circuit.

4. The electronic device according to claim 3, wherein each of the first transistor and the second transistor comprises an oxide semiconductor.

5. The electronic device according to claim 3,
wherein the first transistor comprises an oxide semiconductor, and
wherein the second transistor comprises silicon.
